(19) United States
(12) Patent Application Publication
(10) Pub. No.: US 2025/0393345 A1
(43) Pub. Date: Dec. 25, 2025

(54) LIGHT-EMITTING CHIP, DISPLAY BASE PLATE AND DISPLAY APPARATUS

(71) Applicants: Beijing BOE Technology Development Co., Ltd., Beijing (CN); BOE Technology Group Co., Ltd., Beijing (CN)

(72) Inventors: Xiang LI, Beijing (CN); Mingxing WANG, Beijing (CN); Qian WANG, Beijing (CN); Che AN, Beijing (CN); Qian JIN, Beijing (CN); Xiaohu LI, Beijing (CN); Yu TIAN, Beijing (CN); Xue DONG, Beijing (CN); Yingtao WANG, Beijing (CN); Xinxing WANG, Beijing (CN)

(73) Assignees: Beijing BOE Technology Development Co., Ltd., Beijing (CN); BOE Technology Group Co., Ltd., Beijing (CN)

(21) Appl. No.: 18/996,276

(22) PCT Filed: May 20, 2024
(86) PCT No.: PCT/CN2024/094308

§ 371 Date: Jan. 17, 2025

(30) Foreign Application Priority Data
Sep. 28, 2023 (WO) PCT/CN2023/123002

(51) Int. Cl. H10H 20/851; H10H 20/853; H10H 29/24

(52) U.S. Cl. CPC H10H 20/8514; H10H 20/853; H10H 29/24

(57) ABSTRACT

Provided is a light-emitting chip. The light-emitting unit includes a plurality of light-emitting parts; the light-emitting unit further includes a second semiconductor layer, wherein the second semiconductor layer is disposed on light-emitting sides of the plurality of light-emitting parts; wherein a surface of the second semiconductor layer facing away from the color converting unit is a second surface, and the second semiconductor layer includes a first groove that opens in the second surface; and the light-emitting chip further includes a filling part disposed in the first groove, wherein the filling part is made of an opaque material.

### CROSS-REFERENCE TO RELATED APPLICATIONS

This application is a U.S. national stage of international application No. PCT/CN2024/094308, filed on May 20, 2024, which claims priority to international application No. PCT/CN2023/123002, filed on Sep. 28, 2023 and entitled “LIGHT-EMITTING CHIP, DISPLAY BASE PLATE AND DISPLAY APPARATUS,” the disclosures of which are herein incorporated by reference in their entireties.

### TECHNICAL FIELD

The present disclosure relates to the field of display technologies, and particularly, relates to a light-emitting chip, a display base plate and a display apparatus.

### BACKGROUND

With the development of technologies and the increasing high requirement for display, light-emitting diodes (LEDs) are the trend for the development of display apparatuses in the future, which have unparalleled advantages over liquid crystal displays and organic electroluminescent display panels, such as ultra-high contrast, ultra-high color gamut, high luminous efficiency, high luminance and low energy consumption.

In this regard, display apparatuses provided with the LEDs and quantum-dots (QDs) are highly favored, and are applicable to mobile phones, monitors, TVs and outdoor displays.

### SUMMARY

Embodiments of the present disclosure provide a light-emitting chip, a display base plate and a display apparatus, which can solve a problem of relatively poor display of the display base plate. The technical solutions are as follows.

In an aspect, a light-emitting chip is provided, and includes: a light-emitting unit, and a color converting unit disposed on a light-emitting side of the light-emitting unit; wherein the light-emitting unit includes a plurality of light-emitting parts, and each light-emitting part in the plurality of light-emitting parts includes a first electrode, a first semiconductor layer and a light-emitting layer which are laminated in a first direction; the light-emitting unit further includes a second semiconductor layer and a common electrode layer, wherein the second semiconductor layer is disposed on light-emitting sides of the plurality of light-emitting parts, and includes a connecting part and an assisting part, wherein the connecting part is connected to the light-emitting parts, and at least part of the assisting part is disposed between an adjacent connecting part; the connecting part and the assisting part are of an integrated structure, and the common electrode layer and the assisting part are connected; wherein a surface of the second semiconductor layer facing the color converting unit is a first surface, and a surface of the second semiconductor layer facing away from the color converting unit is a second surface, and the second semiconductor layer includes a first groove that opens in the second surface, and the first groove is at least disposed between orthographic projections of two adjacent light-emitting parts in the plurality of light-emitting parts on an extension surface of the second semiconductor layer; and the light-emitting chip further includes a filling part disposed in the first groove, wherein the filling part is made of an opaque material.

In some embodiments, the filling part is a part of the common electrode layer.

In some embodiments, the first groove is disposed in an orthographic projection of the common electrode layer on the extension surface of the second semiconductor layer.

In some embodiments, a side of the common electrode layer facing away from the color converting unit is provided with a recessed groove, wherein an orthographic projection of the recessed groove on the extension surface of the second semiconductor layer overlaps with the first groove.

In some embodiments, a part of the common electrode layer disposed in the first groove and a part of the common electrode layer disposed outside the first groove are of a continuously-extended integrated structure.

In some embodiments, a ratio of the depth of the first groove to the thickness of the second semiconductor layer is in a range of 10% to 65%.

In some embodiments, a ratio of the distance between a bottom of the first groove and the first surface in the first direction to a thickness of the second semiconductor layer is in a range of 35% to 90%

In some embodiments, the second semiconductor layer includes a first sub-layer and a second sub-layer which are laminated, wherein the first sub-layer is more proximal to the light-emitting part than the second sub-layer, the first sub-layer is a first carrier transport layer, and the second sub-layer is a buffer layer; wherein the first groove includes a first blind groove disposed on a side of the first sub-layer facing away from the second sub-layer; or the first groove includes a first penetrating groove penetrating through the first sub-layer; or the first groove includes: a first penetrating groove penetrating through the first sub-layer, and a second blind groove disposed on a side of the second sub-layer facing the first sub-layer, the first penetrating groove being connected with the second blind groove; or the first groove includes: a first penetrating groove penetrating through the first sub-layer and a second penetrating groove penetrating through the second sub-layer, the first penetrating groove being connected with the second penetrating groove.

In some embodiments, a minimum distance between an outer boundary of the first groove and an outer boundary of an orthographic projection, on the extension surface of the second semiconductor layer, of the light-emitting layer in the light-emitting part adjacent to the first groove is greater than or equal to 5 microns.

In some embodiments, the plurality of light-emitting parts includes a first light-emitting part, a second light-emitting part and a third light-emitting part; wherein the first light-emitting part and the second light-emitting part are disposed in a row in a second direction, and the first light-emitting part and the third light-emitting part are disposed in a row in a third direction; the second direction intersects with the third direction, and both the second direction and the third direction intersect with the first direction; and the first groove includes a first groove portion and a second groove portion, wherein the first groove portion is disposed between orthographic projections of the first light-emitting part and the second light-emitting part on the extension surface of the second semiconductor layer, and the second groove portion is disposed between orthographic projections of the first light-emitting part and the third light-emitting part on the extension surface of the second semiconductor layer.

In some embodiments, the first groove portion and the second groove portion are both strip-shaped, the first groove portion extends along the third direction, and the second groove portion extends along the second direction.

In some embodiments, a length of the first groove portion in the third direction is greater than or equal to a width of the first light-emitting part in the third direction and greater than or equal to a width of the second light-emitting part in the third direction; and/or, a length of the second groove portion in the second direction is greater than or equal to a width of the first light-emitting part in the second direction and greater than or equal to a width of the third light-emitting part in the second direction.

In some embodiments, a width of the first groove portion in the second direction and a width of the second groove portion in the third direction are both in a range of 2 microns to 10 microns.

In some embodiments, the first groove portion and the second groove portion are connected with each other.

In some embodiments, a shape of an orthographic projection, on the extension surface of the second semiconductor layer, of the first groove portion and the second groove portion that are connected with each other includes a T-shape.

In some embodiments, the light-emitting unit further includes a second electrode, the second electrode being disposed on a side of the common electrode layer distal from the color converting unit and being electrically connected to the common electrode layer; wherein the first electrode in the third light-emitting part and the second electrode are disposed in a row in the second direction, and the first electrode in the second light-emitting part and the second electrode are disposed in a row in the third direction.

In some embodiments, the light-emitting chip further includes an encircling dam, the encircling dam being disposed on a side of the color converting unit facing the light-emitting unit, and being distributed surrounding a periphery of the light-emitting unit; wherein the encircling dam is made of an opaque material.

In some embodiments, the color converting unit includes a defining dam layer, wherein the defining dam layer defines a plurality of opening regions, one light-emitting part corresponding to one opening region in the first direction; and the color converting unit further includes optical functional parts disposed in the opening regions of the defining dam layer, and an encapsulating layer configured to encapsulate the optical functional parts and the defining dam layer; wherein each light-emitting part is configured to emit a first light ray, and at least part of the optical functional parts are configured to convert a color of an incident first light rays.

In some embodiments, the plurality of light-emitting parts includes: a first light-emitting part, a second light-emitting part and a third light-emitting part; wherein the first light-emitting part and the second light-emitting part are disposed in a row in a second direction, and the first light-emitting part and the third light-emitting part are disposed in a row in a third direction; the second direction intersects with the third direction, and both the second direction and the third direction intersect with the first direction; a light-emitting area of the second light-emitting part is larger than a light-emitting area of the first light-emitting part, and is larger than a light-emitting area of the third light-emitting part; and a projection area of an optical functional part corresponding to the second light-emitting part on the extension surface of the second semiconductor layer is larger than a projection area of an optical functional part corresponding to the first light-emitting part on the extension surface of the second semiconductor layer, and is larger than a projection area of an optical functional part corresponding to the third light-emitting part on the extension surface of the second semiconductor layer.

In some embodiments, the length of a light-emitting layer of the second light-emitting part in the third direction is greater than a length of a light-emitting layer of the first light-emitting part in the third direction; and a length of the optical functional part corresponding to the second light-emitting part in the third direction is greater than a length of the optical functional part corresponding to the third light-emitting part in the third direction.

In some embodiments, the first light ray is blue light, and the optical functional part corresponding to the second light-emitting part is configured to convert the blue light into green light; and the optical functional part corresponding to one of the first light-emitting part or the second light-emitting part is configured to convert the blue light into red light, and the optical functional part corresponding to the other light-emitting part of the first light-emitting part or the second light-emitting part is configured to transmit the first light ray.

In some embodiments, the color converting unit further includes: a first light selective transmission layer, wherein the first light selective transmission layer is distributed on a side of the color converting unit facing away from the light-emitting unit, and is configured to reflect the first light ray and transmit a light ray different from the first light ray in color; wherein the plurality of optical functional parts includes at least one first target optical functional part configured to convert the color of the first light ray into another color, wherein an orthographic projection of the first light selective transmission layer on the extension surface of the second semiconductor layer overlaps with an orthographic projection of the first target optical functional part on the extension surface of the second semiconductor layer.

In some embodiments, the first light selective transmission layer is a continuously distributed film layer; wherein the plurality of optical functional parts includes at least one second target optical functional part configured to transmit the first light ray, the first light selective transmission layer includes a hollowed-out region, wherein an orthographic projection of the hollowed-out region on the extension surface of the second semiconductor layer overlaps with an orthographic projection of the second target optical functional part on the extension surface of the second semiconductor layer.

In some embodiments, the first light selective transmission layer includes a plurality of first dielectric layers and a plurality of second dielectric layers, wherein the plurality of first dielectric layers and the plurality of second dielectric layers are sequentially laminated along the first direction, and a refractive index of the first dielectric layer and a refractive index of the second dielectric layer are different.

In some embodiments, the first light selective transmission layer is disposed in the opening region defining the first target optical functional part.

In some embodiments, the material of the first light selective transmission layer includes cholesteric liquid crystal.

In some embodiments, the light-emitting chip further includes a second light selective transmission layer distributed in the color converting unit or the light-emitting unit, wherein the second light selective transmission layer is configured to transmit the first light ray and reflect a light ray different from the first light ray in color.

In some embodiments, in the case that the second light selective transmission layer is distributed in the color converting unit, the second light selective transmission layer is disposed on a side, facing the light-emitting unit, of the defining dam layer and the plurality of optical functional parts; and in the case that the second light selective transmission layer is distributed in the light-emitting unit, the second light selective transmission layer is disposed on a side of the second semiconductor layer facing the color converting unit.

In some embodiments, in the case that the first light ray is blue light, at least one of the first target optical parts includes a first optical functional part configured to convert the blue light into red light and a second optical functional part configured to convert the blue light into green light, and at least one of the second target optical parts includes a third optical functional part configured to transmit the first light ray.

In some embodiments, the color converting unit further includes a light filtering layer, wherein the light filtering layer includes a plurality of light filtering parts disposed in one-to-one correspondence with the plurality of optical functional parts; wherein the light filtering parts are configured to filter light rays with other colors different from light rays with corresponding colors among light rays emitted from the optical functional parts.

In another aspect, a display base plate is provided, and includes: the light-emitting chip described in any one of the above items; and a driving circuit layer configured to drive the light-emitting chip to emit light.

In yet another aspect, a display apparatus is provided, and includes the above display base plate; and a control circuit, configured to provide an electric signal to the display base plate.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following description show merely some embodiments of the present disclosure, and those skilled in the art may still derive other drawings from these accompanying drawings without creative efforts.

FIG. 1 is a structural diagram of a mobile phone according to some embodiments of the present disclosure;

FIG. 2 is a structural diagram of a display base plate according to some embodiments of the present disclosure;

FIG. 3 is a structural diagram of a light-emitting chip according to some embodiments of the present disclosure;

FIG. 4 is a sectional view of the light-emitting chip according to FIG. 3 along a sectional line QQ;

FIG. 5 is another structural diagram of a light-emitting chip according to some embodiments of the present disclosure;

FIG. 6 is a yet another structural diagram of a light-emitting chip according to some embodiments of the present disclosure;

FIG. 7 is a yet another structural diagram of a light-emitting chip according to some embodiments of the present disclosure;

FIG. 8 is a structural diagram of a wafer according to some embodiments of the present disclosure;

FIG. 9 is a flowchart of a method for preparing an initial chip wafer unit according to some embodiments of the present disclosure;

FIGS. 10 to 20 are process diagrams of a method for preparing an initial chip wafer unit according to some embodiments of the present disclosure;

FIG. 21 is a flowchart of a method for preparing an optical functional unit according to some embodiments of the present disclosure;

FIGS. 22 to 26 are process diagrams of a method for preparing an optical functional unit according to some embodiments of the present disclosure;

FIG. 27 is a flowchart of forming a light-emitting chip by cell aligning an optical functional unit and an initial chip wafer unit according to some embodiments of the present disclosure;

FIGS. 28 to 35 are process diagrams of forming a light-emitting chip by cell aligning an optical functional unit and an initial chip wafer unit according to some embodiments of the present disclosure;

FIG. 36 is a flowchart of forming another light-emitting chip by cell aligning an optical functional unit and an initial chip wafer unit according to some embodiments of the present disclosure;

FIGS. 37 and 38 are process diagrams of forming another light-emitting chip by cell aligning an optical functional unit and an initial chip wafer unit according to some embodiments of the present disclosure;

FIG. 39 is a flowchart of forming yet another light-emitting chip by cell aligning an optical functional unit and an initial chip wafer unit according to some embodiments of the present disclosure;

FIGS. 40 to 44 are process diagrams of forming yet another light-emitting chip by cell aligning an optical functional unit and an initial chip wafer unit according to some embodiments of the present disclosure;

FIG. 45 is a top view of a light-emitting chip according to some embodiments of the present disclosure;

FIG. 46 is a sectional view of the light-emitting chip according to FIG. 45 along a sectional line HH;

FIG. 47 is an internal light ray path diagram of a light-emitting chip according to some embodiments of the present disclosure;

FIG. 48 is another internal light ray path diagram of a light-emitting chip according to some embodiments of the present disclosure;

FIG. 49 is a yet another structural diagram of a light-emitting chip according to some embodiments of the present disclosure;

FIG. 50 is a sectional view of the light-emitting chip according to FIG. 49 along a sectional line VV;

FIG. 51 is another structural diagram of a light-emitting chip according to some embodiments of the present disclosure;

FIG. 52 is a yet another structural diagram of a light-emitting chip according to some embodiments of the present disclosure;

FIG. 53 is a yet another structural diagram of a light-emitting chip according to some embodiments of the present disclosure;

FIG. 54 is a yet another structural diagram of a light-emitting chip according to some embodiments of the present disclosure;

FIG. 55 is a sectional structural view taken along a sectional line DD in the structural diagram of the light-emitting chip illustrated in FIG. 54;

FIG. 56 is a view of a nano layer along a direction E in the structural diagram of the light-emitting chip illustrated in FIG. 54;

FIG. 57 is a path diagram of a light ray on a surface of a nano layer according to some embodiments of the present disclosure;

FIG. 58 is a test result diagram of reflectivity according to some embodiments of the present disclosure;

FIG. 59 is a yet another structural diagram of a light-emitting chip according to some embodiments of the present disclosure;

FIG. 60 is another test result diagram of reflectivity according to some embodiments of the present disclosure;

FIG. 61 is a yet another structural diagram of a light-emitting chip according to some embodiments of the present disclosure;

FIG. 62 is a yet another structural diagram of a light-emitting chip according to some embodiments of the present disclosure;

FIG. 63 is a yet another structural diagram of a light-emitting chip according to some embodiments of the present disclosure;

FIG. 64 is a yet another structural diagram of a light-emitting chip according to some embodiments of the present disclosure;

FIG. 65 is a yet another structural diagram of a light-emitting chip according to some embodiments of the present disclosure;

FIG. 66 is a process diagram of a method for manufacturing a light-emitting chip according to some embodiments of the present disclosure;

FIG. 67 is a yet another structural diagram of a light-emitting chip according to some embodiments of the present disclosure;

FIG. 68 is an enlarged view at I in the structural diagram of the light-emitting chip illustrated in FIG. 67;

FIG. 69 is a yet another structural diagram of a light-emitting chip according to some embodiments of the present disclosure;

FIG. 70 is a yet another structural diagram of a light-emitting chip according to some embodiments of the present disclosure;

FIG. 71 is an enlarged view of a grating strip of a light-emitting chip according to some embodiments of the present disclosure;

FIG. 72 is a yet another structural diagram of a light-emitting chip according to some embodiments of the present disclosure;

FIG. 73 is a yet another structural diagram of a light-emitting chip according to some embodiments of the present disclosure;

FIG. 74 is a ray path diagram of a second semiconductor layer according to some embodiments of the present disclosure;

FIG. 75 is yet another internal light ray path diagram of a light-emitting chip according to some embodiments of the present disclosure;

FIG. 76 is a yet another structural diagram of a light-emitting chip according to some embodiments of the present disclosure;

FIG. 77 is a yet another structural diagram of a light-emitting chip according to some embodiments of the present disclosure;

FIG. 78 is a bottom view of a light-emitting chip according to some other embodiments of the present disclosure;

FIG. 79 is a top view of a light-emitting unit illustrated in FIG. 78;

FIG. 80 is a sectional view of the light-emitting chip illustrated in FIGS. 78 and 79 at LL;

FIG. 81 is a partially enlarged view of a distribution of a second semiconductor layer and a common electrode layer according to some embodiments of the present disclosure;

FIG. 82 is a schematic structural diagram of a second semiconductor layer according to some embodiments of the present disclosure;

FIG. 83 is a schematic structural diagram of another second semiconductor layer according to some embodiments of the present disclosure;

FIG. 84 is a structural schematic diagram of yet another second semiconductor layer according to some embodiments of the present disclosure;

FIG. 85 is a schematic structural diagram of still another second semiconductor layer according to some embodiments of the present disclosure;

FIG. 86 is a bottom view of another light-emitting chip according to some other embodiments of the present disclosure;

FIG. 87 is a bottom view of yet another light-emitting chip according to some other embodiments of the present disclosure;

FIG. 88 is a sectional view of a light-emitting chip according to some embodiments of the present disclosure;

FIG. 89 is a sectional view of another light-emitting chip according to some embodiments of the present disclosure;

FIG. 90 is a sectional view of yet another light-emitting chip according to some embodiments of the present disclosure;

FIG. 91 is a schematic structural diagram of a first light selective transmission layer according to some embodiments of the present disclosure;

FIG. 92 is a sectional view of still another light-emitting chip according to some embodiments of the present disclosure;

FIG. 93 is a sectional view of a light-emitting chip according to some other embodiments of the present disclosure;

FIG. 94 is a sectional view of a light-emitting chip according to some other embodiments of the present disclosure;

FIG. 95 is a sectional view of another light-emitting chip according to some other embodiments of the present disclosure;

FIG. 96 is a sectional view of yet another light-emitting chip according to some other embodiments of the present disclosure;

FIG. 97 is a sectional view of still another light-emitting chip according to some other embodiments of the present disclosure;

FIG. 98 is a schematic structural diagram of a light-emitting chip according to some other embodiments of the present disclosure; and

FIG. 99 is a schematic diagram of a preparing process of the light-emitting chip according to the embodiments of FIG. 98.

### DETAILED DESCRIPTION

For clearer descriptions of the objectives, technical solutions, and advantages of the present disclosure, the embodiments of the present disclosure are described in detail hereinafter with reference to the accompanying drawings.

The technical solutions in some embodiments of the present disclosure will be clearly and completely described hereinafter with reference to the accompanying drawings. Obviously, the embodiments described are merely some but not all embodiments of the present disclosure. Based on the embodiments provided by the present disclosure, all other embodiments acquired by those of ordinary skill in the art belong to protection scope of the present disclosure.

Unless the context requires otherwise, throughout the Description and claims, the terms “comprise” and its other forms, such as the third person singular form “comprises” and the present participle form “comprising.” are interpreted as an open and inclusive meaning, that is, “including, but not limited to” In the description of the Description, the terms such as “one embodiment,” “some embodiments,” “exemplary embodiments,” “example,” “specific example” or “some examples” are intended to indicate that a specific feature, structure, material or characteristic related to this embodiment or example is included in at least one embodiment or example of the present disclosure. The schematic representations of the above terms do not necessarily refer to the same embodiment or example. In addition, the specific feature, structure, material or characteristic described may be included in any one or more embodiments or examples in any suitable way.

Hereinafter, the terms “first” and “second” are only used for a descriptive purpose, and shall not be understood as indicating or implying relative importance or implicitly indicating the quantity of indicated technical features. Therefore, the features defined as “first” and “second” may include one or more of these features explicitly or implicitly. In the description of the embodiments of the present disclosure, unless otherwise stated, “a plurality of” means two or more.

In describing some embodiments, expressions of “coupled” and “connected” and their extensions may be used. The term “connected” are to be construed broadly, may be, for example, fixedly connected, detachably connected or integrally formed; and may be directly connected or indirectly connected over an intermediate medium. The term “coupled” may, for example, indicate that two or more components have direct physical contact or electrical contact. However, the term “coupled” or “connectively coupled” may also mean that two or more components are not in direct contact with each other, but still cooperate or interact with each other. The embodiments disclosed herein are not necessarily limited to the contents herein.

The expression “at least one of A, B and C” has the same meaning as the expression “at least one of A, B or C,” and each includes the following combinations of A, B and C: only A, only B, only C, a combination of A and B, a combination of A and C, a combination of B and C, and a combination of A, B and C.

The expression “A and/or B” includes the following three combinations: only A, only B, and a combination of A and B.

The term “about,” “roughly” or “approximately” as used herein includes a stated value and an average value within an acceptable deviation range of a specific value, and the acceptable deviation range is determined by a person of ordinary skill in the art in consideration of the measurement in question and an error associated with the measurement of a specific quantity (i.e., caused by limitations of a measuring system).

The term “parallel,” “perpendicular” and “equal” as used herein include a stated situation and a situation similar to the stated situation, the range of the similar situation is within an acceptable deviation range, and the acceptable deviation range is determined by a person of ordinary skill in the art in consideration of the measurement in question and an error associated with the measurement of a specific quantity (i.e., caused by limitations of a measuring system). For example, “parallel” includes absolute parallel and approximate parallel, wherein an acceptable deviation range of the approximate parallel may be, for example, within 5 degrees; and “perpendicular” includes absolute perpendicular and approximate perpendicular, wherein an acceptable deviation range of the approximate perpendicular may also be, for example, within 5 degrees. “Equal” includes absolute equal and approximate equal, wherein an acceptable deviation range of the approximate equal may be that, for example, a difference value between the approximately equal two is less than or equal to 5% of either one.

It should be understood that in the case that it is described that a layer or element is disposed on another layer or base plate, it may be that the layer or element is directly disposed on another layer or base plate, or there may be an intermediate layer between the layer or element and another layer or base plate.

Embodiments are described herein with reference to sectional views and/or plan views as idealized exemplary accompanying drawings. In the accompanying drawings, the thickness of the layer and the area of the region are enlarged for clarity. Therefore, variations in shape relative to the accompanying drawings due to, for example, manufacturing techniques and/or tolerances can be envisaged. Therefore, the embodiments should not be interpreted as being limited to the shapes of the regions illustrated herein, but rather as including shape deviations resulting from, for example, manufacturing. For example, an illustrated rectangular etched region will generally have a curved feature. Therefore, the regions illustrated in the accompanying drawings are schematic in nature, and their shapes are not intended to illustrate the actual shapes of the regions of the device, and are not intended to limit the scope of the embodiments.

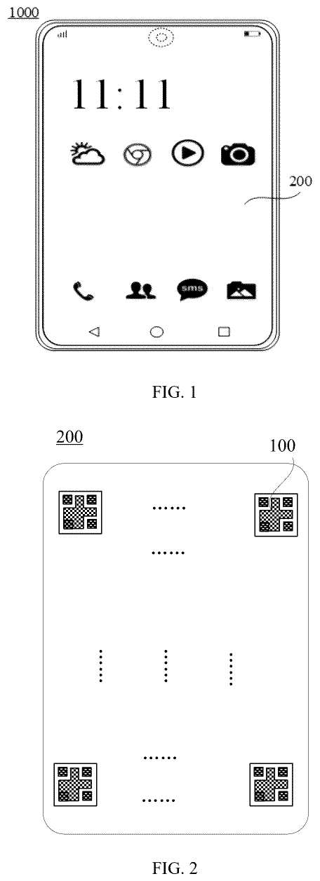

As illustrated in FIG. 1, a display apparatus is provided according to some embodiments of the present disclosure.

In some embodiments, the display apparatus is a light-emitting diode (LED) display apparatus, a mini light-emitting diode (Mini LED) display apparatus or a micro light-emitting diode (Micro LED) display apparatus.

The display apparatus according to the embodiments of the present disclosure may be any apparatus that can display not only moving object (e.g., a video) or fixed object (e.g., a still image) but also a text or an image. More specifically, it is contemplated that the embodiments may be implemented in or associated with a variety of electronic apparatuses. For example, the variety of electronic apparatuses include, but are not limited to, a mobile phone, a wireless apparatus, a personal data assistant (PDA), a handheld or portable computer, a GPS receiver/navigator, a camera, an MP4 video player, a video camera, a game console, a watch, a clock, a calculator, a television monitor, a flat panel display, a computer monitor, an automobile display (for example, an odometer display, or the like), a navigator, a cockpit controller and/or display, a camera view display (for example, a rear-view camera display in an vehicle), an electronic photograph, an electronic billboard or sign, a projector, a building structure, a packaging and aesthetic structure (for example, a display for an image of a piece of jewelry), and the like.

As illustrated in FIG. 1, a display apparatus is exemplified by a mobile phone 1000 in the embodiments of the present disclosure.

For example, the mobile phone 1000 includes a display base plate 200, a frame, a control circuit and other electronic accessories. The display base plate is disposed in the frame, and the control circuit is configured to provide an electric signal to the display base plate.

For example, the display base plate 200 is a display base plate 200 provided with a mini light-emitting diode (Mini LED) and quantum dots (QDs), or a display base plate 200 provided with a micro light-emitting diode (Micro LED) and QDs. The following takes the display base plate 200 provided with the Micro LED and the QDs as an example for introduction.

In some examples, as illustrated in FIG. 2, the display base plate 200 includes a plurality of light-emitting chips 100, and a driving circuit layer configured to drive the light-emitting chips 100 to emit light.

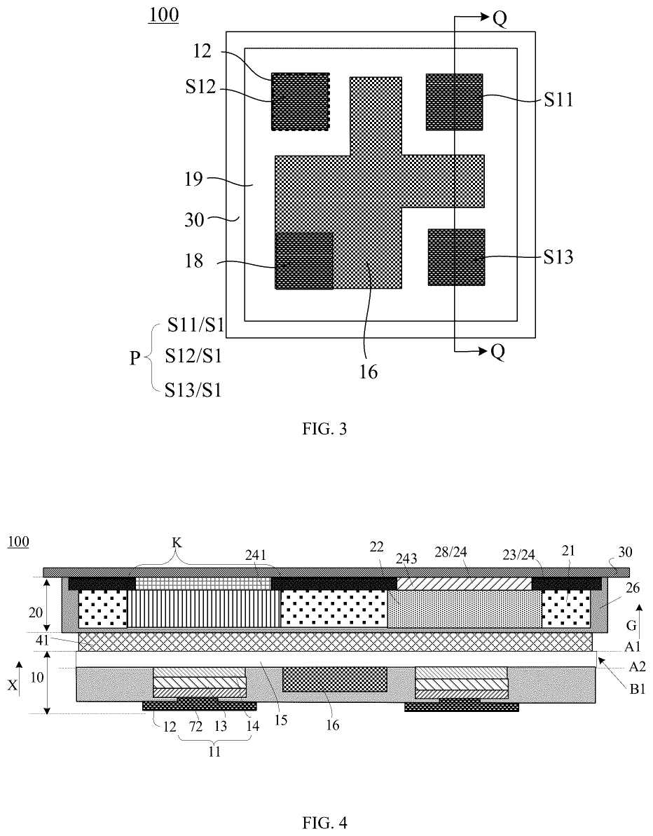

In some examples, as illustrated in FIG. 3, one light-emitting chip 100 is one pixel region P, and one pixel region P includes a plurality of sub-pixel regions S1. The plurality of sub-pixel regions S1 may include sub-pixel regions S1 different in emitted light colors.

In some embodiment, the plurality of sub-pixel regions are categorized to a first sub-pixel region S11, a second sub-pixel region S12 and a third sub-pixel region S13. The first sub-pixel region S11, the second sub-pixel region S12 and the third sub-pixel region S13 emit three primary colors of light, respectively. For example, the first sub-pixel region S11 emits red light, the second sub-pixel region S12 emits green light, and the third sub-pixel region S13 emits blue light.

In some embodiments, as illustrated in FIG. 4, the light-emitting chip 100 includes a light-emitting unit 10, a color converting unit 20 disposed on a light-emitting side G of the light-emitting unit 10, an adhesion connecting layer 41 configured to connect the light-emitting unit 10 and the color converting unit 20, and a first substrate 30 disposed on a side of the color converting unit 20 distal from the light-emitting unit 10.

In some examples, as illustrated in FIG. 4, the light-emitting unit 10 includes a plurality of light-emitting parts 11, one light-emitting part 11 being disposed in one sub-pixel region.

In some embodiments, the light-emitting part 11 is a blue light-emitting diode chip unit.

In some examples, as illustrated in FIG. 4, each light-emitting part 11 includes a first electrode 12, a current spreading layer 72, a first semiconductor layer 13, and a light-emitting layer 14 which are laminated in a first direction X. The light-emitting unit 10 further includes a second semiconductor layer 15 and a common electrode layer 16. The second semiconductor layer 15 may be disposed on light-emitting sides of the plurality of light-emitting parts 11 and may be electrically connected to the common electrode layer 16. The light-emitting unit 10 further includes a second electrode 18. The second electrode 18 may be disposed on a side distal from the color converting unit 20 and may be electrically connected to the common electrode layer 16.

It should be noted that in the embodiments of the present disclosure, the light-emitting part 11 may or may not be provided with the current spreading layer 72, which is not limited in the embodiments of the present disclosure.

In some examples, the first electrode 12 electrically connected to the first semiconductor layer 13 is an anode of the light-emitting part 11. The material of the first electrode 12 may be chromium, platinum, gold, tin, silver, or any combination thereof, but some embodiments of the present disclosure are not limited thereto.

In some examples, the second electrode 18 electrically connected to the second semiconductor layer 15 is a cathode of the light-emitting part 11. The material of each of the second electrode 18 and the common electrode layer 16 may be chromium, platinum, gold, tin, silver, or any combination thereof, but some embodiments of the present disclosure are not limited thereto.

In some examples, the light-emitting layer 14 is a multiple quantum well (MQW) layer. The first semiconductor layer 13 may be a second carrier transport layer, and the second semiconductor layer 15 may include a first carrier transport layer. Here, one of a first carrier and a second carrier is a hole and the other thereof is an electron. For example, in the case that the first carrier is a hole and the second carrier is an electron, the first semiconductor layer 13 is a P-type gallium nitride (P-GaN) layer, and the second semiconductor layer 15 includes an N-type gallium nitride (N-GaN) layer. The material of the current spreading layer 72 includes indium tin oxide.

In some embodiments, in the case that different voltages are applied to the first electrode 12 and the second electrode 18 to form an electric field therebetween, a PN junction with a potential barrier is formed between the first semiconductor layer 13 and the second semiconductor layer 15, and carriers in the first semiconductor layer 13 and carriers in the second semiconductor layer 15 enter the light-emitting layer 14 and recombine. In this case, excess energy will be released in the form of light, such that electric energy can be directly converted into light energy to enable the light-emitting part 14 to emit light.

In some examples, the adhesion connecting layer 41 is a bonding adhesive layer. In some embodiments, the adhesion connecting layer 41 is a benzocyclobutene (BCB) layer. In this case, a refractive index of the adhesion connecting layer 41 is about 1.56, but it is not limited in some embodiments of the present disclosure.

In some examples, as illustrated in FIG. 4, the color converting unit 20 includes a defining dam layer 21. Here, a plurality of opening regions K are defined on the defining dam layer 21, one light-emitting part 11 corresponding to one opening region K in the first direction X. The color converting unit 20 may further include optical functional parts 22 disposed in the opening regions K of the defining dam layer 21. The first direction X is a direction in which the light-emitting unit 10 and the color converting unit 20 are laminated. It should be noted that each light-emitting part 11 in the light-emitting unit 10 may be configured to emit a first light ray, and at least part of the optical functional units 22 in the color converting unit 20 are configured to convert the color of an incident first light ray.

In some embodiments, the material of the optical functional part 22 includes a quantum dot (QD), which can emit a light ray with a predetermined color by applying an electric field or light pressure thereon. For example, the quantum dot can absorb short-wave blue light and excite long-wave red light and green light, and such a characteristic enables the quantum dot to change the color of a light ray emitted by a light source.

The color converting unit 20 further includes a light filtering layer 24, and the light filtering layer 24 includes a plurality of light filtering parts 28. The plurality of light filtering parts 28 includes a first light filtering part 241 (not illustrated in the figure, referring to FIG. 23), a second light filtering part 242 and a third light filtering part 243. For example, the first light filtering part 241 is a red light filtering part, the second light filtering part 242 is a green light filtering part, and the third light filtering part 243 is a blue light filtering part. All light filtering parts in the light filtering layer 24 are configured to filter light rays of other colors different from light rays of corresponding colors among the light rays emitted from the optical functional parts 22, so as to transmit light rays of three primary colors for color display (for example, the first light filtering part 241 can only transmit a red light ray, the second light filtering part 242 can only transmit a blue light ray, and the third light filtering part 243 can only transmit a green light ray), thereby achieving full-color display. For example, the light filtering parts are separated by disposing light shielding layers 23 between different light filtering parts (including the first light filtering part 241, the second light filtering part 242 and the third light filtering part 243), thereby preventing color crosstalk between different light filtering parts and avoid an adverse effect on the display effect.

In some other embodiments, the first light filtering part 241 and the second light filtering part 242 are both be yellow filtering parts that can filter blue light but allow red light and green light to pass through.

In some examples, a method for preparing the light-emitting chip 100 includes: separately manufacturing the light-emitting unit 10 and the color converting unit 20, and forming the light-emitting chip 100 by adhering the light-emitting unit 10 and the color converting unit 20 using the adhesion connecting layer 41. In this way, the transfer efficiency of a Micro-LED is improved, the chip thickness is reduced, the preparation accuracy and a product yield are improved. The fitting effect of the adhesion connecting layer 41 may be a gluing effect or a metal bonding effect. Please refer to the following contents for details, which are not described herein.

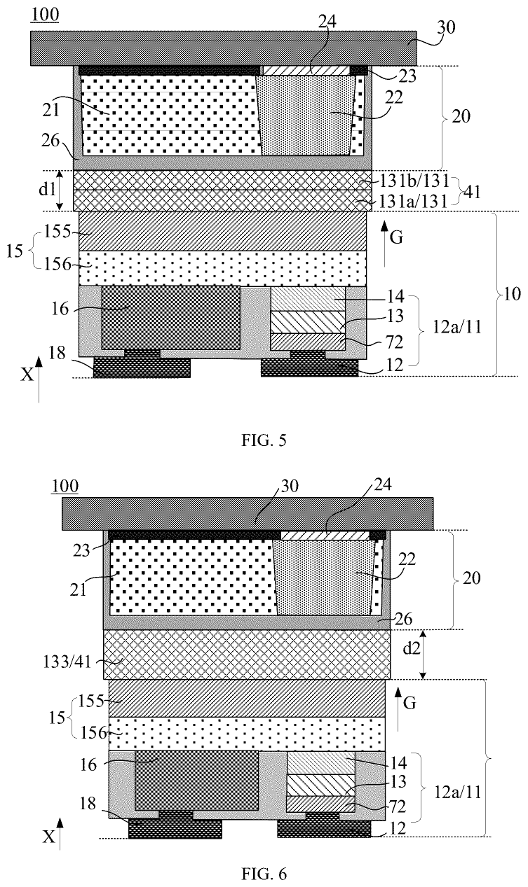

In some embodiments, as illustrated in FIGS. 5 to 7, the adhesion connecting layer 41 is any one of an indium zinc oxide bonding layer 131, a metal bonding layer 132 or an adhesive layer 133.

In some examples, as illustrated in FIG. 5, the adhesion connecting layer 41 is the indium zinc oxide bonding layer 131. The indium zinc oxide bonding layer 131 includes a first indium zinc oxide layer 131a and a second indium zinc oxide layer 131b which are laminated along the first direction X, and the first indium zinc oxide layer 131a and the second indium zinc oxide layer 131b are connected by a bonding effect of molecular bonds. The first indium zinc oxide layer 131a and the light-emitting unit 10 are laminated and connected, and the second indium zinc oxide layer 131b and the color converting unit 20 are laminated and connected. By the bonding effect of the molecular bonds between the first indium zinc oxide layer 131a and the second indium zinc oxide layer 131b, adhesion between the light-emitting unit 10 and the color converting unit 20 is achieved, thereby forming the light-emitting chip 100.

In some examples, as illustrated in FIG. 6, the adhesion connecting layer 41 is the adhesive layer 133. In some embodiments, the material of the adhesive layer 133 is an organic adhesive material of epoxy resin. The adhesion between the light-emitting unit 10 and the color converting unit 20 is achieved by the adhesion effect of the adhesive layer 133, thereby forming the light-emitting chip 100. The specific preparation method is as follows, and details thereof are not described herein.

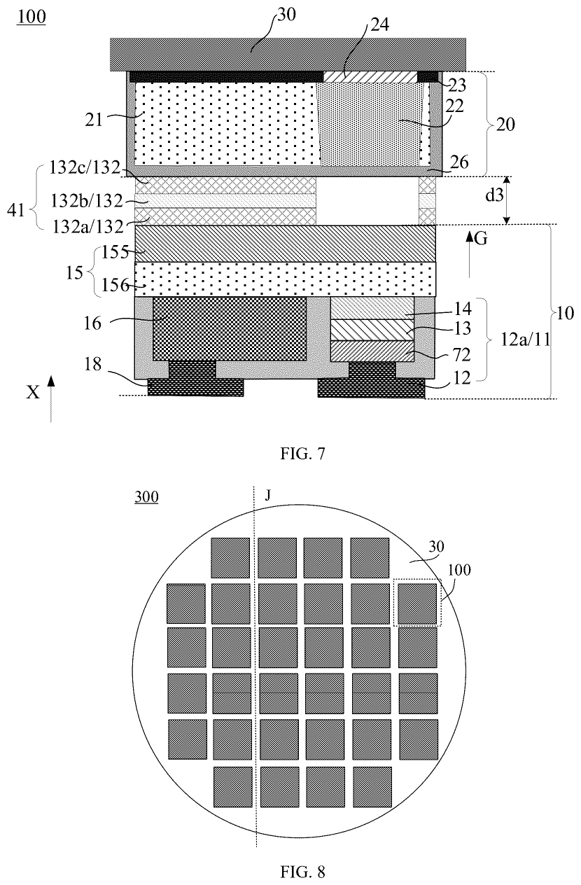

In some examples, as illustrated in FIG. 7, the adhesion connecting layer 41 is the metal bonding layer 132. The metal bonding layer 132 includes a first metal sub-layer 132a, a second metal sub-layer 132b and a third metal sub-layer 132c which are laminated along the first direction X. The second metal sub-layer 132b is disposed as a eutectic alloy layer for connecting the first metal sub-layer 132a and the third metal sub-layer 132c.

The first metal sub-layer 132a and the light-emitting unit 10 are laminated and connected, and the third metal sub-layer 132c and the color converting unit 20 are laminated and connected. By the eutectic alloy layer (the second metal sub-layer 132b), the first metal sub-layer 132a and the third metal sub-layer 132c are connected and the light-emitting unit 10 and the color converting unit 20 are bonded, thereby forming the light-emitting chip 100.

In some examples, the method for preparing the light-emitting chip 100 includes: preparing an initial light-emitting unit 120 and the color converting unit 20, forming the adhesion connecting layer 41, acquiring the light-emitting unit 10 by adhering the initial light-emitting unit 120 and the color converting unit 20, and forming the light-emitting chip 100. In order to describe the technical solutions more clearly, three embodiments are provided hereinafter to introduce the method for preparing the light-emitting chip 100.

It should be noted that in order to clearly illustrate the method for preparing the light-emitting chip 100, the formation of one light-emitting chip 100 is described hereinafter. It can be understood that the method for preparing the light-emitting chip 100 includes: forming a wafer 300 including a plurality of light-emitting chips 100 disposed in an array, and forming the single light-emitting chip 100 by dicing the wafer 300. The structure of the wafer 300 is illustrated in FIG. 8.

The first embodiment of the method for preparing the light-emitting chip 100 is described hereinafter, and the light-emitting chip 100 illustrated in FIG. 5 is formed according to this embodiment. It should be noted that in the process of preparing the light-emitting chip 100, the structural example of the light-emitting chip 100 can be understood by referring to the content illustrated in FIG. 5 and the process diagram.

### First Embodiment

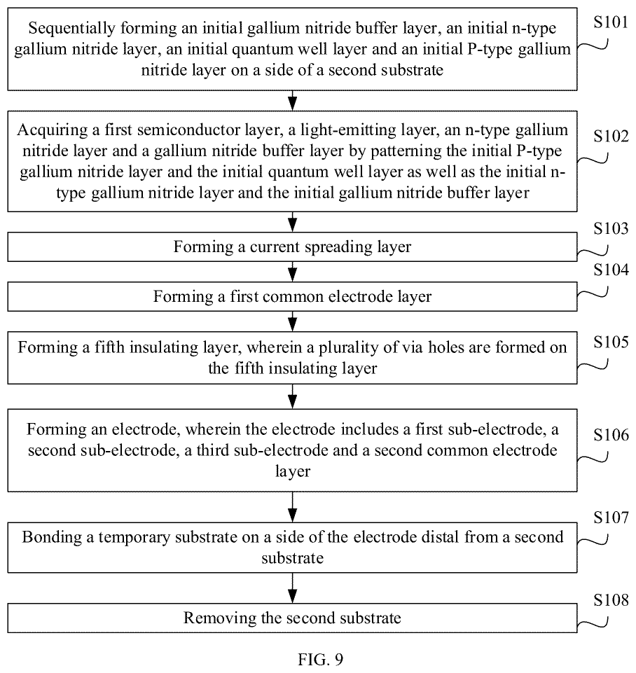

For example, as illustrated in FIG. 9, preparation processes of the initial light-emitting unit 120 include S101 to S108.

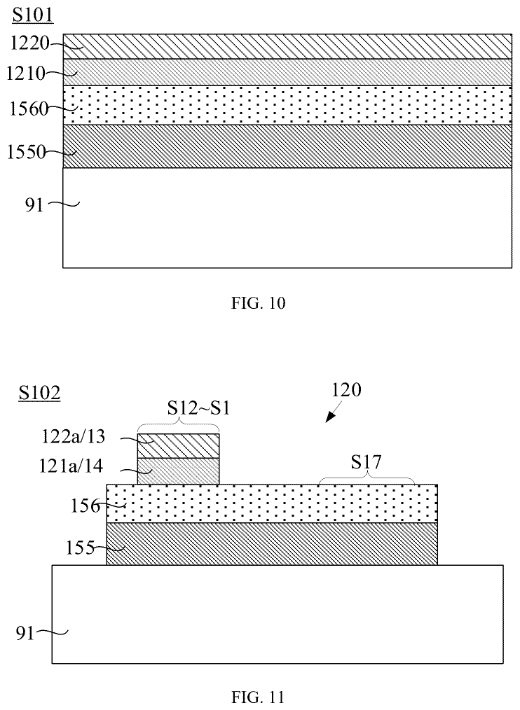

In S101, as illustrated in FIG. 10, an initial gallium nitride buffer layer 1550, an initial n-type gallium nitride layer 1560, an initial quantum well layer 1210 and an initial P-type gallium nitride layer 1220 are sequentially formed on a side of a second substrate 91.

In some embodiments, the second substrate 91 is any one of a sapphire substrate or a silicon-based substrate.

In some embodiments, the initial quantum well layer 1210 is a blue quantum well layer, and the light-emitting part 11 (not illustrated in the figure, see FIG. 5) formed by the blue quantum well layer emits blue light.

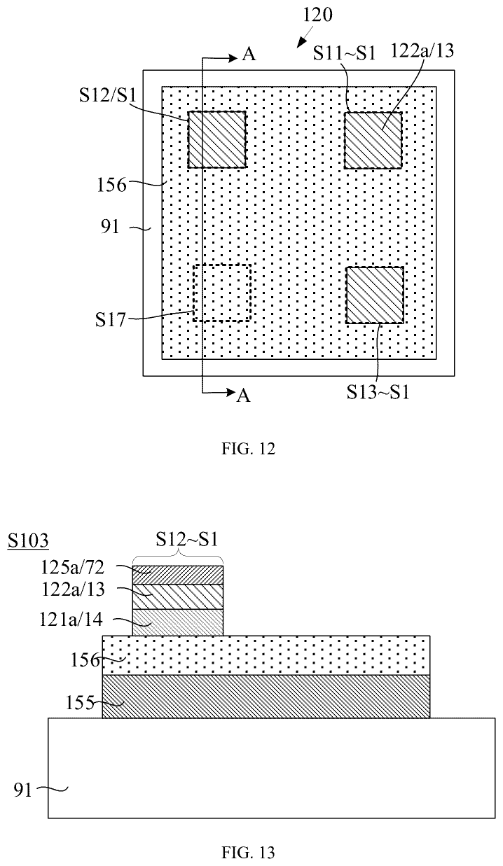

In S102, as illustrated in FIGS. 11 and 12, the first semiconductor layer 13, the light-emitting layer 14, the n-type gallium nitride layer 156 and the gallium nitride buffer layer 155 are acquired by patterning the initial P-type gallium nitride layer 1220 and the initial quantum well layer 1210 as well as the initial n-type gallium nitride layer 1560 and the initial gallium nitride buffer layer 1550.

In some embodiments, the initial quantum well layer 1210 and the initial P-type gallium nitride layer 1220 are patterned by a photolithographic process, and the initial quantum well layer 1210 and the initial P-type gallium nitride layer 1220 are removed in a region between adjacent light-emitting parts 11 and a cathode region S17.

For example, as illustrated in FIGS. 11 and 12, the initial light-emitting unit 120 includes three sub-pixel regions S1 and one cathode region S17. The three sub-pixel regions S1 are a first sub-pixel region S11, a second sub-pixel region S12 and a third sub-pixel region S13, respectively. The initial quantum well layer 1210 and the initial P-type gallium nitride layer 1220 are patterned by a photolithography process, and the initial quantum well layer 1210 and the initial P-type gallium nitride layer 1220 are removed from regions other than the three sub-pixel regions S1 and the cathode region S17. It can be understood that the three sub-pixel regions S1 are light-emitting regions of the light-emitting chip 100. That is, the sub-pixel regions S1 and the cathode region S17 are also the sub-pixel regions S1 and the cathode region S17 of the light-emitting chip 100.

The plurality of light-emitting parts 11 of the light-emitting unit 10 includes a first light-emitting part 12a, a second light-emitting part 12b and a third light-emitting part 12c. The first light-emitting part 12a is disposed in the first sub-pixel region S11, the second light-emitting part 12b is disposed in the second sub-pixel region S12, and the third light-emitting part 12c is disposed in the third sub-pixel region S13. The cathode region S17 is configured to form a part of the common electrode layer 16 and the second electrode 18. Details of the introduction of the common electrode layer 16 are referred to the following content, which will not be described herein.

As illustrated in FIGS. 11 and 12, a first quantum well layer 121a and a first p-type gallium nitride layer 122a of the first light-emitting part 12a, a second quantum well layer and a second p-type gallium nitride layer of the second light-emitting part 12b, and a third quantum well layer and a third p-type gallium nitride layer of the third light-emitting part 12c are formed in this process. FIG. 11 is a sectional view of FIG. 12 taken along a sectional line AA.

In some embodiments, the n-type gallium nitride layer 156 and the gallium nitride buffer layer 155 are formed by patterning the initial n-type gallium nitride layer 1560 and the initial gallium nitride buffer layer 1550 using a photolithography process, wherein the n-type gallium nitride layer 156 is a conductive layer for connecting the first light-emitting part 12a, the second light-emitting part 12b, the third light-emitting part 12c and the common electrode layer 16.

In S103, as illustrated in FIG. 13, a current spreading layer 72 is formed.

In some embodiments, an initial current spreading layer is formed, and the current spreading layer 72 is formed by patterning the initial current spreading layer using a photolithography process The current spreading layer 72 includes a first current spreading layer 125a disposed in the first sub-pixel region S11, a second current spreading layer disposed in the second sub-pixel region S12 (not illustrated in the figure, see FIG. 12) and a third current spreading layer disposed in the third sub-pixel region S13 (not illustrated in the figure, see FIG. 12).

The material of the current spreading layer 72 is indium tin oxide (ITO), and the current spreading layer 72 is disposed in the sub-pixel region S1, which is beneficial to the transmission of holes and improves the electrical performance of the light-emitting chip 100.

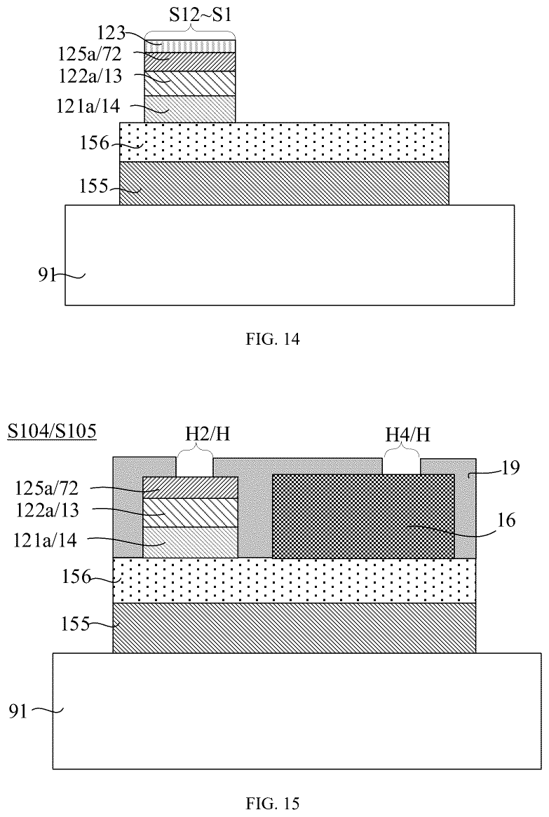

In some examples, as illustrated in FIG. 14, the method for preparing the initial light-emitting unit 120 further includes a process of forming a reflective metal layer 123

In some embodiments, an initial reflective metal layer is formed on a side of the current spreading layer 72 distal from the second substrate 91, and the reflective metal layer 123 of each light-emitting part 11 is formed by patterning the initial reflective metal layer using a photolithography process. The reflective metal layer 123 has the function of reflecting light rays, which can increase a light output rate of the light-emitting part 11.

It should be noted that in the following accompanying drawings, the reflective metal layer 123 is not illustrated.

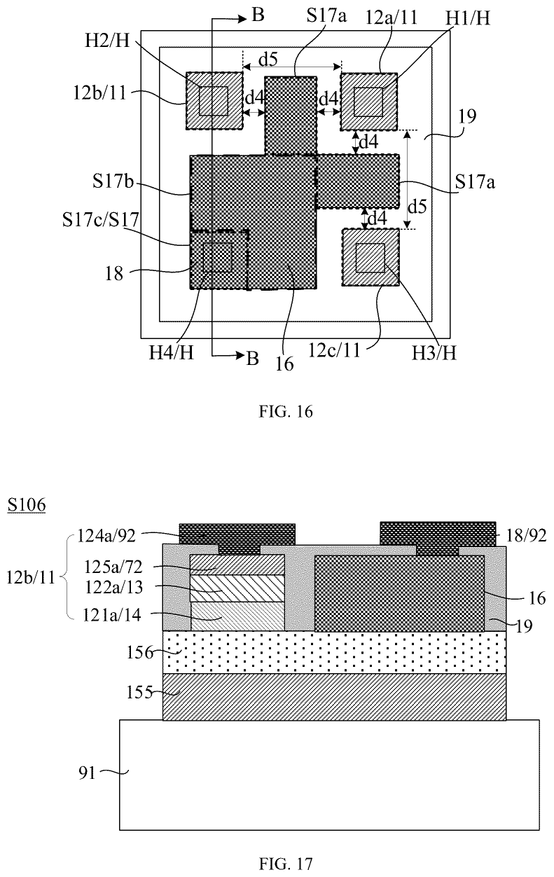

In S104, as illustrated in FIGS. 15 and 16, a common electrode layer 16 is formed. FIG. 15 is a sectional view of FIG. 16 taken along a sectional line BB

In some embodiments, the common electrode layer 16 is formed by a photolithography process.

In some embodiments, the material of the common electrode layer 16 is titanium, aluminum, nickel, gold, or any combination thereof.

In some embodiments, as illustrated in FIG. 16, the common electrode layer 16 includes a first portion S17c covering the cathode region S17, and a second portion S17b disposed between the common electrode layer 16 and the light-emitting part 11 adjacent thereto.

As illustrated in FIG. 16, the common electrode layer 16 further includes a portion disposed between two adjacent light-emitting parts 11. The common electrode layer 16 has the function of connecting the n-type gallium nitride layer 156 and elevating the second electrode 18 (not illustrated in the figure, see FIG. 17). The portion of the common electrode layer 16 disposed between two adjacent light-emitting parts 11 is referred to as a third portion S17a. By disposing the second portion S17b of the common electrode layer 16 between the common electrode layer 16 and the light-emitting parts 11 adjacent thereto and disposing the third portion S17a between the light-emitting parts 11, not only can the light-emitting chip 100 be reinforced and prevented from cracking, but also the volume of the common electrode layer 16 can be increased, such that a spreading effect on the current is achieved, and the resistance of the light-emitting chip 100 is reduced.

In some examples, as illustrated in FIG. 16, the portion of the common electrode layer 16 disposed between two adjacent light-emitting parts 11 has a distance d4 from each of the two light-emitting parts 11. A range of the distance d4 between each light-emitting part 11 and the common electrode layer 16 is 1/10 to ⅓ of a range of a distance d5 between the two adjacent light-emitting parts 11.

In some embodiments, the range of the distance d4 between the light-emitting part 11 and the common electrode layer 16 is 1/10, ¼ or ⅓ of the range of the distance d5 between two adjacent light-emitting parts 11, which is not limited herein.

By disposing the third portion S17a between the two adjacent light-emitting parts 11 and setting the range of the distance d4 between the light-emitting part 11 and the common electrode layer 16 to be 1/10 to ⅓ of the range of the distance d5 between the two adjacent light-emitting parts 11, the area of the common electrode layer 16 can be increased while ensuring an opening ratio of the region where the light-emitting parts 11 of the light-emitting chip 100 are disposed, thereby reducing the resistance of the light-emitting chip 100, preventing the light-emitting chip 100 from cracking and improving the stability of the light-emitting chip 100.

In some embodiments, as illustrated in FIG. 16, the range of the distance d4 between the light-emitting part 11 and the common electrode layer 16 is 8 μm to 10 μm.

In some embodiments, the distance d4 between the light-emitting part 11 and the common electrode layer 16 is 8 μm, 9 μm, 10 μm or the like, which is not limited herein.

In S105, as illustrated in FIGS. 15 and 16, a fifth insulating layer 19 is formed, wherein a plurality of via holes H are formed in the fifth insulating layer 19.

In some embodiments, an initial insulating layer is formed on a side of the common electrode layer 16 distal from the second substrate 91 using a deposition process, and a plurality of via holes H is formed using a photolithography process. As illustrated in FIG. 16, the plurality of via holes H includes a first via hole H1, a second via hole H2, a third via hole H3 and a fourth via hole H4. The first via hole H1 is disposed corresponding to the first light-emitting part 12a, the second via hole H2 is disposed corresponding to the second light-emitting part 12b, the third via hole H3 is disposed corresponding to the third light-emitting part 12c, and the fourth via hole H4 is disposed corresponding to the cathode region S17.

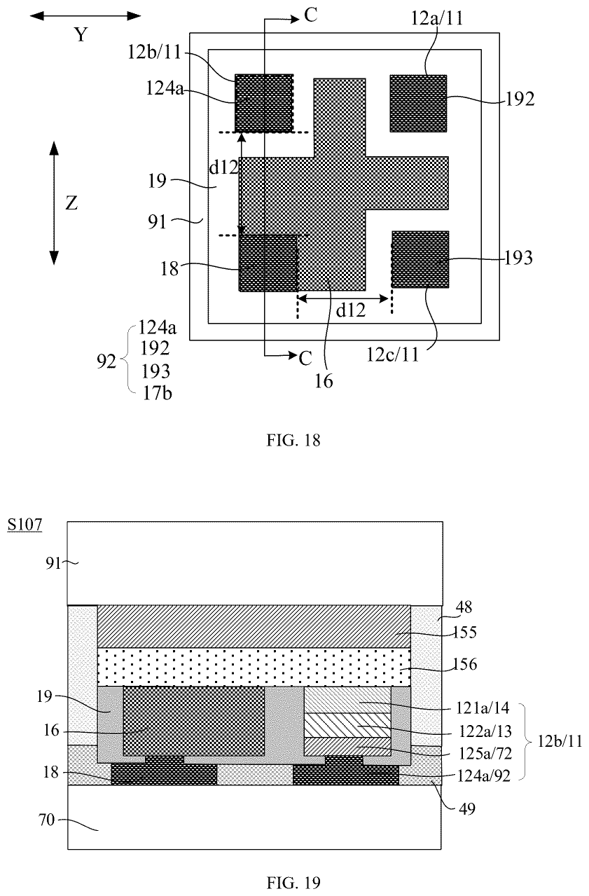

In S106, as illustrated in FIGS. 17 and 18, an electrode 92 is formed, wherein the electrode 92 includes a first sub-electrode 124a, a second sub-electrode 192, a third sub-electrode 193 and a second electrode 18. FIG. 17 is a sectional view of FIG. 18 taken along a sectional line CC.

The first sub-electrode 124a, the second sub-electrode 192 and the third sub-electrode 193 are referred to as the first electrode 12.

In some embodiments, the electrode 92 is formed by a patterning process. The first sub-electrode 124a is disposed corresponding to the first light-emitting part 12a, the second sub-electrode 192 is disposed corresponding to the second light-emitting part 12b, and the third sub-electrode 193 is disposed corresponding to the third light-emitting part 12c.

In S107, as illustrated in FIG. 19, a temporary substrate 70 is bonded on a side of the electrode 92 distal from the second substrate 91.

In some embodiments, the temporary substrate 70 is temporarily bonded using a temporary adhesive layer 48 and an adhesive release layer 49, wherein the temporary adhesive layer 48 has an adhesion effect, and the adhesive release layer 49 can achieve adhesive release under the irradiation of a target light ray (for example, ultraviolet light and/or laser). The temporary adhesive layer 48 and the adhesive release layer 49 have a function of achieving the temporary adhesion of the temporary substrate 70.

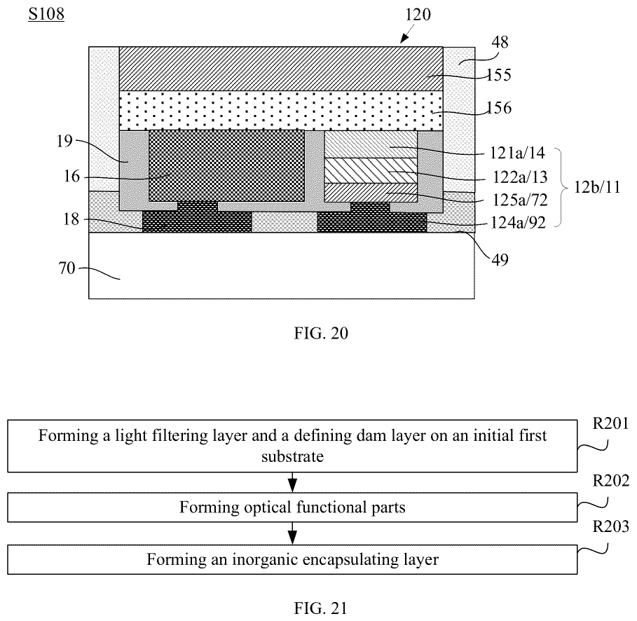

In S108, as illustrated in FIG. 20, the second substrate 91 is removed.

The initial light-emitting unit 120 is formed after the second substrate 91 is removed.

In some embodiments, the second substrate 91 is a sapphire substrate, and the sapphire substrate is peeled off by laser.

In some embodiments, the second substrate 91 is a silicon-based substrate, and the temporary substrate 70 is protected by an acid-proof film or wax sealing. The initial light-emitting unit 120 is placed in a hydrofluoric acid (HF) etching tank, and the second substrate 91 is removed by etching.

It can be understood that compared with the light-emitting unit 10, the initial light-emitting unit 120 is provided with the temporary substrate 70 on the side of the electrode 92 distal from the gallium nitride buffer layer 155. The light-emitting unit 10 is acquired by removing the temporary substrate 70, and the adhesion connecting layer 41 and the adhesive release layer 49 which are on the initial light-emitting unit 120

The following describes the preparation processes of the color converting unit 20. As illustrated in FIG. 21, processes R201 to R203 are included.

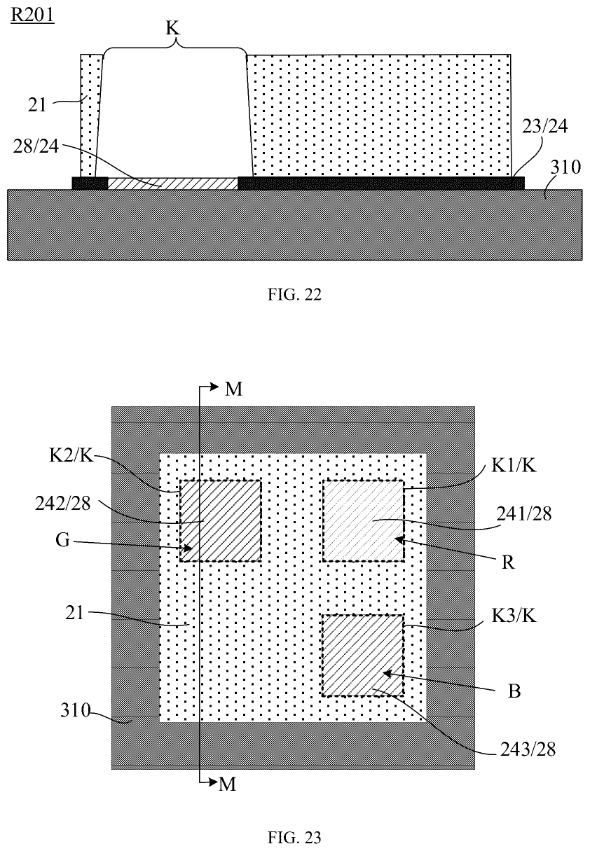

In R201, as illustrated in FIG. 22, a light filtering layer 24 and a defining dam layer 21 are formed on an initial first substrate 310.

The light filtering layer 24 includes a plurality of light filtering parts 28, and the defining dam layer 21 is disposed on a side of the light filtering layer 24 distal from the initial first substrate 310.

In some embodiments, the initial first substrate 310 is a glass substrate. For example, the first substrate 310 is transparent to visible light.

In some embodiments, a light shielding layer 23 and the plurality of light filtering parts 28 are formed by coating, exposure, development, post-baking, and the like. For example, as illustrated in FIG. 23, the plurality of light filtering parts 28 includes a first light filtering part 241, a second light filtering part 242 and a third light filtering part 243. For example, the first light filtering part 241 is a red light filtering part, the second light filtering part 242 is a green light filtering part, and the third light filtering part 243 is a blue light filtering part. FIG. 22 is a sectional view of FIG. 23 taken along a sectional line MM.

In some embodiments, as illustrated in FIG. 22, a defining dam layer 21 is formed on a side of the light shielding layer 23 distal from the initial first substrate 310 by coating, exposure, development, post-baking, and the like, and a plurality of opening regions K are defined on the defining dam layer 21. For example, as illustrated in FIG. 23, the plurality of opening regions K includes a first opening region K1, a second opening region K2 and a third opening region K3.

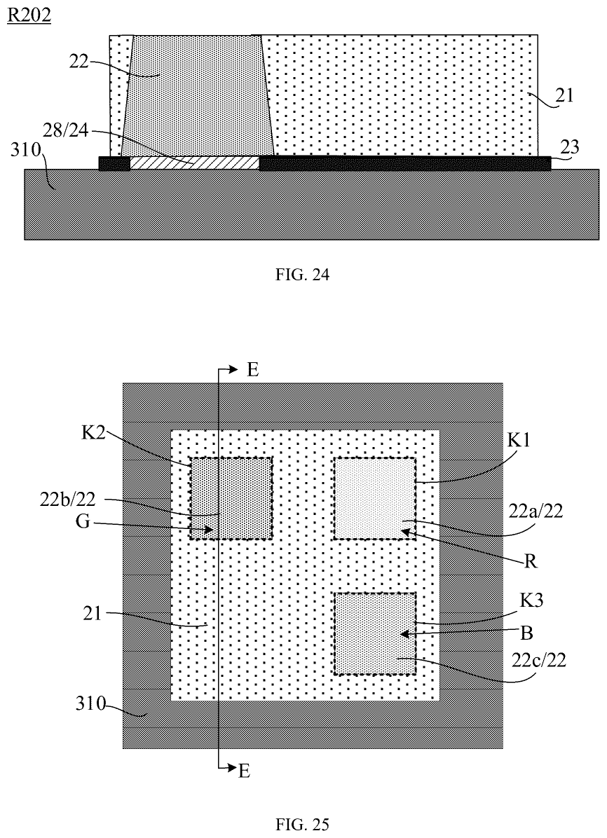

In R202, as illustrated in FIG. 24, an optical functional part 22 is formed.

In some embodiments, as illustrated in FIG. 25, the optical functional parts 22 are manufactured in the first opening K1, the second opening K2 and the third opening K3 by coating, exposure, development, post-baking and the like, or by ink-jet printing. In some embodiments, the optical functional parts 22 include a first optical functional part 22a, a second optical functional part 22b and a third optical functional part 22c. The first optical functional part 22a is formed in the first opening region K1; the second optical functional part 22b is formed in the second opening region K2; and the third optical functional part 22c is formed in the third opening region K3. FIG. 24 is a sectional view of FIG. 25 taken along a sectional line EE.

In some embodiments, as illustrated in FIGS. 18 and 25, the light-emitting chip 100 has a red sub-pixel R, a green sub-pixel G and a blue sub-pixel B. As illustrated in FIG. 18, the plurality of light-emitting parts 11 includes a first light-emitting part 12a, a second light-emitting part 12b and a third light-emitting part 12c. The first light-emitting part 12a, the second light-emitting part 12b and the third light-emitting part 12c are all configured to emit first light rays, and the first light ray emitted by each of the first light-emitting part 12a, the second light-emitting part 12b and the third light-emitting part 12c includes at least one of blue light or ultraviolet light. The first light-emitting part 12a and the second light-emitting part 12b are disposed in a row in a second direction Y, and the first light-emitting part 12a and the third light-emitting part 12c are disposed in a row in a third direction Z. The second direction Y intersects with the third direction Z, and both the second direction Y and the third direction Z intersect with the first direction X. For example, the second direction Y is perpendicular to the third direction Z, and both the second direction Y and the third direction Z are perpendicular to the first direction X.

As illustrated in FIGS. 18 and 25, the first optical functional part 22a is configured to convert the first light ray into red light. In some embodiments, red quantum dots that convert the first light ray into the red light are included in the first optical functional part 22a. In some embodiments, scattering particles configured to scatter light rays are further included in the first optical functional part 22a. Here, after the first light ray emitted by the first light-emitting part 12a is irradiated to the first optical functional part 22a distributed in the first opening region K1, the first light ray can be converted into the red light by the red quantum dots, and the first light ray and the red light can be scattered by the scattering particles, such that more first light rays can be ensured to be converted into the red light by the red quantum dots, and an emergent angle of the red light can be ensured to be larger, thereby ensuring that a viewing angle of the display base plate 200 integrated with the light-emitting chip 100 is larger. For this purpose, the red sub-pixel R in the light-emitting chip 100 may include the first light-emitting part 12a and the first optical functional part 22a.

The second optical functional part 22b is configured to convert the first light ray into green light. In some embodiments, green quantum dots that convert the first light ray into the green light are included in the second optical functional part 22b. In some embodiments, scattering particles configured to scatter light rays are further included in the second optical functional part 22b. Here, after the first light ray emitted by the second light-emitting part 12b is irradiated to the second optical functional part 22b distributed in the second opening region K2, the first light ray can be converted into the green light by the green quantum dots, and the first light ray and the green light can be scattered by the scattering particles, such that more first light rays can be ensured to be converted into the green light by the green quantum dots, and an emergent angle of the green light can be ensured to be larger, thereby ensuring that a viewing angle of the display base plate 200 integrated with the light-emitting chip 100 is larger. For this purpose, the green sub-pixel G in the light-emitting chip 100 may include the second light-emitting part 12b and the second optical functional part 22b.

The third optical functional part 22c is configured to convert the first light ray into blue light or maintain blue light emission In some embodiments, in the case that the first light ray only contains blue light, the third optical functional part 22c is a transparent part or includes blue quantum dots. The transparent part is configured to directly transmit the first light ray, and the blue quantum dots are configured to convert the first light ray into the blue light with different wavelengths from the first light ray. In some embodiments, scattering particles configured to scatter light rays are further included in the third optical functional part 22c. Here, after the first light ray emitted by the third light-emitting part 12c is irradiated to the third optical functional part 22c distributed in the third opening region K3, the first light ray can be scattered by the scattering particles, thereby ensuring that the emergent angle of the blue light is larger, and further ensuring that the viewing angle of the display base plate 200 integrated with the light-emitting chip 100 is larger. For example, in the case that the first light ray contains ultraviolet light, the third optical functional part 22c includes blue quantum dots configured to convert the first light ray into blue light, or scattering particles configured to scatter light rays and blue quantum dots configured to convert the ultraviolet light into the blue light are both distributed in the third optical functional part 22c. Here, after the first light ray emitted by the third light-emitting part 12c is irradiated to the third optical functional part 22c distributed in the third opening region K3, the ultraviolet light in the first light ray can be converted into the blue light by the blue quantum dots, and the first light ray and the blue light can be scattered by the scattering particles, such that more ultraviolet light can be ensured to be converted into the blue light by the blue quantum dots, and an emergent angle of the blue light can be ensured to be larger, thereby ensuring that a viewing angle of the display base plate 200 integrated with the light-emitting chip 100 is larger. For this purpose, the blue sub-pixel B in the light-emitting chip 100 may include the third light-emitting part 12c and the third optical functional part 22c.

In the embodiments of the present disclosure, as illustrated in FIGS. 23 and 24, the color converting unit 20 in the light-emitting chip 100 may further include a light filtering layer 24. The light filtering layer 24 includes a plurality of light filtering parts 28.

In some embodiments, as illustrated in FIGS. 23 and 25, the light filtering parts 28 include a first light filtering part 241, a second light filtering part 242 and a third light filtering part 243. Here, the first light filtering part 241 may be corresponding to the first optical functional part 22a, the third light filtering part 243 may be corresponding to the third optical functional part 22c, and the second light filtering part 242 may be corresponding to the second optical functional part 22b. For this purpose, the red sub-pixel R in the light-emitting chip 100 may further include a first filtering part 241; the green sub-pixel G in the light-emitting chip 100 may further include a second filtering part 242; and the blue sub-pixel B in the light-emitting chip 100 may further include a third filtering part 243.

For example, the first light rays emitted by the first light-emitting part 12a, the second light-emitting part 12b and the third light-emitting part 12c in the plurality of light-emitting parts 11 are all blue light. The first light filtering part 241 is a red color stopping block which can transmit red light and absorb light rays of other colors. In this way, after passing through the first light filtering part 241, the light emitted from the first optical functional part 22a can be emitted, and the first light filtering part 241 can filter out light rays of other colors except the red light, so as to ensure that the red sub-pixel R in the light-emitting chip 100 can filter out the blue light component. It should be noted that in other embodiments, the first light filtering part 241 is a film layer configured to transmit red light and reflect the blue light ray. In this way, after the light ray emitted from the first optical functional part 22a is irradiated to the first light filtering part 241, the red light in these light rays can be re-emitted after passing through the first light filtering part 241, and the blue light in these light rays can be reflected back to the first optical functional part 22a by the first light filtering part 241, such that the red quantum dots in the first optical functional part 22a can excite the blue light into red light, thereby further improving the excitation efficiency of the red quantum dots.

For example, the first light rays emitted by the first light-emitting part 12a, the second light-emitting part 12b and the third light-emitting part 12c in the plurality of light-emitting parts 11 are all blue light. The second light filtering part 242 is a green color stopping block which can transmit green light and absorb light rays of other colors. In this way, after passing through the second light filtering part 242, the light emitted from the second optical functional part 22b can be emitted, and the second light filtering part 242 can filter out light rays of other colors except the green light, so as to ensure that the green sub-pixel G in the light-emitting chip 100 can filter out the blue light component. It should be noted that in other embodiments, the second light filtering part 242 is a film layer configured to transmit green light and reflect the blue light ray. In this way, after the light ray emitted from the second optical functional part 22b is irradiated to the second light filtering part 242, the green light in these light rays can be re-emitted after passing through the second light filtering part 242, and the blue light in these light rays can be reflected back to the second optical functional part 22b by the second light filtering part 242, such that the green quantum dots in the second optical functional part 22b can excite the blue light into green light, thereby further improving the excitation efficiency of the green quantum dots.

For example, the film structures of the first light filtering part 241 and the second light filtering part 242 may be the same, and may be prepared by the same process. For example, both that first light filtering part 241 and the second light filtering part 242 are film layers that transmit red and green light and reflect blue light.

For example, the first light rays emitted by the first light-emitting part 12a, the second light-emitting part 12b and the third light-emitting part 12c in the plurality of light-emitting parts 11 are all blue light, and the third light filtering part 243 is a blue color stopping block which can transmit blue light and absorb light rays of other colors. In this way, after passing through the third light filtering part 243, light rays emitted from the third optical functional part 22c can be emitted, and the third light filtering part 243 can filter out the light rays of other colors except the blue light, so as to ensure that the blue sub-pixel B in the light-emitting chip 100 can emit relatively pure blue light.

For example, the first light rays emitted by the first light-emitting part 12a, the second light-emitting part 12b and the third light-emitting part 12c in the plurality of light-emitting parts 11 are all blue light, and the second light filtering part 242 is a transparent block which can transmit blue light.

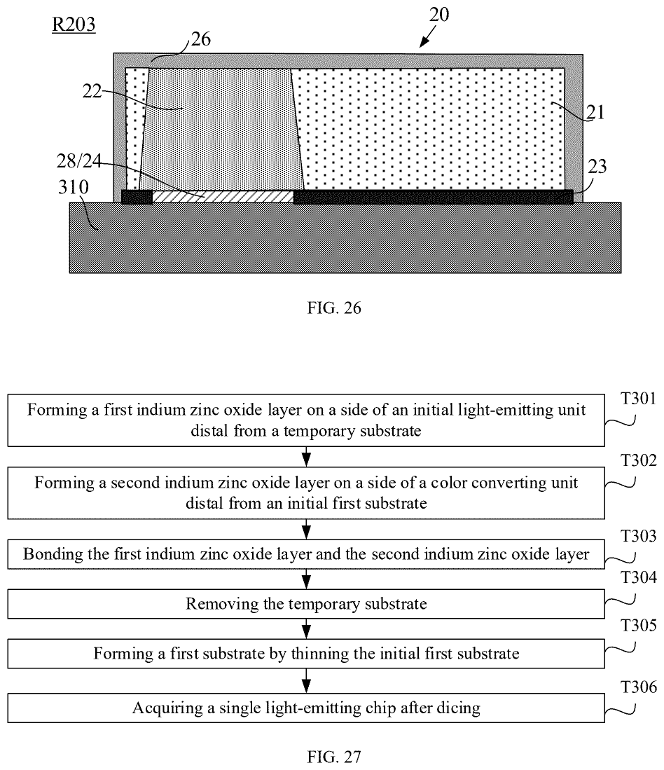

In R203, as illustrated in FIG. 26, an encapsulating layer 26 is formed.

After the encapsulating layer 26 is formed, the color converting unit 20 is acquired.

In some embodiments, the encapsulating layer 26 is deposited on a side of an initial first substrate 310 distal from the initial first substrate 310 by a CVD (chemical vapor deposition) process, and the encapsulating layer 26 covers the optical functional part 22 and the defining dam layer 21. That is, orthographic projections of both the optical functional part 22 and the dam-confining layer 21 on the first substrate 30 are within an orthographic projection of the encapsulating layer 26 on the first substrate 30. In this way, the optical functional part 22 and the dam-confining layer 21 are encapsulated integrally, which can isolate water and oxygen and improve the service life of the light-emitting chip 100.

The following describes the processes of forming an adhesion connecting layer 41 and forming a light-emitting chip 100 by cell aligning a color converting unit 20 and an initial light-emitting unit 120 using the adhesion connecting layer 41. As illustrated in FIG. 27, processes T301 to T306 are included.

In T301, as illustrated in FIG. 28, a first indium zinc oxide layer 131a is formed on a side of the initial light-emitting unit 120 distal from a temporary substrate 70.

That is, the first indium zinc oxide layer 131a is formed on a side of a gallium nitride buffer layer 155 distal from the temporary substrate 70.

In some embodiments, the first indium zinc oxide layer 131a is formed by a photolithography process.

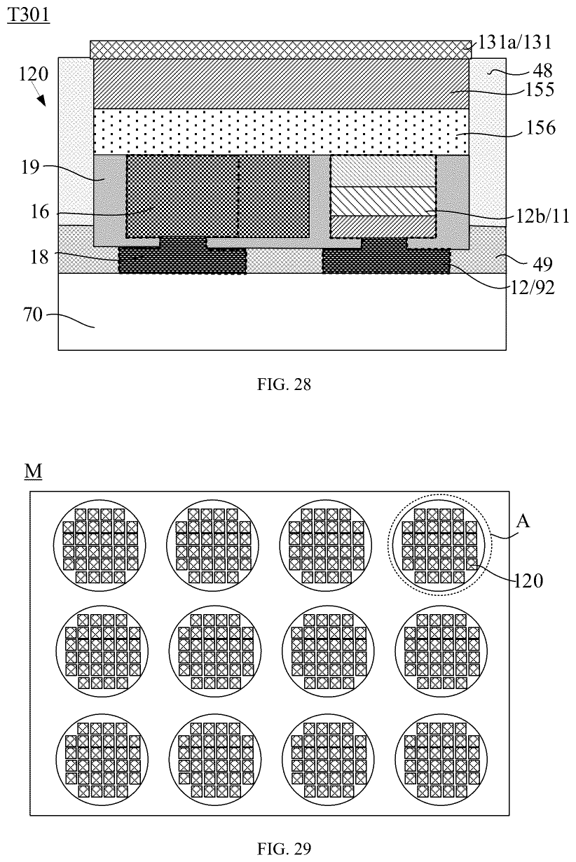

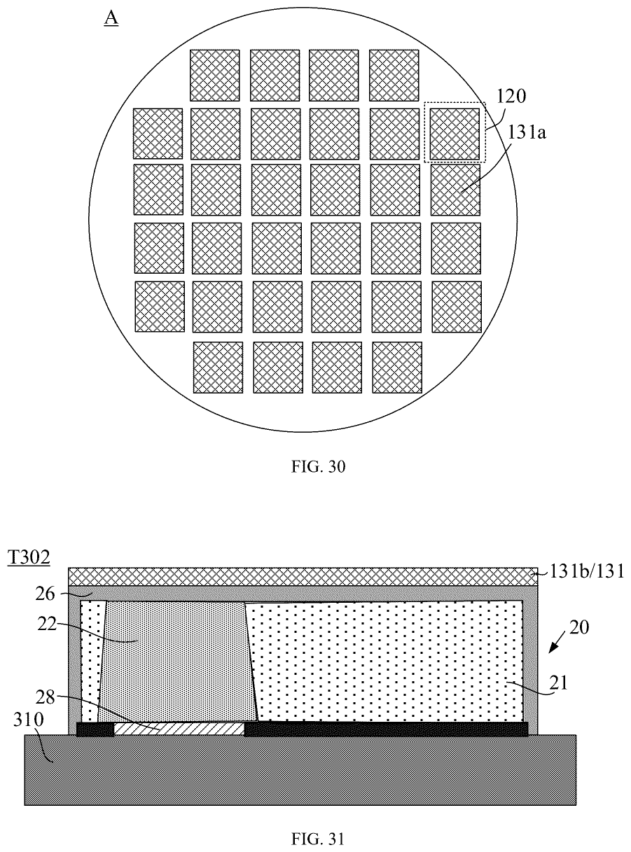

In some embodiments, in a process of manufacturing the initial light-emitting unit 120, a first large plate M including a plurality of initial light-emitting units 120 disposed in an array is formed synchronously, as illustrated in FIG. 29. In this process, the first indium zinc oxide layer is formed on the initial light-emitting units 120 of the first large plate M. Then, the first large plate M is diced to form a plurality of first initial wafers A. As illustrated in FIG. 30, the first initial wafer A is circular, and the first initial wafer A includes a plurality of initial light-emitting units 120 provided with the first indium zinc oxide layer 131a. In some embodiments, a size of the first initial wafer A is 4 inches or 6 inches.

In some embodiments, in a process of manufacturing the initial light-emitting unit 120, the first initial wafer A including the plurality of initial light-emitting units 120 disposed in an array is directly formed. The first initial wafer A may be circular, and includes the plurality of initial light-emitting units 120 provided with the first indium zinc oxide layer 131a. In some embodiments, the size of the first initial wafer A is 4 inches or 6 inches.

In T302, as illustrated in FIG. 31, a second indium zinc oxide layer 131b is formed on a side of the color converting unit 20 distal from the initial first substrate 310.

That is, the second indium zinc oxide layer 131b is formed on a side of the encapsulating layer 26 distal from the initial first substrate 310.

In some embodiments, the second indium zinc oxide layer 131b is formed by a photolithography process.

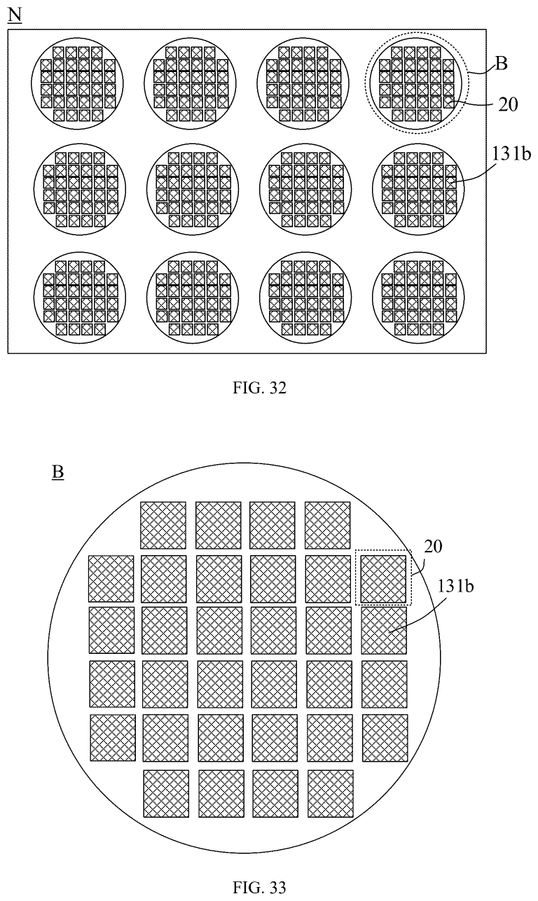

In a process of manufacturing the color converting unit 20, a second large plate N including a plurality of color converting units 20 disposed in an array is formed synchronously, as illustrated in FIG. 32. In this process, the second indium zinc oxide layer 131b is formed on the color converting units 20 of the second large plate N. Then, the second large plate N is diced to form a plurality of second master wafers B. As illustrated in FIG. 33, the second master wafer B is circular, and the second master wafer B includes the plurality of color converting units 20 provided with the second indium zinc oxide layer 131b. A size of the second master wafer B is the same as or equivalent to that of the first initial wafer A, which is convenient for the cell alignment operation.

Processes of cell aligning the first initial wafer A and the second master wafer B to finally form a single light-emitting chip 100 are described hereinafter. It should be noted that the formation of one light-emitting chip 100 is taken as an example in the following.

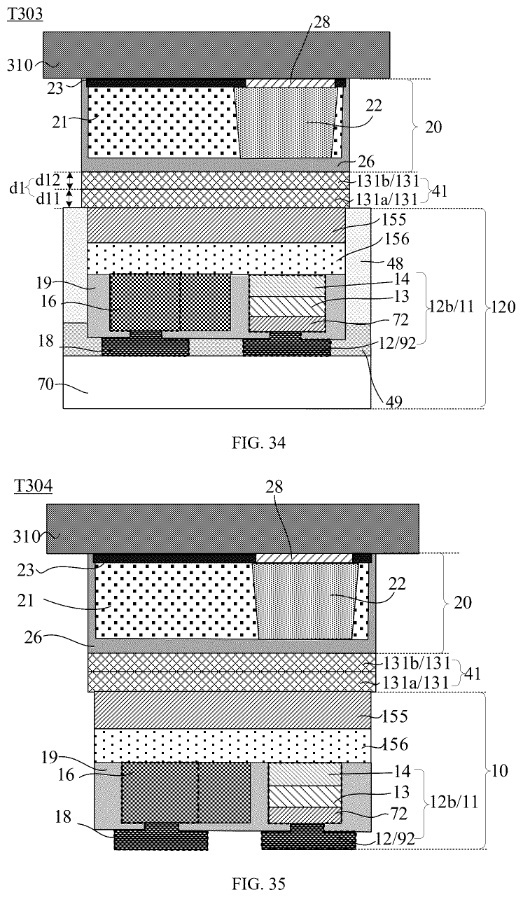

In T303, as illustrated in FIG. 34, the first indium zinc oxide layer 131a and the second indium zinc oxide layer 131b are bonded.

By bonding the first indium zinc oxide layer 131a and the second indium zinc oxide layer 131b, the initial light-emitting units 120 and the color converting units 20 are bonded.

In some embodiments, a thickness d11 of the first indium zinc oxide layer 131a and a thickness d12 of the second indium zinc oxide layer 131b are the same or different, which is not limited herein. A sum of the thickness d11 of the first indium zinc oxide layer 131a and the thickness d12 of the second indium zinc oxide layer 131b is a film thickness of the indium zinc oxide bonding layer 131.

In some embodiments, the process of bonding the first indium zinc oxide layer 131a and the second indium zinc oxide layer 131b includes U1 to U3.

In U1, a surface of the first indium zinc oxide layer 131a distal from the temporary substrate 70 is treated with oxygen plasma to activate the surface of the first indium zinc oxide layer 131a.

In U2, a surface of the second indium zinc oxide layer 131b distal from the initial first substrate 310 is treated with oxygen plasma to activate the surface of the second indium zinc oxide layer 131b.

In U3, the first indium zinc oxide layer 131a and the second indium zinc oxide layer 131b are pressed at a temperature to form the adhesion connecting layer 41.

In T304, the temporary substrate 70 is removed.

After the temporary substrate 70 is removed, the initial light-emitting unit 120 is formed as the light-emitting unit 10, and the structure is illustrated in FIG. 35.

In some embodiments, the temporary adhesive layer 48, the adhesive release layer 49 and the temporary substrate 70 are removed by releasing the adhesive release layer 49 under the irradiation of ultraviolet light.

In T305, the first substrate 30 is formed by thinning the initial first substrate 310.

After this process, a structure including a plurality of light-emitting chips 100 as illustrated in FIG. 5 is acquired.

In some embodiments, a thickness of the initial first substrate 310 is reduced to 60 μm to 200 μm. A shape of the light-emitting chip 100 formed in this way is approximately square, which allows the light-emitting chip 100 to be more stable and is beneficial to the use thereof in subsequent processes. The use of a thicker initial first substrate 310 in the preparation of the light-emitting chip 100 is beneficial to the processing of the light-emitting chip 100.

In some embodiments, an acid-proof film is attached to a first side of the initial first substrate 310, and a second side of the initial first substrate 310 is thinned, wherein the plurality of light-emitting parts 11 is disposed on the first side of the initial first substrate 310.

In T306, a single light-emitting chip 100 is acquired after dicing.

In some embodiments, a blue film is attached onto a side of the first substrate 30 distal from the electrode 92 for protection, and then the single light-emitting chip 100 is acquired by using laser dicing.

In some embodiments, in process T306, the dicing is performed by laser stealth dicing, and the light-emitting chips 100 are separated from each other by stress after the laser stealth dicing. In the case that the dicing is performed by the laser stealth dicing, it is unnecessary to attach the blue film onto the side of the first substrate 30 distal from the electrode 92 for protection.

Through the above S101 to S108, R201 to R203 and T301 to T306, the light-emitting chip 100 as illustrated in FIG. 5 is formed, and a projection of the indium zinc oxide bonding layer 131 on the plurality of light-emitting parts 11 covers the plurality of light-emitting parts 11. That is, in the case that the indium zinc oxide bonding layer 131 is used as the adhesion connecting layer 41, the indium zinc oxide bonding layer 131 is disposed in a whole layer, and an orthographic projection of the indium zinc oxide bonding layer 131 on the first substrate 30 completely covers orthographic projections of the plurality of light-emitting parts 11 on the first substrate 30. The indium zinc oxide bonding layer 131 is a transparent film layer, and thus, the indium zinc oxide bonding layer 131 disposed in the whole layer does not affect light rays emitted from the plurality of light-emitting parts 11. In the present embodiment, the indium zinc oxide bonding layer 131 is used as the adhesion connecting layer 41, such that the accuracy of the formed adhesion connecting layer 41 can be improved, thereby improving the product yield of the light-emitting chip 100, and enabling the formed light-emitting chip 100 to be thinner.

The second embodiment of the method for preparing the light-emitting chip 100 is described hereinafter, and the light-emitting chip 100 illustrated in FIG. 6 is formed according to this embodiment. It should be noted that in the process of preparing the light-emitting chip 100, the structural example of the light-emitting chip 100 can be understood by referring to the content illustrated in FIG. 6 and the process diagram.

### Second Embodiment

In some embodiments, the preparation processes of the initial light-emitting unit 120 are illustrated in processes S101 to S108, and the preparation processes of the color converting unit 20 are illustrated in processes R201 to R203, which are not repeated herein any further.

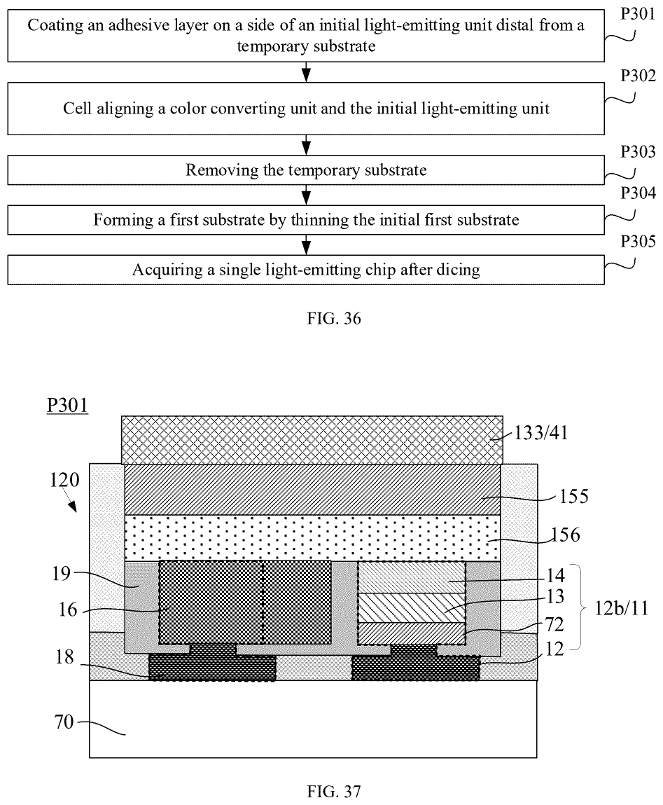

After the initial light-emitting unit 120 and the color converting unit 20 are formed, the light-emitting chip 100 is formed by cell aligning the color converting unit 20 and the initial light-emitting unit 120 using the adhesion connecting layer 41 formed by an adhesive layer 133, as illustrated in FIG. 36. This process includes P301 to P305.

In P301, as illustrated in FIG. 37, an adhesive layer 133 is coated on a side of the initial light-emitting unit 120 distal from the temporary substrate 70.

That is, a side of the gallium nitride buffer layer 155 distal from the temporary substrate 70 is coated with the adhesive layer 133.

In some embodiments, the material of the adhesive layer 133 is an organic adhesive material of epoxy resin, and the adhesive layer 133 is formed by a stencil printing process, and it is ensured that there is no residual material for forming the adhesive layer 133 in a dicing channel J. As illustrated in FIG. 8, the dicing channel J is disposed between two adjacent light-emitting chips 100 on the wafer 300. Only one dicing channel J is illustrated in FIG. 8. It can be understood that in order to acquire a single light-emitting chip 100, a region between every two adjacent light-emitting chips 100 is the dicing channel J.

It can be understood that in the process of manufacturing the initial light-emitting units 120, a large plate including the plurality of initial light-emitting units 120 disposed in an array is formed synchronously. In the process of manufacturing the color converting units 20, a large plate including the plurality of color converting units 20 disposed in an array is formed synchronously. Before cell aligning the color converting units 20 and the initial light-emitting units 120, a process of dicing the large plate of the initial light-emitting units 120 and the large plate of the color converting units 20 is further included.

A plurality of third initial wafers C are formed by dicing the large plate of the initial light-emitting units 120, wherein each of the plurality of third initial wafers C includes a plurality of initial light-emitting units 120 provided with the adhesive layer 133. A plurality of fourth master wafers D are formed by dicing the large plate of the color converting units 20, wherein each of the plurality of fourth master wafers D includes a plurality of color converting units 20.

In some embodiments, in a process of manufacturing the initial light-emitting units 120, the third initial wafer C including a plurality of initial light-emitting units 120 disposed in an array is directly formed, and it is not necessary to dice the large plate. For example, a shape of the third initial wafer C is circular. For example, a shape of the fourth master wafer D is circular, and the sizes of the fourth master wafer D and the third initial wafer C are the same or equivalent, which is convenient for the cell alignment operation.

The structures of the third initial wafer C and the fourth master wafer D may refer to the examples of the first initial wafer A and the second master wafer B in FIGS. 30 and 33, which will not be repeated herein any further. The difference is that the third initial wafer C includes the plurality of initial light-emitting units 120 provided with the adhesive layer 133, and the first initial wafer A includes the plurality of initial light-emitting units 120 provided with the first indium zinc oxide layer 131a. The fourth master wafer D includes the plurality of color converting units 20, and the second master wafer B includes the plurality of color converting units 20 provided with the second indium zinc oxide layer 131b.

The processes of cell aligning the third initial wafer C and the fourth master wafer D to finally form the single light-emitting chip 100 are described hereinafter.

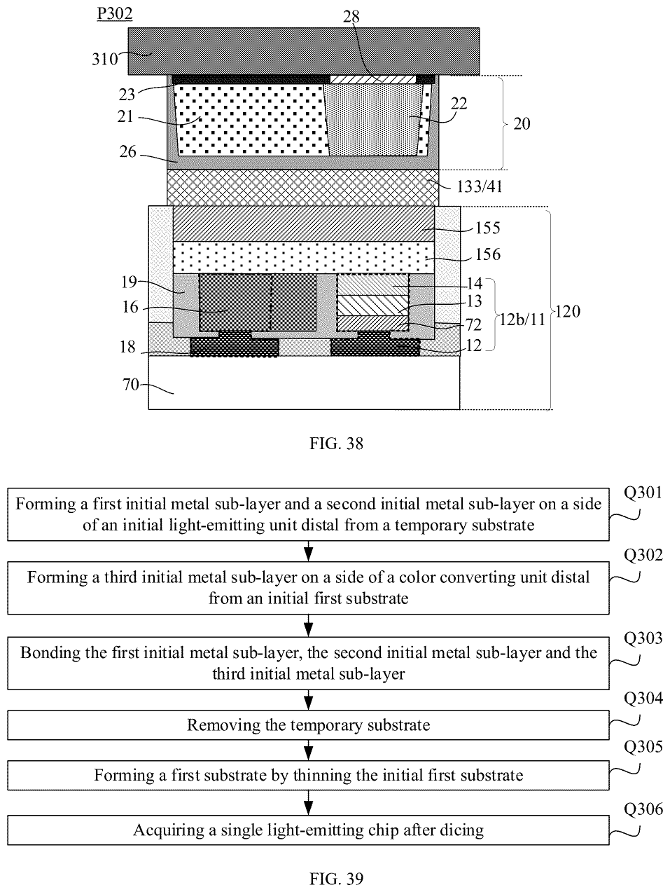

In P302, as illustrated in FIG. 38, the color converting unit 20 and the initial light-emitting unit 120 are cell aligned.

The adhesion between the color converting unit 20 and the initial light-emitting unit 120 is achieved by the adhesive layer 133.

In P303, the temporary substrate 70 is removed.

The specific process may refer to process T304, which will not be repeated herein any further.

In P304, the first substrate 30 is formed by thinning the initial first substrate 310.

The specific process may refer to process T305, which will not be repeated herein any further.

In P305, the single light-emitting chip 100 is acquired after dicing.

The specific process may refer to process T306, which will not be repeated herein any further.

Through the above S101 to S108, R201 to R203 and P301 to P305, the light-emitting chip 100 illustrated in FIG. 6 is formed. The adhesion connecting layer 41 is the adhesive layer 133, and a projection of the adhesive layer 133 on the plurality of light-emitting parts 11 covers the plurality of light-emitting parts 11. That is, the adhesive layer 133 is disposed in a whole layer, and an orthographic projection of the adhesive layer 133 on the first substrate 30 covers orthographic projections of the plurality of light-emitting parts 11 on the first substrate 30. The adhesive layer 133 is made of a transparent organic adhesive material, and the adhesive layer 133 disposed in the whole layer does not affect the light rays emitted from the plurality of light-emitting parts 11. In the present embodiment, the adhesive layer 133 is used as the adhesion connecting layer 41, such that the transfer efficiency of the Micro-LED can be improved, thereby reducing the chip thickness and improving the product yield.

The third embodiment of the method for preparing the light-emitting chip 100 is described hereinafter, and the light-emitting chip 100 illustrated in FIG. 7 is formed according to this embodiment. It should be noted that in the process of preparing the light-emitting chip 100, the structural example of the light-emitting chip 100 can be understood by referring to the content illustrated in FIG. 7 and the process diagram.

### Third Embodiment

In some embodiments, the preparation processes of the initial light-emitting unit 120 are illustrated in processes S101 to S108, and the preparation processes of the color converting unit 20 are illustrated in processes R201 to R203, which are not repeated herein any further.

After the initial light-emitting unit 120 and the color converting unit 20 are formed, the color converting unit 20 and the initial light-emitting unit 120 are cell aligned using the adhesion connecting layer 41 formed by a metal bonding layer 132, and thus, the light-emitting chip 100 is formed, as illustrated in FIG. 39. This process includes Q301 to Q306

In Q301, as illustrated in FIGS. 40 and 41, a first initial metal sub-layer 1310 and a second initial metal sub-layer 1320 are formed on a side of the initial light-emitting unit 120 distal from the temporary substrate 70.

That is, the first initial metal sub-layer 1310 and the second initial metal sub-layer 1320 are formed on the side of the gallium nitride buffer layer 155 distal from the temporary substrate 70. FIG. 40 is a sectional view of FIG. 41 taken along a sectional line FF.

In some embodiments, the whole layer of material for forming the first initial metal sub-layer 1310 is deposited on the side of the gallium nitride buffer layer 155 distal from the temporary substrate 70 by a deposition process, and the first initial metal sub-layer 1310 is patterned by a photolithography process, and the material of the first initial metal sub-layer 1310 may be any one of Au (gold), Ag (silver), Pb (lead) or Sn (tin)

In some embodiments, as illustrated in FIG. 41, the first initial metal sub-layer 1310 includes three opening regions K, which are a first opening sub-region K11, a second opening sub-region K21 and a third opening sub-region K31. The first opening sub-region K11 is disposed corresponding to the first sub-pixel region S11, the second opening sub-region K21 is disposed corresponding to the second sub-pixel region S12, and the third opening sub-region K31 is disposed corresponding to the third sub-pixel region S13. The corresponding arrangement between A and B means that orthographic projections of A and B on the temporary substrate 70 are coincident or approximately coincident. For example, the first opening sub-region K11 being disposed corresponding to the first sub-pixel region

S11 means that orthographic projections of the first opening sub-region K11 and the first sub-pixel region S11 on the temporary substrate 70 are coincident or approximately coincident.

In some embodiments, as illustrated in FIGS. 40 and 41, the second initial metal sub-layer 1320 includes a plurality of first-type metal bumps 132t, wherein a structure of each of the plurality of first-type metal bumps 132t may be cylindrical or conical.

The material of the second initial metal sub-layer 1320 may be In (indium).

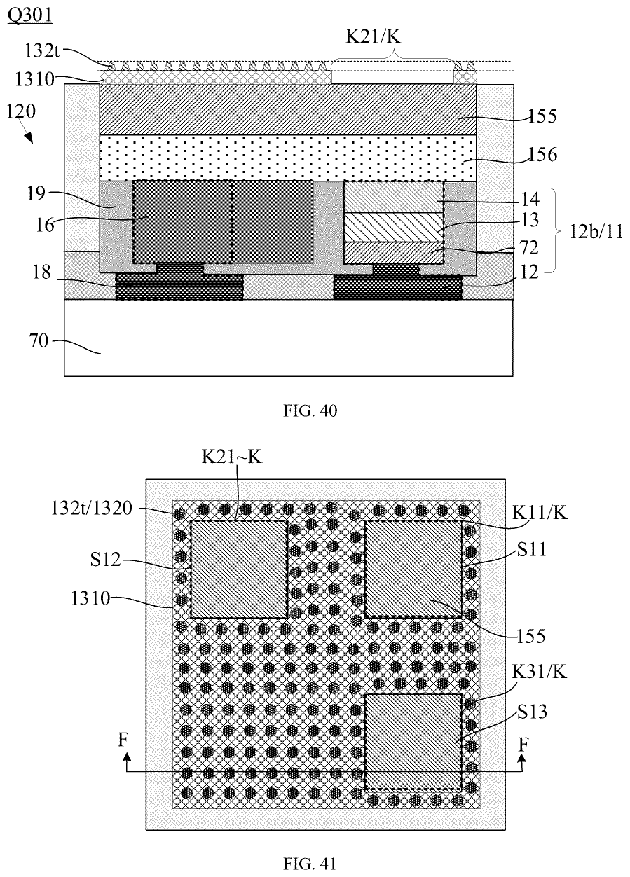

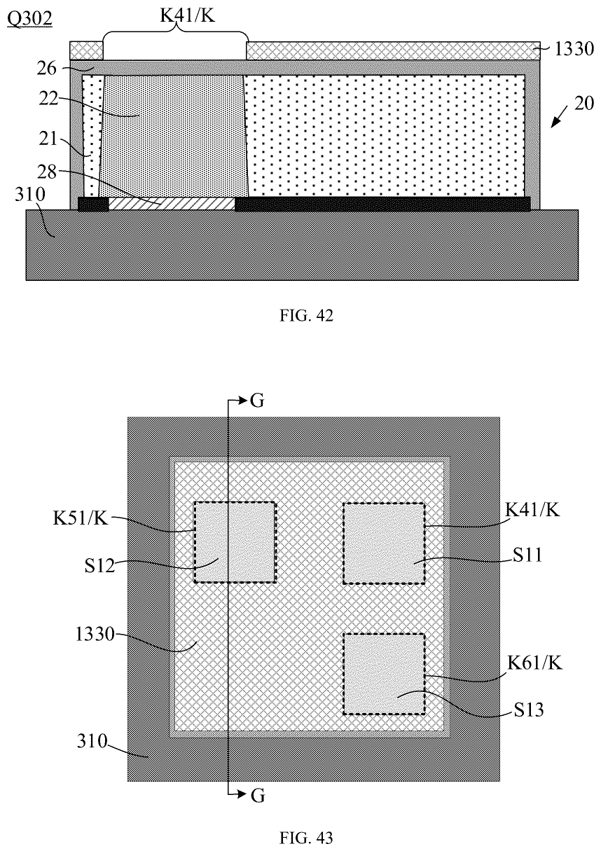

In Q302, as illustrated in FIGS. 42 and 43, a third initial metal sub-layer 1330 is formed on a side of the color converting unit 20 distal from the initial first substrate 310.

That is, the third initial metal sub-layer 1330 is formed on a side of an encapsulating layer 26 distal from the initial first substrate 310.

In some embodiments, a whole layer of material for forming the third initial metal sub-layer 1330 is deposited on the side of the encapsulating layer 26 distal from the initial first substrate 310 by a deposition process, and the third initial metal sub-layer 1330 is patterned by a photolithography process. The material of the third initial metal sub-layer 1330 may be any one of Au (gold), Ag (silver), Pb (lead) or Sn (tin). The material of the third initial metal sub-layer 1330 may be the same as that of the first initial metal sub-layer 1310.

In some embodiments, as illustrated in FIG. 43, the third initial metal sub-layer 1330 includes three opening regions K, which are a fourth opening sub-region K41, a fifth opening sub-region K51 and a sixth opening sub-region K61. The fourth opening sub-region K41 is disposed corresponding to the first sub-pixel region S11, the fifth opening sub-region K51 is disposed corresponding to the second sub-pixel region S12, and the sixth opening sub-region K61 is disposed corresponding to the third sub-pixel region S13.

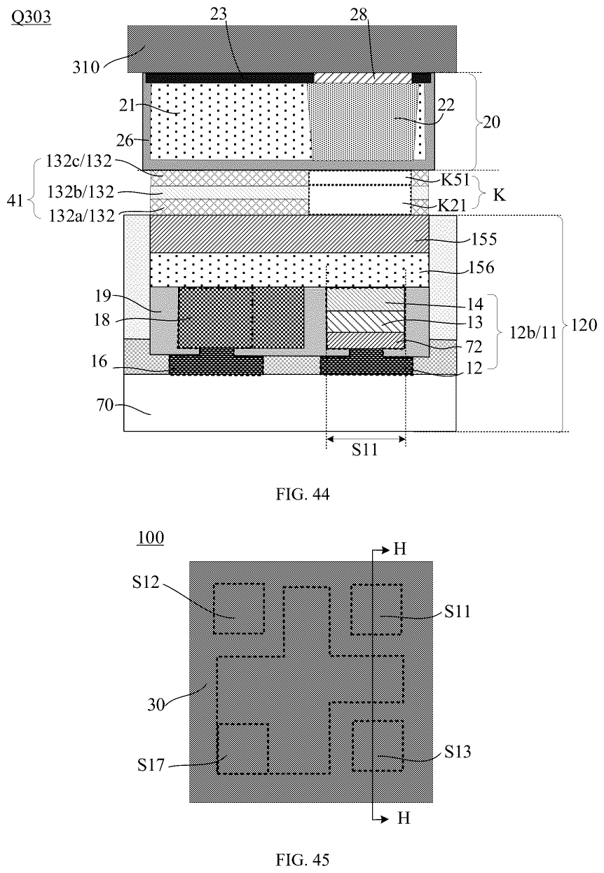

In Q303, as illustrated in FIG. 44, the first initial metal sub-layer 1310, the second initial metal sub-layer 1320 and the third initial metal sub-layer 1330 are bonded.

In some embodiments, the bonding of the first initial metal sub-layer 1310, the second initial metal sub-layer 1320 and the third initial metal sub-layer 1330 is achieved by a metal wafer bonding technology. The metal wafer bonding technology refers to a technology that relies on the formation of a eutectic alloy between two different metals to completely bond at a temperature lower than respective melting points of the two metals. The metal wafer bonding technology may be classified into a solid-liquid interdiffusion bonding technology and a solid-state diffusion bonding technology based on different bonding temperatures. The solid-liquid interdiffusion bonding technology has less requirements for film flatness than the solid-state diffusion bonding technology, and moreover, is high in bonding strength and short in bonding time. Therefore, the metal bonding layer 132 may be formed using the solid-liquid interdiffusion bonding technology to achieve the cell alignment between the color converting unit 20 and the initial light-emitting unit 120.

As illustrated in FIG. 44, the formed metal bonding layer 132 includes a first metal sub-layer 132a, a second metal sub-layer 132b and a third metal sub-layer 132c. The first initial metal sub-layer 1310, the second initial metal sub-layer 1320 and the third initial metal sub-layer 1330 form the metal bonding layer 132 by the metal wafer bonding technology, and the second metal sub-layer 132b is a eutectic alloy layer formed by a part of the first initial metal sub-layer 1310, the second initial metal sub-layer 1320 and a part of the third initial metal sub-layer 1330.

For example, as illustrated in FIG. 44, the metal bonding layer 132 includes a fourth opening region K4, a fifth opening region and a sixth opening region. The fourth opening region K4 is disposed corresponding to the first sub-pixel region S11, the fifth opening region is disposed corresponding to the second sub-pixel region S12 and the sixth opening region is disposed corresponding to the third sub-pixel region S13. Please refer to FIG. 43 for the arrangement of the second sub-pixel region S12 and the third sub-pixel region S13. The first opening sub-region K1l and the fourth opening sub-region K41 form the fourth opening region K4. Similarly, the second opening sub-region K21 and the fifth opening sub-region K51 form the fifth opening region, and the third opening sub-region K31 and the sixth opening sub-region K61 form the sixth opening region. Please refer to FIGS. 41 and 43 for the arrangement of the second opening sub-region K21, the third opening sub-region K31, the fifth opening sub-region K51 and the sixth opening sub-region K61.

In Q304, the temporary substrate 70 is removed

The specific process may refer to process T304, which will not be repeated herein any further.

In Q305, the first substrate 30 is formed by thinning the initial first substrate 310.

The specific process may refer to process T305, which will not be repeated herein any further.

In Q306, the single light-emitting chip 100 is acquired after dicing.

The specific process may refer to process T306, which will not be repeated herein any further.

Through the above S101 to S108, R201 to R203 and Q301 to Q306, the light-emitting chip 100 as illustrated in FIG. 7 is formed. The adhesion connecting layer 41 is the metal bonding layer 132, and it is required to arrange opening regions K corresponding to the plurality of light-emitting parts 11 on the metal bonding layer 132. Because the metal bonding layer 132 is opaque, it is required to form openings in the region of the metal bonding layer 132 corresponding to the light-emitting parts 11 to emit light rays. It should be noted that the region of the metal bonding layer 132 corresponding to the light-emitting parts 11 refers to the region where orthographic projections of the light-emitting parts 11 and the metal bonding layer 132 on the first substrate 30 overlap. In the present embodiment, the metal bonding layer 132 is used as the adhesion connecting layer 41, which can improve the accuracy of the formed adhesion connecting layer 41.

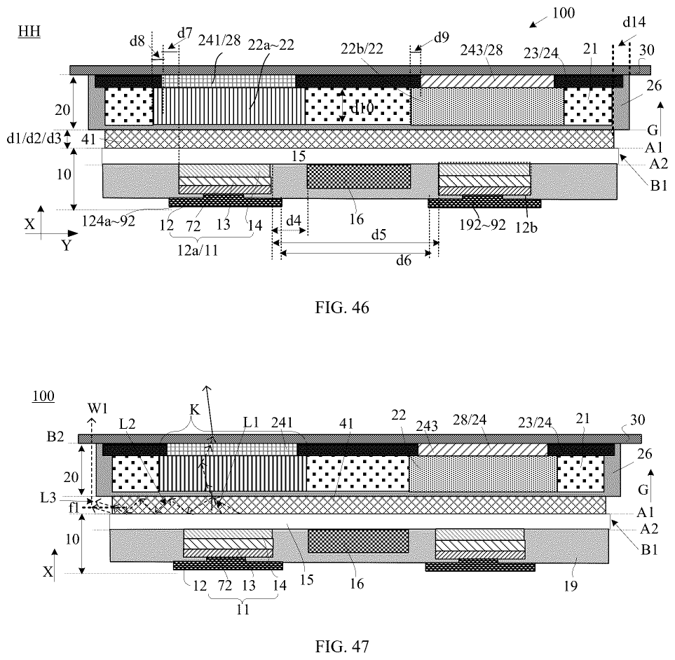

In some embodiments, as illustrated in FIG. 46, the first light-emitting part 12a is disposed corresponding to the first sub-electrode 124a, and the third light-emitting part 12c is disposed corresponding to the third sub-electrode 193. A distance d6 between the first sub-electrode 124a and the third sub-electrode 193 is smaller than the distance d5 between the first light-emitting part 12a and the third light-emitting part 12c.

The distance do between the two adjacent anode electrodes is set to be less than or equal to the distance d5 between the two light-emitting parts 11 where the two anode electrodes are disposed. That is, the boundary of the anode electrode exceeds the boundary of the light-emitting part 11 where the anode electrode is disposed, such that the anode electrode has a conduction function, and also can ensure that the anode electrode has a larger area for light ray reflection, thereby improving the light-emitting effect of the light-emitting chip 100.

In some embodiments, as illustrated in FIGS. 45 and 46, the projection of the light filtering part 28 on the first substrate 30 covers the projection of the light-emitting part 11 corresponding to the light filtering part 28 on the first substrate 30. The projection of the optical functional part 22 on the first substrate 30 covers the projection of the light filtering part 28 corresponding to the optical functional part 22 on the first substrate 30. FIG. 46 is a sectional view of FIG. 45 taken along a sectional line HH.

That is, in any direction, the projection size of the light filtering part 28 on the first substrate 30 is larger than the projection size of the light-emitting part 11 corresponding to the light filtering part 28 on the first substrate 30. The projection size of the optical functional part 22 on the first substrate 30 is larger than the projection size of the light filtering part 28 corresponding to the optical functional part 22 on the first substrate 30.

In some embodiments, as illustrated in FIGS. 45 and 46, a size d10 of the defining dam layer 21 in the first direction X is defined to be in the range of 10 μm to 30 μm.

In some embodiments, the size d10 of the defining dam layer 21 in the first direction X is defined as 10 μm, 15 μm, 20 μm, 25 μm, 28 μm or 30 μm, which is not limited herein. Setting the size d10 of the defining dam layer 21 in the first direction X, that is, the thickness of the defining dam layer 21 to be 10 μm to 30 μm increases the thickness of the defining dam layer 21. Because the optical functional part 22 is disposed in the opening region K of the defining dam layer 21, the thickness of the optical functional part 22 is increased synchronously, such that the design can improve the light-emitting effect of the light-emitting chip 100

In some embodiments, as illustrated in FIG. 46, the projection of the color converting unit 20 on the first substrate 30 covers the projection of the adhesion connecting layer 41 on the first substrate 30.

In some embodiments, the adhesion connecting layer 41 is made of an organic adhesive material of epoxy resin. By setting the projection of the color converting unit 20 on the first substrate 30 to cover the projection of the adhesion connecting layer 41 on the first substrate 30, it can be ensured that no organic adhesive material remains at the position of the dicing channel J (as illustrated in FIG. 8), which is convenient for dicing to form the light-emitting chip 100.

In some embodiments, as illustrated in FIG. 46, a distance d14 between the projection boundary of the color converting unit 20 on the first substrate 30 and the projection boundary of the adhesion connecting layer 41 on the first substrate 30 ranges from Oum to 10 μm.

In some embodiments, the distance d14 between the projection boundary of the color converting unit 20 on the first substrate 30 and the projection boundary of the adhesion connecting layer 41 on the first substrate 30 is 0 μm, 2 μm, 5 μm, 7 μm or 10 μm, which is not limited herein.

By setting the range of the distance d14 between the projection boundary of the color converting unit 20 on the first substrate 30 and the projection boundary of the adhesion connecting layer 41 on the first substrate 30 to be 0 μm to 10 μm, under the condition of ensuring the adhesion stability of the light-emitting chip 100, when the adhesion connecting layer 41 is made of an organic adhesive material of epoxy resin, it can be ensured that no organic adhesive material remains at the position of the dicing channel J (as illustrated in FIG. 8).

The second semiconductor layer 15 of the light-emitting unit 10 is described hereinafter. It should be noted that the second semiconductor layer 15 may be a first carrier transport layer, or the second semiconductor layer 15 is a laminated layer composed of a first carrier buffer layer and a buffer layer. Herein, the first carrier transport layer may be an N-type gallium nitride layer 156; the buffer layer 156 may be a gallium nitride buffer layer 155; and the gallium nitride buffer layer 155 is disposed on the side of the N-type gallium nitride layer 156 distal from the light-emitting part 11.

In some examples, as illustrated in FIG. 47, the adhesion connecting layer 41 of the light-emitting chip 100 is the adhesive layer 133; a refractive index of the second semiconductor layer 15 is 2.45; and a refractive index of the adhesion connecting layer 41 is 1.56. Because the difference between the refractive index of the second semiconductor layer 15 and the refractive index of the adhesion connecting layer 41 is relatively great, a light ray from the light-emitting chip 100 is totally reflected by an interface between the second semiconductor layer 15 and the adhesion connecting layer 41. A light ray L1 whose angle with the first direction X is smaller than a critical angle α1 is propagated upwards and enters the color converting unit 20. A light ray L2 whose angle with the first direction X is larger than or equal to the critical angle α1 is totally reflected in the second semiconductor layer 15, and is transversely propagated in the second semiconductor layer 15 to form an optical waveguide. The first direction X is a direction in which the light-emitting unit 10 and the color converting unit 20 are laminated.

It should be noted that the critical angle α1 at which total reflection is formed between the second semiconductor layer 15 and the adhesion connecting layer 41 is calculated according to:

$$sin α1 \times 2.45 = sin 90 ° \times 1.56 .$$

Therefore, α1 is 39.5°.

That is, the light ray L1 whose angle with the first direction X is smaller than 39.5° is propagated upwards and enters the color converting unit 20; and the light ray L2 whose angle with the first direction X is larger than or equal to 39.5° is totally reflected in the second semiconductor layer 15.

The refractive index of air is 1.0. Because the difference between the refractive index of the second semiconductor layer 15 and the refractive index of air is relatively great, total reflection is also formed on an interface between the second semiconductor layer 15 and air. A normal line perpendicular to the second semiconductor layer 15 is referred to as a No. 1 normal line f1. A light ray whose angle with the No. 1 normal line f1 is smaller than a critical angle α2 is emitted from the second semiconductor layer 15 to air. A light ray whose angle with the No. 1 normal line f1 is larger than or equal to the critical angle α2 is totally reflected in the second semiconductor layer 15

It should be noted that the critical angle α2 at which total reflection is formed between the second semiconductor layer 15 and air is calculated according to.

$$sin 2 \times 2.45 = sin 90 ° \times 1. .$$

Therefore, α2 is 24°

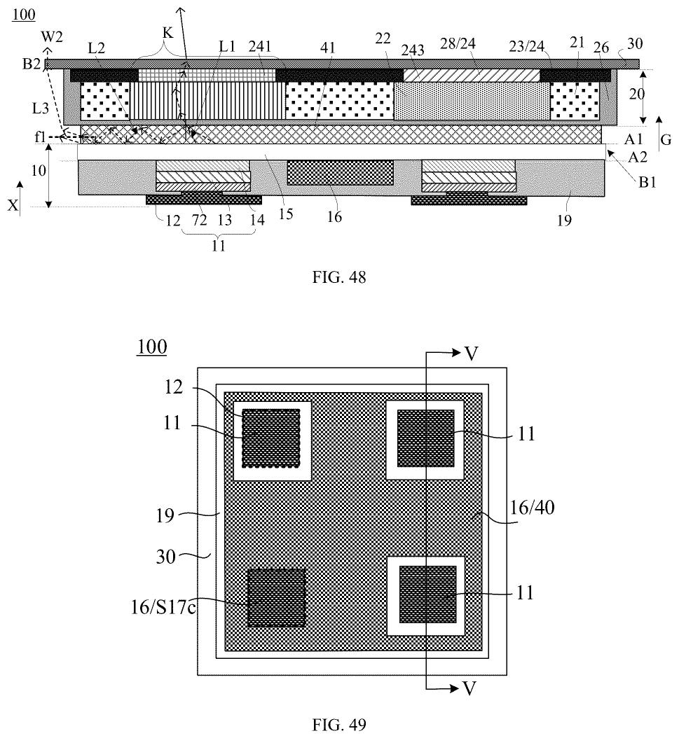

As illustrated in FIG. 47, that is, the light ray whose angle with the No. 1 normal line f1 is smaller than 24° is emitted from the second semiconductor layer 15 to air, and the light ray whose angle with the No. 1 normal line f1 is larger than or equal to 24° is totally reflected in the second semiconductor layer 15. After scattering in air, a light ray L3 emitted from a side surface B1 of the second semiconductor layer 15 forms a light leak W1 near a side surface B2 of the first substrate 30. As illustrated in FIG. 48, after being propagated aslant in air to the side surface B2 of the first substrate 30, the light ray L3 emitted from the side surface B1 of the second semiconductor layer 15 forms a light leak W2.

Due to the negative effects of the light leak W1 and the light leak W2, the light-emitting efficiency of the display base plate 200 and the display effect of the display base plate 200 are reduced. Moreover, the light leak W2 also enters an adjacent light-emitting chip 100, causing poor light uniformity.

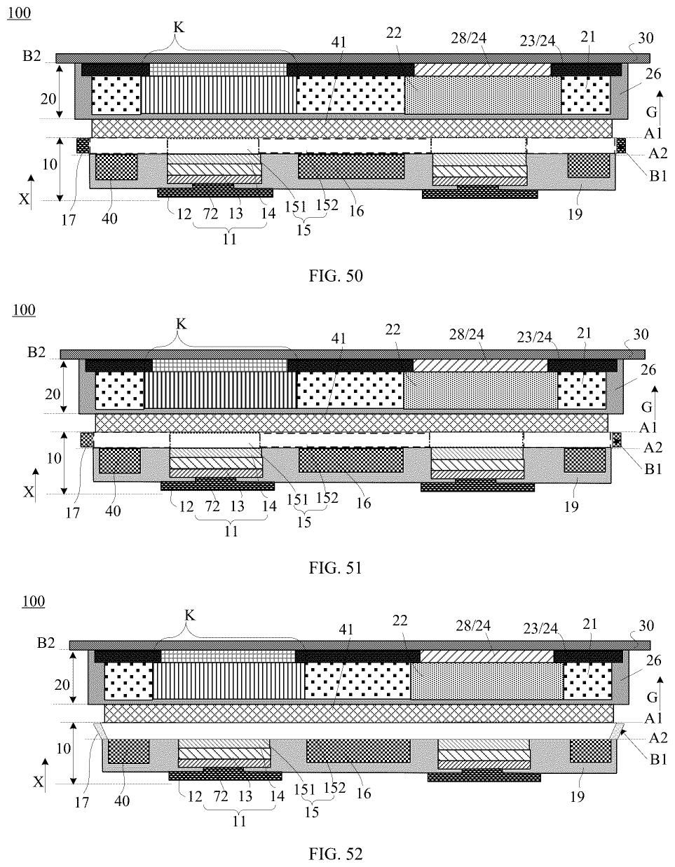

Based on this, as illustrated in FIGS. 49 and 50, an embodiment of the present disclosure provides a light-emitting chip 100. The light-emitting chip 100 includes: a light-emitting unit 10 and a color converting unit 20 disposed on a light-emitting side G of the light-emitting unit 10.

The light-emitting unit 10 includes a plurality of light-emitting parts 11. The light-emitting part 11 includes a first electrode 12, a first semiconductor layer 13, and a light-emitting layer 14 which are laminated in the first direction X.

In some embodiments, the first electrode 12 is an anode; and a material of the first semiconductor layer 13 includes P-type gallium nitride.

In some embodiments, one of the plurality of light-emitting parts 11 is configured to emit one of lights of different colors; and the plurality of light-emitting parts 11 are configured to emit lights of the same color, or configured to emit lights of different colors.

The light-emitting unit 10 further includes a second semiconductor layer 15 and a common electrode layer 16. The second semiconductor layer 15 is disposed on a light-emitting side G of the plurality of light-emitting parts 11. The second semiconductor layer 15 includes a connecting part 151 and an assisting part 152. The connecting part 151 and the light-emitting parts 11 are connected At least part of the assisting part 152 is disposed between the adjacent connecting parts 151. The connecting part 151 and the assisting part 152 are of an integrated structure. The common electrode layer 16 and the assisting part 152 are connected.

Specifically, a region of the connecting part 151 in the second semiconductor layer 15 is defined as a region of the second semiconductor layer 15 in contact with the light-emitting part 11. In the case that the second semiconductor layer 15 is not in direct contact with the light-emitting part 11, the region of the connecting part 151 in the second semiconductor layer 15 is defined as a region defined by an orthographic projection of the light-emitting part 11 on an extension surface of the second semiconductor layer 15.

A surface of the second semiconductor layer 15 facing the color converting unit 20 is a first surface A1. A surface of the second semiconductor layer 15 facing away from the color converting unit 20 is a second surface A2. Herein, the second semiconductor layer 15 may further include a side surface B1 disposed between the first surface A1 and the second surface A2 and connected to the first surface A1 and the second surface A2. The light-emitting chip 100 further includes a light disturbing part 17. The light disturbing part 17 is disposed at the periphery and/or in the second semiconductor layer 15. The light disturbing part 17 may be configured to break an optical path, including propagation in the second semiconductor layer 15 and emission from the side surface B1 of the second semiconductor layer 15, of a light ray emitted from the light-emitting layer 14.

As the light disturbing part 17 is disposed at the periphery and/or in the second semiconductor layer 15, the optical path, including propagation in the second semiconductor layer 15 and emission from the side surface B1 of the second semiconductor layer 15, of the light ray emitted from the light-emitting layer 14 is broken, that is, a light ray L3 (as illustrated in FIGS. 47 and 48) emitted from the side surface B1 of the second semiconductor layer 15 is broken effectively. This avoids formation, on the first substrate 30, of the light leak W1 (as illustrated in FIG. 47) and the light leak W2 (as illustrated in FIG. 48) by the light ray L3 emitted from the side surface B1 of the second semiconductor layer 15, thereby improving the light-emitting efficiency and the display effect of the display base plate 200.

In some embodiments, one side of a portion of the assisting part 152 between the adjacent connecting parts 151 is connected to one of the connecting parts 151; and the other side of the portion is connected to the other connecting part 151.

In some embodiments, as illustrated in FIG. 50, the light disturbing part 17 covers the side surface B1 of the second semiconductor layer 15.

It should be noted that the light disturbing part 17 is disposed annularly surrounding the side surface B1 of the second semiconductor layer 15.

As the light disturbing part 17 covers the side surface B1 of the second semiconductor layer 15, the light disturbing part 17 can absorb or reflect a light ray that is transversely propagated in the second semiconductor layer 15 to the side surface B1 of the second semiconductor layer 15.

In some embodiments, as illustrated in FIG. 50, the light-emitting part 11 further includes a first electrode 12 electrically connected to the light-emitting layer 14; the first electrode 12 is disposed on the side of the light-emitting layer 14 distal from the color converting unit 20; and a material of the light disturbing part 17 is the same as a material of the first electrode 12.

The light disturbing part 17 made of the same material as the first electrode 12 is configured to reflect a light ray acquired after a light ray emitted from the light-emitting layer 14 is propagated in the second semiconductor layer 15 and emitted from the side surface B1 of the second semiconductor layer 15.

That is, the light disturbing part 17 is formed during formation of the first electrode 12 by patterning; and the light disturbing part 17 and the first electrode 12 are disposed in the same layer.

The “same layer” refers to a layer structure formed in the following manner: forming, via the same film formation process, film layers for forming specific patterns, and then forming the layer structure via one-time composition process using the same mask. Depending on different specific patterns, one-time composition process may include multiple exposure, development or etching processes; the specific patterns in the formed layer structure may be continuous or discontinuous; and these specific patterns may be at different heights or have different thicknesses.

From the foregoing method for preparing the light-emitting chip 100, it can be learned that as illustrated in FIG. 38, an initial light-emitting unit 120 and the color converting unit 20 are prepared first; then, the adhesion connecting layer 41 is formed; the initial light-emitting unit 120 and the color converting unit 20 are adhered to acquire a light-emitting unit 10, thereby forming the light-emitting chip 100. For a specific color converting unit 20 and a process of forming the adhesion connecting layer 41, reference may be made to the foregoing content. Details are not described herein any further. Similarly, the following embodiments describe only a method for preparing the initial light-emitting unit 120

A difference of this example lies in that during preparation of the initial light-emitting unit 120, in process S106 (as illustrated in FIG. 9), the light disturbing part 17 is formed synchronously during formation of the electrode 92 (as illustrated in FIG. 17). Other processes of preparing the initial light-emitting unit 120 may refer to the foregoing content, which will not be repeated herein any further.

Another embodiment is provided hereinafter. As illustrated in FIG. 51, the material of the light disturbing part 17 is the same as a material of the second electrode 18.

The light disturbing part 17 made of the same material as the second electrode 18 is configured to reflect a light ray acquired after a light ray emitted from the light-emitting layer 14 is propagated in the second semiconductor layer 15 and emitted from the side surface B1 of the second semiconductor layer 15.

In some embodiments, during preparation of the initial light-emitting unit 120, in process S104 (as illustrated in FIG. 9), the light disturbing part 17 is formed synchronously during formation of the second electrode 18 (as illustrated in FIG. 15). Other processes of preparing the initial light-emitting unit 120 may refer to the foregoing content, which will not be repeated herein any further.

That is, the light disturbing part 17 is formed during formation of the second electrode 18 by patterning; and the light disturbing part 17 and the second electrode 18 are disposed in the same layer.

Still another embodiment in which the light disturbing part 17 covers the side surface B1 of the second semiconductor layer 15 is provided hereinafter.

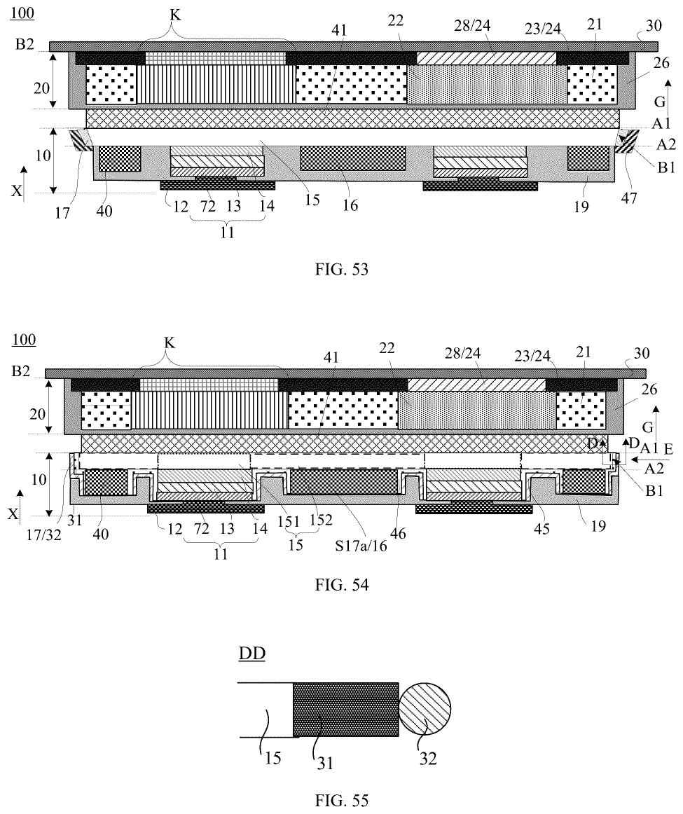

In some embodiments, as illustrated in FIGS. 52 and 53, the material of the light disturbing part 17 includes: a metal material, a semiconductor material, black resin, or any combination thereof.

In some embodiments, as illustrated in FIG. 52, the material of the light disturbing part 17 includes black resin. The black resin is used to absorb a light ray propagated in the second semiconductor layer 15 and emitted from the side surface B1 of the second semiconductor layer 15.

In some embodiments, as illustrated in FIG. 53, the material of the light disturbing part 17 includes amorphous silicon. The amorphous silicon is a semiconductor material and is used to absorb a light ray propagated in the second semiconductor layer 15 and emitted from the side surface B1 of the second semiconductor layer 15.

In some embodiments, as illustrated in FIG. 52, the material of the light disturbing part 17 includes a metal material silver. The silver is used to reflect a light ray propagated in the second semiconductor layer 15 and emitted from the side surface B1 of the second semiconductor layer 15

In some embodiments, during preparation of the initial light-emitting unit 120, in process S102 (as illustrated in FIG. 9), after the first semiconductor layer 13, the light-emitting layer 14, the N-type gallium nitride layer 156, and the gallium nitride buffer layer 155 are acquired via formation, the light disturbing part 17 is formed on a side surface of the N-type gallium nitride layer 156 and/or the gallium nitride buffer layer 155. Other processes of preparing the initial light-emitting unit 120 may refer to the foregoing content, which will not be repeated herein any further.

In some embodiments, as illustrated in FIGS. 52 and 53, a section of the second semiconductor layer 15 is trapezoid. That is, there is an angle between the side surface B1 of the second semiconductor layer 15 and the first direction X. The side surface B1 of the second semiconductor layer 15 is disposed at a position that is distal from and obliquely below the color converting unit 20, such that a light ray propagated in the second semiconductor layer 15 and emitted from the side surface B1 of the second semiconductor layer 15 can be reflected in a direction distal from the color converting unit 20, thereby preventing the light ray propagated in the second semiconductor layer 15 and emitted from the side surface B1 of the second semiconductor layer 15 from being emitted from the first substrate 30, and solving the problem of a light leak from the first substrate 30.

Still another embodiment in which the light disturbing part 17 covers the side surface B1 of the second semiconductor layer 15 is provided hereinafter.

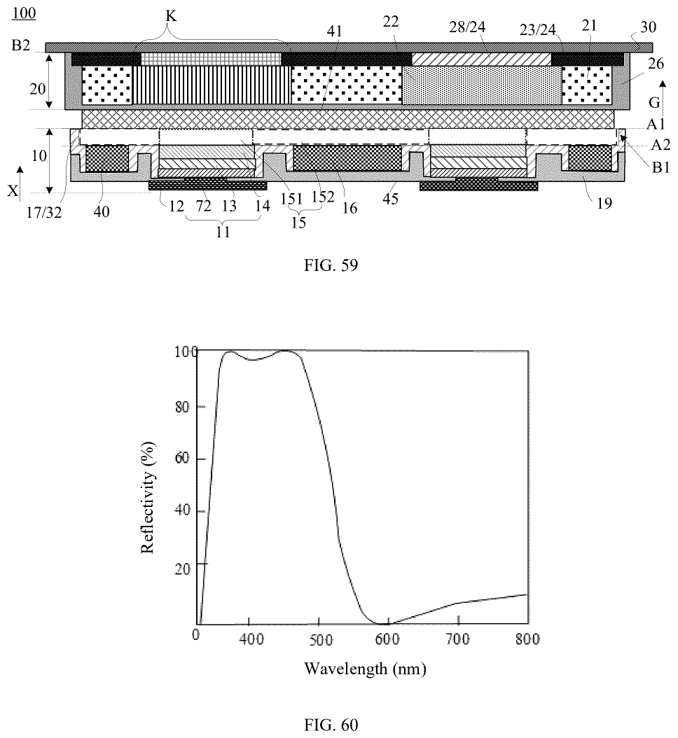

In some embodiments, as illustrated in FIGS. 54 and 59, the material of the light disturbing part 17 includes a nanosphere material.

In some examples, as illustrated in FIG. 54, the material of the light disturbing part 17 includes nano silver, nano gold, or nano aluminum.

That is, a nano layer 32 covering the side surface B1 is disposed on the side surface B1 of the second semiconductor layer 15.

In some embodiments, a radius of the nano silver ranges from 25 nm to 70 nm.

In some embodiments, the radius of the nano silver is 25 nm, 35 nm, 40 nm, 50 nm, 65 nm, 70 nm, or the like, which is not limited herein.

Because the dielectric constant of the metal material is high, by arranging the nano layer 32 made of a metal nano material, high reflection can be realized in a wide wave band range, and the light ray that is transversely propagated in the second semiconductor layer 15 to the side surface B1 of the second semiconductor layer 15 can be reflected.

In some examples, as illustrated in FIG. 54, the light disturbing part 17 includes a conductive material. The light-emitting unit 10 further includes: a first insulating layer 31 disposed between side surfaces of the light disturbing part 17 and the second semiconductor layer 15.

The light-emitting unit 10 further includes a common electrode layer 16 disposed on the side of the second semiconductor layer 15 distal from the color converting unit 20. The common electrode layer 16 includes a third portion S17a belonging to the common electrode layer 16, and further includes a first reflective pattern 40 spaced from the light-emitting part 11.

The light-emitting unit further includes: a second reflective pattern 45 that is disposed in a region between the light-emitting part 11 and the common electrode layer 16 and a region between the first reflective pattern 40 and the light-emitting part 11, and covers side surfaces of the first reflective pattern 40, the light-emitting part 11, and the common electrode layer 16.

In some embodiments, the second reflective pattern 45 and the light disturbing part 17 are disposed in the same layer. The second reflective pattern 45 is configured to reflect a light ray emitted from the second surface A2 of the second semiconductor layer 15, thereby improving the light-emitting efficiency of the display base plate 200.

In some embodiments, the second reflective pattern 45 covers the side surface of the light-emitting part 11; or the second reflective pattern 45 covers a side surface of a current spreading layer 72 of the light-emitting part 11, a side surface of the first semiconductor layer 13, and a side surface of the light-emitting layer 14.

In some embodiments, during preparation of the initial light-emitting unit 120, when the common electrode layer 16 is formed in process S104 (as illustrated in FIG. 9), as illustrated in FIG. 49, the third portion S17a and the first reflective pattern 40 of the common electrode layer 16 are formed synchronously; and then, the first insulating layer 31 and the nano layer 32 are formed to acquire the light disturbing part 17 and the second reflective pattern 45. Other processes of preparing the initial light-emitting unit 120 may refer to the foregoing content, which will not be repeated herein any further.

In some embodiments, as illustrated in FIG. 54, there is also a third insulating layer 46 disposed between the second reflective pattern 45 and the second semiconductor layer 15, between the second reflective pattern 45 and the first reflective pattern 40, between the second reflective pattern 45 and the light-emitting part 11, and between the second reflective pattern 45 and the common electrode layer 16.

It can be understood that the first insulating layer 31 and the third insulating layer 46 are disposed in the same layer.

In some embodiments, materials of the first insulating layer 31 and the third insulating layer 46 include silicon dioxide. Due to arrangement of the first insulating layer 31 and the third insulating layer 46, a nanosphere can be prevented from being connected to the current spreading layer 72 of the light-emitting part 11, the first semiconductor layer 13, the light-emitting layer 14, and the common electrode layer 16, thereby avoiding a short circuit.

In some examples, as illustrated in FIG. 53, the light-emitting unit 10 further includes: a second insulating layer 47 disposed on the side of the light disturbing part 17 distal from the second semiconductor layer 15.

In some embodiments, as illustrated in FIG. 54, a fourth insulating layer is disposed on the side of the second reflective pattern 45 distal from the second semiconductor layer 15 and the common electrode layer 16.

Due to arrangement of the second insulating layer 47 and the fourth insulating layer, solder paste can be prevented from overflowing in a subsequent process, thereby avoiding a short circuit caused by connection between the second semiconductor layer 15 and the common electrode layer 16.

Thicknesses of the first insulating layer 31, the second insulating layer 47, the third insulating layer 46, and the fourth insulating layer range from 0.2 μm to 0.5 μm.

In some embodiments, the thickness of the first insulating layer 31 is 0.2 μm, 0.3 μm, 0.4 μm, 0.5 μm, or the like, which is not limited herein.

In some embodiments, the thickness of the second insulating layer 47 is 0.2 μm, 0.3 μm, 0.4 μm, 0.5 μm, or the like, which is not limited herein.

In some embodiments, the thickness of the third insulating layer 46 is 0.2 μm, 0.3 μm, 0.4 μm, 0.5 μm, or the like, which is not limited herein.

In some embodiments, the thickness of the fourth insulating layer is 0.2 μm, 0.3 μm, 0.4 μm, 0.5 μm, or the like, which is not limited herein.

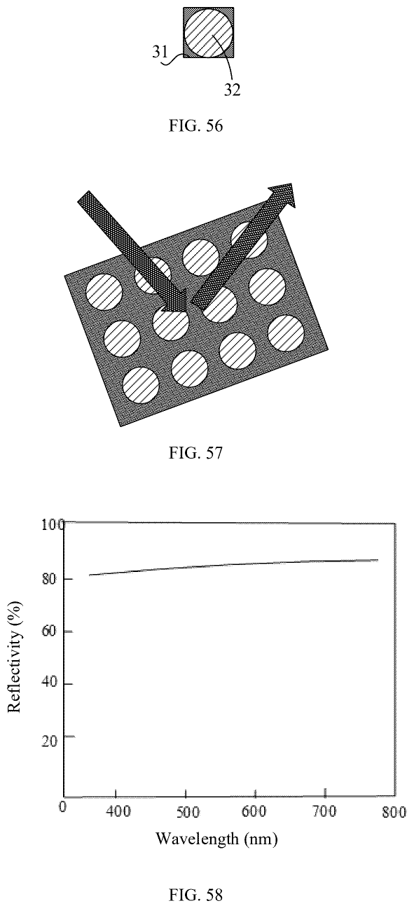

In some embodiments, an arranging mode of the nano layer 32 is provided. FIG. 55 is a sectional view acquired along a section line DD in FIG. 54. FIG. 56 is a view of the nano layer 32 acquired in a direction E in FIG. 54. The direction E is perpendicular to the nano layer 32, that is, the nano layer 32 covers the side of the first insulating layer 31 distal from the side surface B1 of the second semiconductor layer 15.

As illustrated in FIG. 57, due to arrangement of the nano layer 32, the light ray that is transversely propagated in the second semiconductor layer 15 to the side surface B1 of the second semiconductor layer 15 can be reflected effectively. As illustrated in FIG. 58, the reflectivity of the nano layer 32 for the light ray is higher than 80%. In addition, the light disturbing part 17 made of a metal nano material also absorbs a light ray that is transversely propagated in the second semiconductor layer 15 to the side surface B1 of the second semiconductor layer 15.

In some embodiments, as illustrated in FIG. 59, the material of the light disturbing part 17 includes a semiconductor nano material.

That is, the nano layer 32 covering the side surface B1 is disposed on the side surface B1 of the second semiconductor layer 15. In some embodiments, the material of the nano layer 32 includes: spherical silicon, wherein a radius of the silicon is 60 nm.

It should be noted that the silicon has a relatively high dielectric constant; nanometer sized silicon can generate strong Mie resonance; electromagnetic energy near a resonant frequency is enhanced remarkably; and electromagnetic radiation is limited in a resonant mode. Under a condition of magnetic dipole resonance, the transmittance of an array formed by the spherical silicon can be inhibited, such that high reflection is realized in a relatively wide wave band range, thereby reflecting the light ray that is transversely propagated in the second semiconductor layer 15 to the side surface B1 of the second semiconductor layer 15. It should be noted that Mie resonance is structural resonance at a microwave frequency.

In some embodiments, the radius of the spherical silicon is 60 nm; and the lattice constant of the spherical silicon is 150 nm. As illustrated in FIG. 60, the reflectivity of light rays whose wavelengths range from 380 nm to 500 nm are higher than 90%, such that the light ray that is transversely propagated in the second semiconductor layer 15 to the side surface B1 of the second semiconductor layer 15 can be reflected effectively.

In some embodiments, during preparation of the initial light-emitting unit 120, when the common electrode layer 16 is formed in process S104 (as illustrated in FIG. 9), as illustrated in FIG. 49, the third portion S17a and the first reflective pattern 40 of the common electrode layer 16 are formed synchronously; and then, the nano layer 32 made of the semiconductor nano material is formed to acquire the light disturbing part 17 and the second reflective pattern 45. Other processes of preparing the initial light-emitting unit 120 may refer to the foregoing content, which will not be repeated herein any further.

Still another embodiment of disposing the light disturbing part 17 is provided hereinafter.

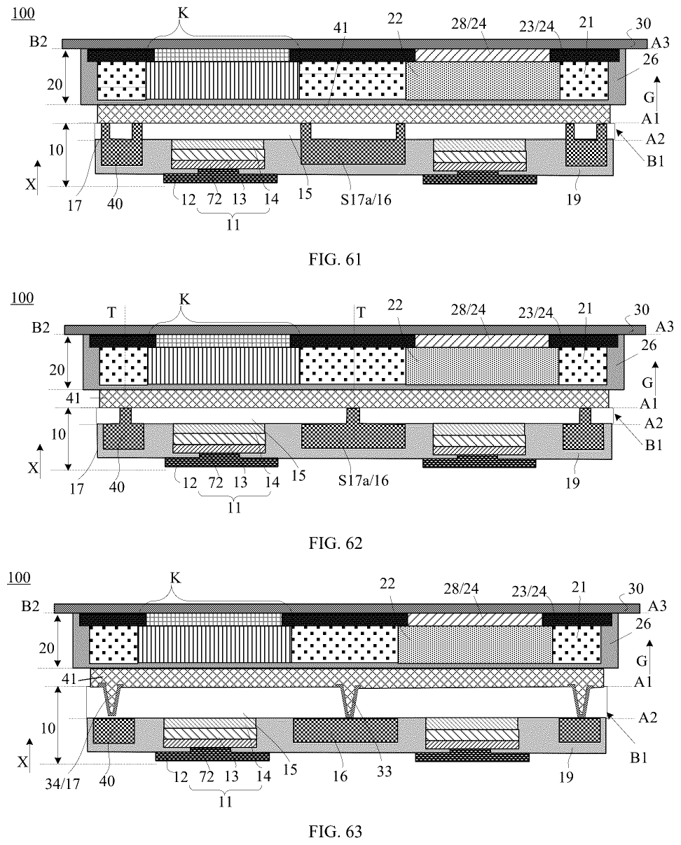

In some embodiments, as illustrated in FIG. 61, the color converting unit 20 includes: a defining dam layer 21 which defines a plurality of opening regions K, wherein one light-emitting part 11 corresponds to one opening region K in the first direction X. The first direction X is a direction in which the light-emitting unit 10 and the color converting unit 20 are laminated.

The light disturbing part 17 is embedded in the second semiconductor layer 15. In an orthographic projection to a reference surface A3, the light disturbing part 17 surrounds the light-emitting layer 14, and is within the range of the defining dam layer 21. The reference surface A3 is a plane in which a surface of the color converting unit 20 distal from the light-emitting unit 10 is disposed.

Due to the arrangement of the light disturbing part 17 embedded in the second semiconductor layer 15, the optical path, including propagation in the second semiconductor layer 15 and emission from the side surface B1 of the second semiconductor layer 15, of the light ray emitted from the light-emitting layer 14 is broken.

In some embodiments, as illustrated in FIG. 61, the light disturbing part 17 is disposed near a boundary of the opening region K.

That is, in the orthographic projection to the reference surface A3, the light disturbing part 17 is disposed near the boundary of the opening region K.

In some embodiments, as illustrated in FIG. 62, the light disturbing part 17 is disposed near a center line T of the defining dam layer 21 between two adjacent opening regions K.

That is, in the orthographic projection to the reference surface A3, the light disturbing part 17 is disposed near the center line T of the defining dam layer 21 between two adjacent opening regions K. Moreover, the light disturbing part 17 is also disposed on the center line T of the defining dam layer 21 in an edge region of the light-emitting chip 100.

In addition, as illustrated in FIGS. 61 and 62, the light disturbing part 17 penetrates the second semiconductor layer 15 in a direction perpendicular to the reference surface A3.

It should be noted that the direction perpendicular to the reference surface A3 is parallel to the first direction X. The light disturbing part 17 penetrates the second semiconductor layer 15 in the first direction X.

It can be understood that the light disturbing part 17 is disposed annularly in the second semiconductor layer 15, and is configured to block a light ray propagated in the second semiconductor layer 15, thereby changing an optical path of the light ray propagated in the second semiconductor layer 15, improving the emergent rate of the light ray along the first surface A1 of the second semiconductor layer 15, and blocking a light leak from the side surface B1 of the second semiconductor layer 15.

As illustrated in FIGS. 61 and 62, the light-emitting unit 10 further includes a common electrode layer 16; and the common electrode layer 16 includes a third portion S17a belonging to the common electrode layer 16, and may further include a first reflective pattern 40 spaced from the light-emitting part 11. For example, the material of the light disturbing part 17 is the same as a material of the common electrode layer 16; and the light disturbing part 17 and either the common electrode layer 16 or the first reflective pattern 40 are disposed integrally.

In the case that the light disturbing part 17 is connected to the common electrode layer 16, the light disturbing part 17 and the third portion S17a of the common electrode layer 16 are of an integrated structure.

In some embodiments, as illustrated in FIGS. 61 and 62, the light disturbing part 17 and either the first reflective pattern 40 or the third portion S17a of the common electrode layer 16 are of an integrated structure. That is, the material of the light disturbing part 17 is the same as the material of the common electrode layer 16.

In some embodiments, during preparation of the initial light-emitting unit 120, when the initial N-type gallium nitride layer 1560 and the initial gallium nitride buffer layer 1550 are patterned in process S102 (as illustrated in FIG. 9), a material in a region to be penetrated by the light disturbing part 17 is removed to form the second semiconductor layer 15. When the common electrode layer 16 is formed in process S104, the third portion S17a and the first reflective pattern 40 of the common electrode layer 16, and the light disturbing part 17 embedded in the second semiconductor layer 15 are formed synchronously.

Still another embodiment of disposing the light disturbing part 17 is provided hereinafter.

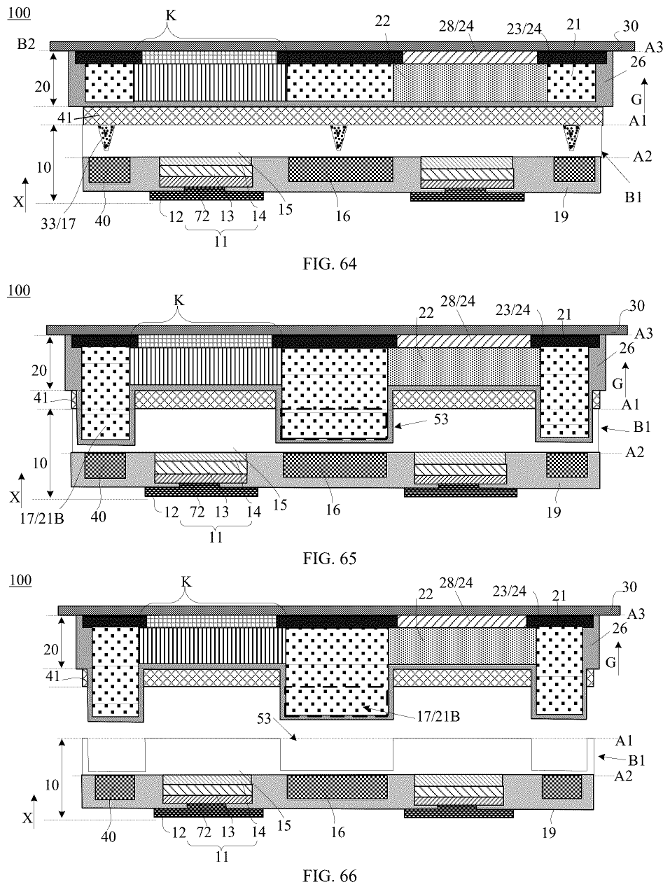

In some embodiments, as illustrated in FIGS. 63 and 64, the second semiconductor layer 15 is provided with a second groove 33, wherein a groove opening of the second groove 33 is on the first surface A1 of the second semiconductor layer 15; and in the orthographic projection to the reference surface A3, the second groove 33 is within the range of the defining dam layer 21. The light disturbing part 17 includes a metal layer 34 covering the slot bottom and the inner wall of the second groove 33, and/or scattering particles filled in the second groove 33. The reference surface A3 is a plane in which a surface of the color converting unit 20 distal from the light-emitting unit 10 is disposed.

It can be understood that the second groove 33 of the second semiconductor layer 15 is disposed annularly; and the metal layer 34 can reflect a light ray propagated in the second semiconductor layer 15, thereby improving the emergent rate of the light ray along the first surface A1 of the second semiconductor layer 15, and blocking a light leak from the side surface B1 of the second semiconductor layer 15.

In some embodiments, as illustrated in FIG. 63, a material of the metal layer 34 in the second groove 33 includes lithium, gold, or silver.

In some embodiments, as illustrated in FIG. 64, a material of the scattering particle includes titanium dioxide. A dimension of the scattering particle ranges from 10 nm to 1000 nm. For example, the dimension of the scattering particle is 10 nm, 50 nm, 100 nm, 200 nm, 500 nm, 750 nm, 1000 nm, or the like, which is not limited herein.

As the scattering particles are disposed in the second groove 33 of the second semiconductor layer 15, a refractive index of an interface between the scattering particle and the second semiconductor layer 15 is non-uniform, which causes light scattering. A light having a large angle is scattered into a light having a small angle, thereby avoiding total reflection.

In some embodiments, during preparation of the initial light-emitting unit 120, after the second substrate 91 is removed in process S108 (as illustrated in FIG. 9), patterning the second semiconductor layer 15 (including the laminated layer composed of the N-type gallium nitride layer 156 and the gallium nitride buffer layer 155, or the gallium nitride buffer layer 155, wherein in the case that the gallium nitride buffer layer 155 does not exist, the second semiconductor layer 15 may be the N-type gallium nitride layer 156) to form the second groove 33; and then, the metal layer 34 is formed in the second groove 33 via a patterning process, or the scattering particles are formed in the second groove 33, to acquire the light disturbing part 17.

Still another embodiment of disposing the light disturbing part 17 is provided hereinafter.

In some embodiments, as illustrated in FIG. 65, in the direction perpendicular to the reference surface A3, an end of the defining dam layer 21 proximal to the light-emitting unit 10 extends into the second semiconductor layer 15; and the defining dam layer 21 extending into the second semiconductor layer 15 is reused as the light disturbing part 17. The reference surface A3 is a plane in which a surface of the color converting unit 20 distal from the light-emitting unit 10 is disposed.

That is, the defining dam layer 21 penetrates the adhesion connecting layer 41 and extends into the second semiconductor layer 15; and the defining dam layer 21 penetrating the second semiconductor layer 15 can block a light ray propagated in the second semiconductor layer 15, thereby changing an optical path of the light ray propagated in the second semiconductor layer 15, and blocking a light leak from the side surface B1 of the second semiconductor layer 15.

In some embodiments, as illustrated in FIG. 66, the first surface A1 of the second semiconductor layer 15 is provided with a recess 53 matched with the shape of the end of the defining dam layer 21 proximal to the light-emitting unit 10; and the end 21B of the defining dam layer 21 proximal to the light-emitting unit 10 extends into the recess 53.

As illustrated in FIG. 66, the end 21B that is of the defining dam layer 21 proximal to the light-emitting unit 10 and extends into the recess 53 can block a light ray propagated in the second semiconductor layer 15, thereby changing an optical path of the light ray propagated in the second semiconductor layer 15.

As illustrated in FIG. 65, the light-emitting chip 100 further includes an adhesion connecting layer 41 configured to connect the light-emitting unit 10 to the color converting unit 20. The color converting unit 20 further includes an optical functional part 22 disposed in the opening regions K of the defining dam layer 21, and an encapsulating layer 26 configured to encapsulate the optical functional part 22 and the defining dam layer 21. The end 21B of the defining dam layer 21 proximal to the light-emitting unit 10 penetrates the adhesion connecting layer 41. A portion of the encapsulating layer 26 extends into the recess 53, and encapsulates the end 21B of the defining dam layer 21 extending into the recess 53.

In some embodiments, during preparation of the initial light-emitting unit 120, after the second substrate 91 is removed in process S108 (as illustrated in FIG. 9), the recess 53 is formed on the first surface A1 of the second semiconductor layer 15 by a photolithography process. Then, adhesive forming the adhesion connecting layer 41 is applied on the first surface A1 of the second semiconductor layer 15. Subsequently, the light-emitting unit 10 and the color converting unit 20 are cell aligned, to form a structure in which the end 21B of the defining dam layer 21 proximal to the light-emitting unit 10 extends into the recess 53 of the second semiconductor layer 15. Finally, a temporary substrate 70 is stripped to form the light-emitting chip 100.

As the encapsulating layer 26 encapsulates the end 21B of the defining dam layer 21 extending into the recess 53, a problem that a light leak appears in a region of the optical functional part 22 at the end 21B of the defining dam layer 21 can be avoided effectively. Therefore, the encapsulating effect is improved.

Still another embodiment of disposing the light disturbing part 17 is provided hereinafter.

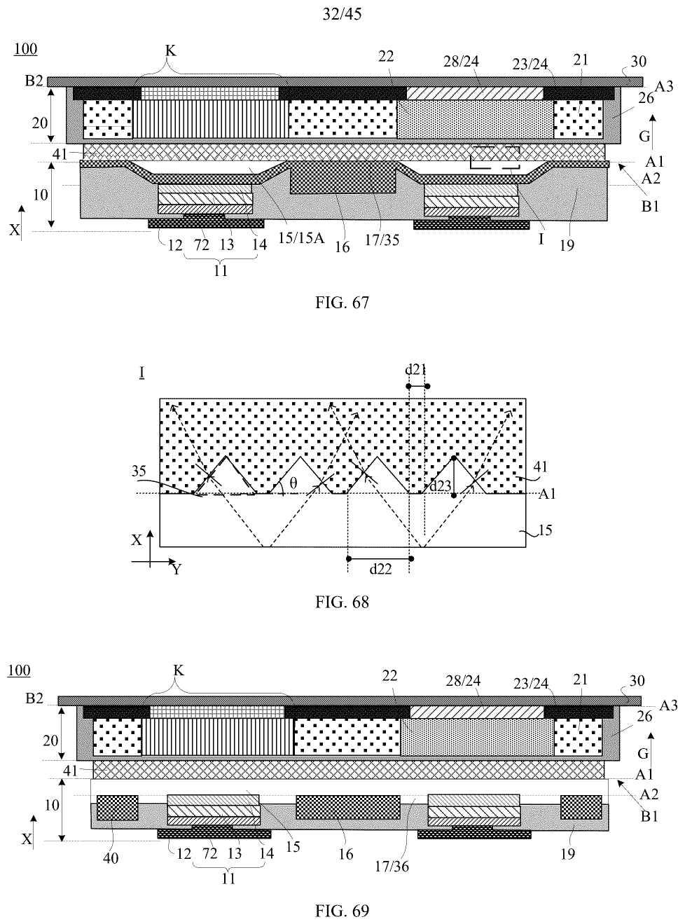

In some embodiments, as illustrated in FIG. 67, the second semiconductor layer 15 includes a plurality of semiconductor parts 15A disposed at intervals; and in the orthographic projection to the reference surface A3, one semiconductor part 15A covers at least one light-emitting part 11. The light disturbing part 17 includes a light extracting structure disposed on the first surface A1 of the second semiconductor layer 15 The reference surface A3 is a plane in which a surface of the color converting unit 20 distal from the light-emitting unit 10 is disposed.

In some embodiments, as illustrated in FIG. 67, the light extracting structure includes a plurality of protrusions 35 disposed in an array, wherein the protrusions 35 are triangles or trapezoids.

That is, a second semiconductor layer 15 disposed as an integral layer is separated for arrangement, which breaks an optical waveguide caused by integral arrangement of the second semiconductor layer 15. In addition, as illustrated in FIG. 67, the common electrode layer 16 covers all surfaces of the second semiconductor layer 15 except the first surface A1, such that a light leak from the side surface of the second semiconductor layer 15 is blocked.

Due to arrangement of the plurality of protrusions 35, a waveguide interface of the second semiconductor layer 15 is broken, and a light ray locked in a waveguide previously can be propagated upwards, such that the light extracting efficiency of the light-emitting chip 100 is increased.

In some embodiments, as illustrated in FIG. 67, the light extracting structure is disposed as an integral layer in a plane where the first surface A1 of the second semiconductor layer 15 is disposed. That is, the light extracting structure is also disposed in a region between adjacent semiconductor parts 15A. The light extracting structure that is disposed as an integral layer does not need to be patterned, such that the light extracting structure is convenient to prepare.

In some examples, as illustrated in FIG. 68, each of the protrusions 35 is a triangle or a trapezoid. A bottom angle θ of the protrusion 35 is 50.9°. The bottom angle θ of the protrusion 35 is an angle between the protrusion 35 and the first surface A1 of the second semiconductor layer 15.

In some embodiments, a structure of the protrusion 35 illustrated in FIG. 68 is a triangle. For example, a bottom diameter d22 of the triangle is 2.6 μm, and a height d23 of the triangle is 1.6 μm.

In some embodiments, the light extracting structure is prepared by a photolithography process.

In some embodiments, as illustrated in FIG. 68, the shortest distance d21 between every two adjacent protrusions 35 of the plurality of protrusions 35 in the second direction Y is 3 μm; and the second direction Y is perpendicular to the first direction X.

Due to the arrangement of the light extracting structure, light rays that are propagated upwards and enter the color converting unit 20 can be expanded from only light rays L1 (as illustrated in FIG. 47) with angles smaller than 39.5° to light rays with angles larger than 11.4°, such that the range of emergence angles is enlarged, and the light utilization of the light-emitting chip 100 is increased. Moreover, as the second semiconductor layer 15 disposed as an integral layer is separated for arrangement, and the light extracting structure is provided, crosstalk between pixels of the plurality of light-emitting parts 11 can also be blocked to reduce a risk of color cast.

Still another embodiment of disposing the light disturbing part 17 is provided hereinafter.

In some embodiments, as illustrated in FIG. 69, the light-emitting part 11 further includes a common electrode layer 16 and a first electrode 12 electrically connected to the light-emitting layer 14, and are disposed on the second surface A2 of the second semiconductor layer 15. The light disturbing part 17 includes a protruded ring 36 disposed on the second surface A2 of the second semiconductor layer 15; and in the orthographic projection to the reference surface A3, the protruded ring 36 surrounds the first electrode 12 and the common electrode layer 16. The reference surface A3 is a plane in which a surface of the color converting unit 20 distal from the light-emitting unit 10 is disposed.

In some embodiments, the protruded ring 36 and the second semiconductor layer 15 are of an integrated structure.

The protruded ring 36 and the second semiconductor layer 15 being of an integrated structure means that second semiconductor layers 15 having different film thicknesses are provided.

In some embodiments, during preparation of the initial light-emitting unit 120, in process S101 (as illustrated in FIG. 9), first, the initial gallium nitride buffer layer 1550 and the initial N-type gallium nitride layer 1560 are sequentially formed on a side of the second substrate 91; then, the initial gallium nitride buffer layer 1550 and the initial N-type gallium nitride layer 1560 are patterned; the thicknesses of the N-type gallium nitride layer 156 and the gallium nitride buffer layer 155 that are formed in a region where the first electrode 12 and the common electrode layer 16 are preformed are relatively thin; finally, the initial quantum well layer 1210 and the initial P-type gallium nitride layer 1220 are deposited. Other processes of preparing the initial light-emitting unit 120 may refer to the foregoing content, which will not be repeated herein any further.

As the thicknesses of second semiconductor layers 15 in different regions are set to different values, an optical waveguide effect of the second semiconductor layer 15 can be weakened effectively, thereby weakening the light leak from the side surface B1 of the second semiconductor layer 15.

Still another embodiment of disposing the light disturbing part 17 is provided hereinafter.

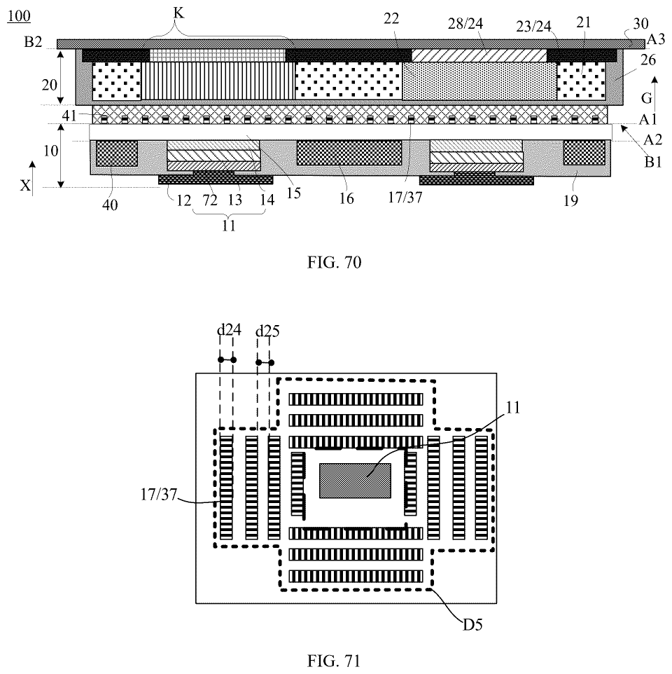

In some embodiments, as illustrated in FIG. 70, the light disturbing part 17 includes: a plurality of rows of grating strips 37 disposed on the first surface A1 of the second semiconductor layer 15 at intervals. In the orthographic projection to the reference surface A3, the plurality of rows of grating strips 37 are disposed surrounding the light-emitting layer 14. The reference surface A3 is a plane in which a surface of the color converting unit 20 distal from the light-emitting unit 10 is disposed.

That is, the grating strips 37 are disposed in regions surrounding the plurality of light-emitting parts 11.

In some embodiments, a material of the grating strip 37 includes: silicon oxide, titanium oxide, or silicon nitride.

In some embodiments, as illustrated in FIG. 71, a width d24 of the grating strip 37 ranges from 50 nm to 500 nm. A distance d25 between adjacent grating strips 37 ranges from 50 nm to 1000 nm. For example, the width d24 of the grating strip 37 is 50 nm, 100 nm, 150 nm, 200 nm, 250 nm, 500 nm, or the like, which is not limited herein. The distance d25 between adjacent grating strips 37 is 50 nm, 100 nm, 200 nm, 300 nm, 800 nm, 1000 nm, or the like, which is not limited herein.

The grating strips 37 on the first surface A1 of the second semiconductor layer 15 may diffract a light ray, such that the light ray cannot be totally reflected in the second semiconductor layer 15, thereby improving the emergent rate of the light ray from the first surface A1 of the second semiconductor layer 15

In some embodiments, during preparation of the initial light-emitting unit 120, after the second substrate 91 is removed in process S108 (as illustrated in FIG. 9), the grating strips 37 are formed on the first surface A1 of the second semiconductor layer 15 by a patterning process. Other processes of preparing the initial light-emitting unit 120 may refer to the foregoing content, which will not be repeated herein any further.

Still another embodiment of disposing the light disturbing part 17 is provided hereinafter.

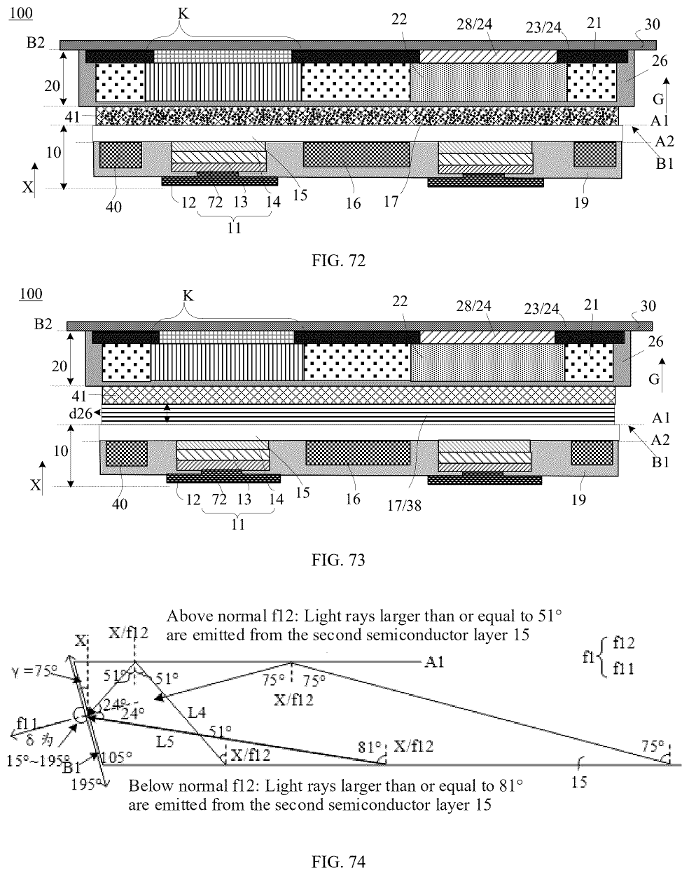

In some embodiments, as illustrated in FIG. 72, the light-emitting chip 100 further includes an adhesion connecting layer 41 disposed between the light-emitting unit 10 and the color converting unit 20 and configured to connect the light-emitting unit 10 to the color converting unit 20. The light disturbing part 17 includes scattering particles dispersed in the adhesion connecting layer 41.

In some embodiments, a material of the scattering particles includes titanium dioxide. A dimension of the scattering particle ranges from 10 nm to 1000 nm. For example, the dimension of the scattering particle is 10 nm, 50 nm, 100 nm, 200 nm, 500 nm, 750 nm, 1000 nm, or the like, which is not limited herein

As the scattering particles are dispersed in the adhesion connecting layer 41, the refractive index of the interface between the second semiconductor layer 15 and the adhesion connecting layer 41 is non-uniform. Therefore, the light ray is scattered, thereby effectively avoiding total reflection on the interface between the second semiconductor layer 15 and the adhesion connecting layer 41.

In some embodiments, after the initial light-emitting unit 120 and the color converting unit 20 are formed, when cell aligning the color converting unit 20 with the initial light-emitting unit 120 is performed using the adhesion connecting layer 41 formed by the adhesive layer 133, in process P301 (as illustrated in FIG. 37), during applying of the adhesive layer 133 on the side of the initial light-emitting unit 120 distal from the temporary substrate 70, the scattering particles are dispersed in the adhesive layer 133, thereby forming the scattering particles dispersed in the adhesion connecting layer 41, and acquiring the light disturbing part 17. For processes of preparing the initial light-emitting unit 120 and the color converting unit 20, and another process of cell aligning the color converting unit 20 with the initial light-emitting unit 120, reference may be made to the foregoing content. Details are not described herein any further.

Still another embodiment of disposing the light disturbing part 17 is provided hereinafter.

In some embodiments, as illustrated in FIG. 73, the light-emitting chip 100 further includes an adhesion connecting layer 41 disposed between the light-emitting unit 10 and the color converting unit 20 and configured to connect the light-emitting unit 10 to the color converting unit 20. The light disturbing part 17 includes a plurality of light guide films 38 that are sequentially laminated on the side of the adhesion connecting layer 41 proximal to the light-emitting unit 10. In the first direction X and from the light-emitting unit 10 to the color converting unit 20, the refractive indexes of the plurality of light guide films 38 decrease sequentially.

Because an optical waveguide is formed when a light ray is propagated transversely in the second semiconductor layer 15 due to a relatively large difference between the refractive indexes of the second semiconductor layer 15 and the adhesion connecting layer 41, the plurality of light guide films 38 with gradually varied refractive indexes destroy the optical waveguide effect of the second semiconductor layer 15.

In some embodiments, during preparation of the initial light-emitting unit 120, after the second substrate 91 is removed in process S108 (as illustrated in FIG. 9), the plurality of light guide films 38 are formed on the first surface A1 of the second semiconductor layer 15 by a patterning process Other processes of preparing the initial light-emitting unit 120 may refer to the foregoing content, which will not be repeated herein any further.

A design principle for the refractive indexes of the light guide films 38 is described hereinafter.

As illustrated in FIG. 74, the No. 1 normal line f1 is differentiated into a first normal line f11 and a second normal line f12. A normal line on the side surface B1 of the second semiconductor layer 15 is the first normal line f11; and normal lines on the first surface A1 and the second surface A2 of the second semiconductor layer 15 are the second normal line f12. It can be understood that the second normal line f12 is parallel to the first direction X.

From the foregoing analysis of the light leak W1 (as illustrated in FIG. 47) and the light leak W2 (as illustrated in FIG. 48), it can be learned that the critical angle α2 at which total reflection is formed between the second semiconductor layer 15 and air is 24°. That is, on the side surface B1 of the second semiconductor layer 15, a light ray L3 (as illustrated in FIG. 47) is formed after emergence of a light ray whose angle with the first normal line f11 is smaller than 24°; and a light leak caused by the light ray L3 results in color cast.

As illustrated in FIG. 74, a section of the second semiconductor layer 15 is trapezoid. That is, there is an angle γ between the side surface B1 of the second semiconductor layer 15 and the first direction X. For example, the angle γ is 75°.

As illustrated in FIG. 74, on the first surface A1 of the second semiconductor layer 15, the angle between a light ray L4 and the second normal line f12 is 51°; and a light ray whose angle with the first normal line f11 of the side surface B1 of the second semiconductor layer 15 is 24° is formed after the light ray L4 is reflected by the first surface A1 of the second semiconductor layer 15. On the first surface A1 of the second semiconductor layer 15, a light ray whose angle with the first normal line f11 of the side surface B1 of the second semiconductor layer 15 is smaller than or equal to 24° is formed after a light ray whose angle with the second normal line f12 is larger than or equal to 51° is reflected by the first surface A1 of the second semiconductor layer 15; and then, the light ray L3 (as illustrated in FIG. 47) is emitted from the side surface B1 of the second semiconductor layer 15. Therefore, on the first surface A1 of the second semiconductor layer 15, after a light ray whose angle with the second normal line f12 is larger than or equal to 51° is reflected by the first surface A1 of the second semiconductor layer 15, a light ray is emitted from the side surface B1 of the second semiconductor layer 15.

As illustrated in FIG. 74, on the second surface A2 of the second semiconductor layer 15, the angle between a light ray LS and the second normal line f12 is 81°; and a light ray whose angle with the first normal line f11 of the side surface B1 of the second semiconductor layer 15 is 24° is formed after the light ray LS is reflected by the second surface A2 of the second semiconductor layer 15. On the second surface A2 of the second semiconductor layer 15, a light ray whose angle with the first normal line f11 of the side surface B1 of the second semiconductor layer 15 is smaller than or equal to 24° is formed after a light ray whose angle with the second normal line f12 is larger than or equal to 81° is reflected by the second surface A2 of the second semiconductor layer 15; and then, the light ray L3 (as illustrated in FIG. 47) is emitted from the side surface B1 of the second semiconductor layer 15.

Therefore, from the path diagram of the light ray L4 and the light ray LS in FIG. 74 and data in Table 1, it can be learned that light rays that are in the second semiconductor layer 15 and whose angles with the first direction X are 51° to 81° are emitted from the side surface B1 of the second semiconductor layer 15, and angles 8 of light rays emitted in air are 15° to 195°. That is, there is a 180° sectorial light-outputting surface on the side surface B1 of the second semiconductor layer 15.

A proportion of light leaks of light rays that are in the second semiconductor layer 15 and whose angles with the first direction X are 51° to 85° can be learned from the data in Table 1, wherein Δx and Δy are deviation values from a color group table. To block color cast caused by a light leak, blocking all light rays that may be emitted in air is a basis for calculating a chromaticity coordinate Δx and Δy of a blocked portion are calculated, wherein Δx≤0.05, and Δy≤0.05.

From the proportion the light leaks, it may be learned that a light ray that is in the second semiconductor layer 15 and whose angle with the first direction X is 85° also has a light leak. That is, there is also a light leak if emergence of only the light rays that are in the second semiconductor layer 15 and whose angles with the first direction X are 51° to 81° is blocked. Therefore, emergence of light rays that are in the second semiconductor layer 15 and whose angles with the first direction X are within 0° to 85° needs to be blocked.

TABLE 1
Light-shielding angle of the second semiconductor layer and color cast calculation

| Angle | | Incidence | Emergence | | | | | |
|---|---|---|---|---|---|---|---|---|
| with a | Proportion | angle on | angle on a | Angle of a | | | | |
| vertical | of a light | a normal | normal | light ray | Blocking | Residual | | |
| direction | leak | line | line | emitted in air | angle | proportion | Δx | Δy |
| −51 | 25% | 24.089 | 89.6 | 15.4 | 51° | 75% | 0.0373 | 0.5623 |
| −55 | 20% | 20 | 56.9 | 48.1 | 51°~55° | 56% | 0.0344 | 0.5196 |
| −60 | 15% | 15 | 39.4 | 65.6 | 51°~60° | 40% | 0.0301 | 0.4674 |
| −65 | 12% | 10 | 25.2 | 78.9 | 51°~65° | 28% | 0.0268 | 0.4038 |
| −70 | 10% | 5 | 12.3 | 92.7 | 51°~70° | 18% | 0.0216 | 0.3264 |
| −75 | 8% | 0 | 0 | 105 | 51°~75° | 11% | 0.0156 | 0.2347 |
| −80 | 6% | 24 | −85.2 | 192.2 | 51°~80° | 5% | 0.0086 | 0.1268 |
| −85 | 5% | 20 | −56.9 | 161.9 | 51°~85° | 0% | 0.0000 | 0.0000 |

The following are calculated according to critical angles of adjacent interfaces: 2.45×sin 85°=n2×sin 90°→n2=2.44067, 2.44067×sin 85°=n3×sin 90°→n3=2.43147, 2.43147×sin 85°=n4×sin 90°→n4=2.4221, and so on. The purpose that all light rays whose angles are within 0° to 85° are propagated upwards can be met only when the difference between the refractive indexes of two adjacent light guide films 38 reaches 0.01, thereby resolving the problem that a light leak of an optical waveguide occurs on a side wall of the second semiconductor layer 15.

Therefore, in the plurality of light guide films 38, the difference between the refractive indexes of every two adjacent light guide films 38 is larger than or equal to 0.01.

According to calculation, (2.45−1.56)=0.89/0.01=89 layers. Therefore, a gradual variation of refractive indexes from 2.45 to 1.56 without any color cast or light leak can be realized when there are 89 light guide films 38 with varied refractive indexes.

In some examples, as illustrated in FIG. 73, the thickness of each of the plurality of light guide films 38 ranges from 20 nm to 50 nm; and the total thickness d26 of the plurality of light guide films 38 ranges from 2 μm to 4 μm.

For example, the thickness of each light guide film 38 is 20 nm, 30 nm, 35 nm, 40 nm, 45 nm, 50 nm, or the like, which is not limited herein.

For example, the total thickness d6 of the plurality of light guide films 38 is 2 μm, 3 μm, 4 μm, or the like, which is not limited herein.

In some examples, a material of the light guide film 38 includes silicon dioxide.

It should be noted that the refractive indexes of light guide films 38 vary with their porosities, and a larger porosity leads to a smaller refractive index. Therefore, the refractive indexes vary gradually by controlling the porosities of the light guide films 38 to vary linearly. In this way, the light guide films 38 with gradually varied refractive indexes are prepared.

For example, polyethylene glycol molecules are added into acid-catalyzed sol; the light guide films 38 with gradually varied refractive indexes are prepared by using the water-soluble property of polyethylene glycol; and polyethylene glycol exists in silicon dioxide sol via simply physical dissolution. When the film is soaked in water, the exterior of the film is in sufficient contact with water. Polyethylene glycol in the film is sufficiently dissolved and precipitated. At a position closer to the center of the film, a channel for polyethylene glycol to dissolve and precipitate is narrower, and a hole left after precipitation is smaller. Therefore, a silicon dioxide gel material with gradually increased porosities and gradually decreased refractive indexes from the inside out is acquired. Silicon dioxide gel materials having different refractive indexes are acquired layer by layer. A plurality of layers of polyethylene glycol with gradually varied refractive indexes are prepared by using a TFE (thin film encapsulation)-CVD (chemical vapor deposition) process.

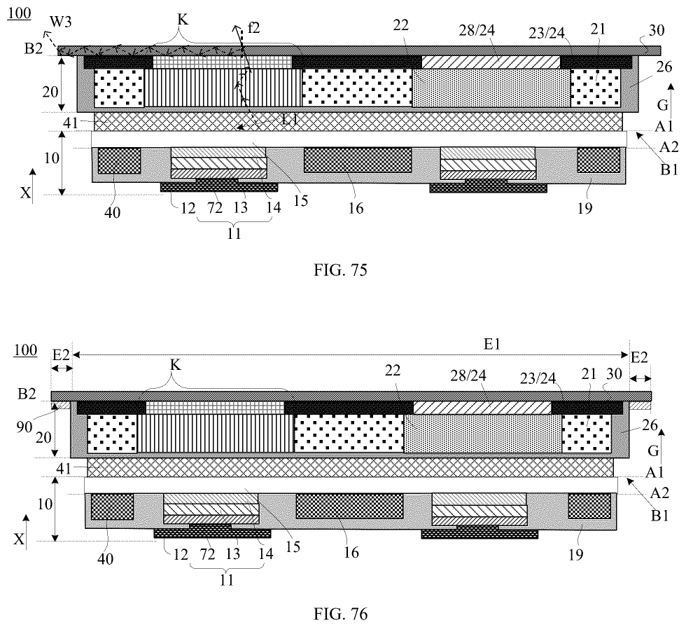

In the related art, as illustrated in FIG. 75, the refractive index of air is 1.0; and the refractive index of the first substrate 30 is 1.5. Because the difference between the refractive indexes of the first substrate 30 and air is relatively great, total reflection is formed on an interface between the first substrate 30 and air. A normal line perpendicular to the first substrate 30 is referred to as a No. 2 normal line f2. A light ray whose angle with the No. 2 normal line f2 is smaller than a critical angle α3 is emitted from the first substrate 30 to air. A light ray whose angle with the No. 2 normal line f2 is larger than or equal to the critical angle α3 is totally reflected in the first substrate 30.

It should be noted that the critical angle α3 at which total reflection is formed between the first substrate 30 and air is calculated according to.

$$sin α3 \times 1.5 = sin 90 ° \times 1. .$$

Therefore, α3 is 41.8°.

That is, as illustrated in FIG. 75, a light ray whose angle with the No. 2 normal line f2 is smaller than 41.8° is emitted from the first substrate 30 to air. A light ray whose angle with the No. 2 normal line f2 is larger than or equal to 41.8° is totally reflected in the first substrate 30. A light leak W3 is formed on an edge of the first substrate 30.

Due to a negative effect of the light leak W1 (as illustrated in FIG. 47), the light leak W2 (as illustrated in FIG. 48), and the light leak W3 that are describe above, the light-emitting efficiency and the display effect of the display base plate 200 are reduced. The following embodiments are provided hereinafter to resolve the problem of the light leak on the edge of the first substrate 30

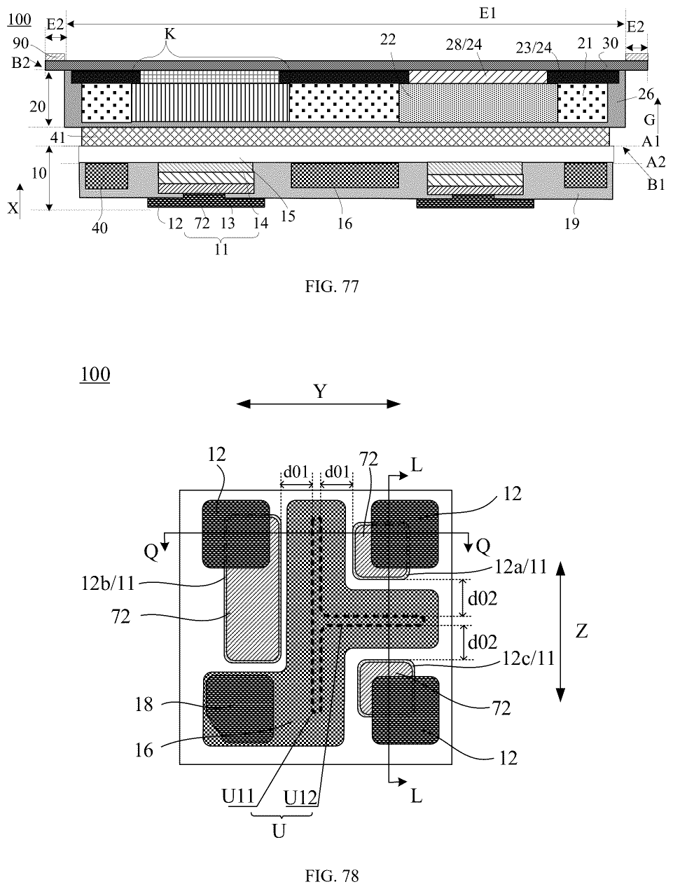

In some embodiments, as illustrated in FIGS. 76 and 77, the light-emitting chip 100 further includes: a first substrate 30 disposed on the side of the color converting unit 20 distal from the light-emitting unit 10. The first substrate 30 includes a first portion E1 and a second portion E2 surrounding the first portion E1. The first portion E1 overlaps with the color converting unit 20. The second portion E2 does not overlap with the color converting unit 20. The light-emitting chip 100 further includes a light-blocking part 90 disposed on the surface of the second portion E2 proximal to the color converting unit 20, or on the surface of the second portion E2 distal from the color converting unit 20

It should be noted that as illustrated in FIG. 8, the wafer 300 includes a plurality of light-emitting chips 100 that are disposed in an array. A single light-emitting chip 100 is formed by dicing the wafer 300. Therefore, a dicing path J is provided on the first substrate 30 of the wafer 300. The dicing path J is disposed between the light-emitting chips 100 disposed in the array; and the light-emitting chips 100 are formed by dicing the first substrate 30 along the dicing path J. It may be understood that the second portion E2 of the first substrate 30 partially overlaps with the dicing path J of the first substrate 30.

As the light-blocking part 90 is disposed on the second portion E2 of the first substrate 30, the light leak W1, the light leak W2, and the light leak W3 can be absorbed or reflected, thereby resolving the problem of a light leak from the side surface B2 of the first substrate 30.

In some examples, as illustrated in FIG. 76, the light-blocking part 90 is disposed on the surface of the second portion E2 proximal to the color converting unit 20. A material of the light-blocking part 90 includes a metal used for reflecting a light ray emitted from the side surface B1 of the second semiconductor layer 15.

In some embodiments, the light-blocking part 90 is formed by deposition.

In some embodiments, during preparation of the color converting unit 20, after the encapsulating layer 26 is formed in process R203 (as illustrated in FIG. 26), the light-blocking part 90 is formed on the side of the dicing path J region of the initial first substrate 310 proximal to the optical functional part 22 by a patterning process.

As illustrated in FIGS. 47, 48, and 76, as the light-blocking part 90 is disposed on the surface of the second portion E2 of the first substrate 30 proximal to the color converting unit 20, the light-blocking part 90 blocks the light leak W1 and the light leak W2, and reflects the light ray L3 back into the light-emitting chip 100, such that the light ray can be emitted only through the color converting unit 20, thereby improving the light extracting rate of the light-emitting chip 100.

In some examples, as illustrated in FIG. 77, the light-blocking part 90 is disposed on the surface of the first substrate 30 distal from the color converting unit 20.

In some embodiments, in the process of forming the light-emitting chip 100 after formation of the initial light-emitting unit 120 and the color converting unit 20 and during cell aligning the color converting unit 20 with the initial light-emitting unit 120 using the adhesion connecting layer 41 formed by the adhesive layer 133, after the initial first substrate 310 is thinned to form the first substrate 30 in process P304 (as illustrated in FIG. 36), the light-blocking part 90 is formed on the side of the dicing path J region of the first substrate 30 distal from the optical functional part 22 by a patterning process.

A material of the light-blocking part 90 includes: black resin, amorphous silicon, or titanium dioxide, and is used to absorb a light acquired after a light ray emitted along a side surface of the second semiconductor layer 15 is emitted from the second portion E2, and absorb a light acquired after a light ray emitted by the light-emitting layer 14 is propagated in the first substrate 30 and is emitted from the side surface B2 of the first substrate 30.

Therefore, black resin, amorphous silicon, and titanium dioxide are light-absorbing materials The light-absorbing material is disposed on at the periphery of the second portion E2, such that the light leak W1, the light leak W2, and the light leak W3 can be absorbed, thereby improving the light-emitting efficiency and the display effect of the display base plate 200.

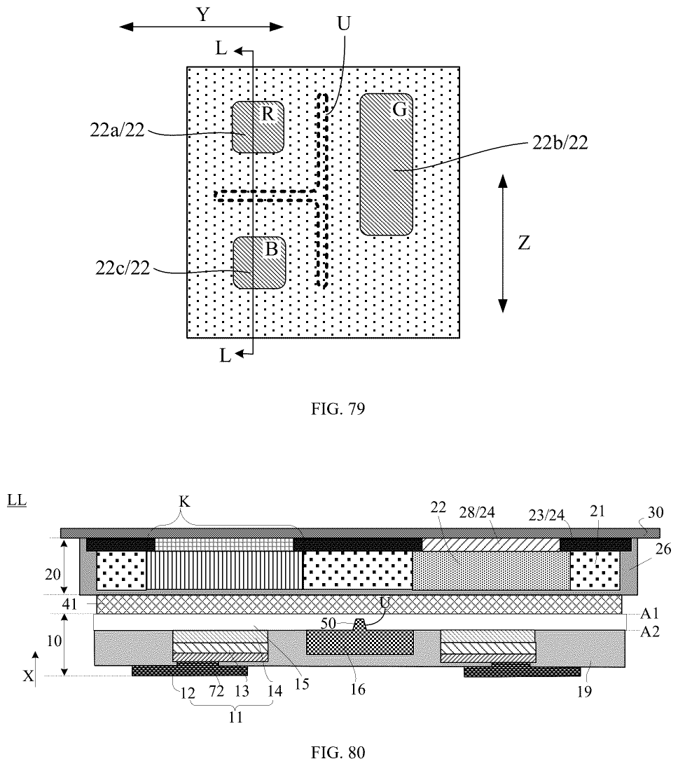

It should be noted that the foregoing embodiments are illustrated by using an example in which the second semiconductor layer 15 is provided with the second groove 33 and the groove opening of the second groove 33 is on the first surface A1 of the second semiconductor layer 15. In some other embodiments, refer to FIGS. 61, 62, 78, 79, and 80. FIG. 78 is a bottom view of a light-emitting chip according to some other embodiments of the present disclosure. Refer to FIG. 79 which is a top view of a light-emitting unit illustrated in FIG. 78. FIG. 80 is a sectional view of a light-emitting chip illustrated in FIGS. 78 and 79 along a line LL. The second semiconductor layer 15 may include a first groove U whose opening is on the second surface A2. That is, the opening of the first groove U formed in the second semiconductor layer 15 is on the second surface A2 of the second semiconductor layer 15.

The first groove U is at least disposed between the orthographic projections of two adjacent light-emitting parts 11 in the plurality of light-emitting parts 11 on an extension surface of the second semiconductor layer 15. Herein, the extension surface of the second semiconductor layer 15 is an extension surface of the first surface A1 of the second semiconductor layer 15, or an extension surface of the second surface A2 of the second semiconductor layer 15.

In some embodiments of the present disclosure, as illustrated in FIG. 80, the light-emitting chip 100 further includes: a filling part 50 disposed in the first groove U. The filling part 50 may be made of an opaque material. In some embodiments, the opaque material herein is a metal material. For example, the opaque material is one or more of copper, aluminum, gold, silver, molybdenum, titanium, chromium, or other metal materials. In some other embodiments, the opaque material is an opaque organic material. For example, the opaque material is light-shielding resin, a gel material doped with a light-absorbing dye (for example, carbon black), or the like.

In some embodiments, the filling part 50 includes a metal layer that is most proximal to the first groove U. A material of the metal layer is gold or silver. In this case, reflection of a light ray by the filling part 50 can be enhanced, such that utilization of a light ray emitted by the light-emitting part is improved. For example, the metal layer is a part of the common electrode layer 16.

It may be understood that in some embodiments of the present disclosure, the filling part 50 is a light disturbing part 17.

In some embodiments of the present disclosure, a light ray emitted from the light-emitting part 11 in the light-emitting unit 10 is emitted after passing through the second semiconductor layer 15 and the color converting unit 20 sequentially. Due to the difference between the refractive indexes of medium in different layers, some of light rays emitted into the second semiconductor layer 15 are propagated in an extension direction of the second semiconductor layer 15; and after a light ray propagated to a region where an adjacent light-emitting part 11 is disposed is emitted after passing through the color converting unit 20, the light-emitting chip 100 displays a color abnormally

For example, in the case that there are a plurality of light-emitting parts 11, the second semiconductor layer 15 is a surface-shaped structure disposed as an integral layer. Therefore, it is highly easy for a portion of light rays emitted into the second semiconductor layer 15 to generate an optical waveguide in the second semiconductor layer 15. For example, a portion of light rays emitted by the light-emitting part 11 in the light-emitting unit 10 into the second semiconductor layer 15 may be totally reflected between the first surface A1 and the second surface A2 in the second semiconductor layer 15 repeatedly for a plurality of times, and be transmitted transversely. In view of this, it is highly easy for a light ray emitted by a light-emitting part 11 to be transversely transmitted to a region where an adjacent light-emitting part 11 is disposed, and then be emitted from an optical functional part 22 corresponding to the adjacent light-emitting part 11. In this case, the light-emitting chip 100 displays a color abnormally.

In view of this, in the present disclosure, because the second semiconductor layer 15 in the light-emitting unit 10 may be provided with the first groove U whose opening is on the second surface A2, and the filling part 50 may be disposed in the first groove U, after a portion of light rays emitted by the light-emitting part 11 are transversely transmitted in the second semiconductor layer 15, a light ray transmitted to a region where an adjacent light-emitting part 11 is disposed may be blocked by the filling part 50 in the first groove U. In this case, a probability that the portion of light rays emitted by the light-emitting part 11 are transversely transmitted in the second semiconductor layer 15 to the region where the adjacent light-emitting part 11 is disposed can be reduced effectively. Therefore, it can be ensured that light ray crosstalk is not easy to occur in the light-emitting chip 100, thereby causing a display base plate integrated with the light-emitting chip 100 to have a relatively good display effect.

In summary, the light-emitting chip provided in the embodiments of the present disclosure includes: a light-emitting unit and a color converting unit disposed on a light-emitting side of the light-emitting unit. Because the second semiconductor layer in the light-emitting unit may be provided with the first groove whose opening is on the second surface, and the filling part may be disposed in the first groove, after a portion of light rays emitted by the light-emitting part are transversely transmitted in the second semiconductor layer, a light ray transmitted to a region where an adjacent light-emitting part is disposed may be blocked by the filling part in the first groove. In this case, a probability that the portion of light rays emitted by the light-emitting part that are transversely transmitted in the second semiconductor layer to the region where the adjacent light-emitting part is disposed can be reduced effectively. Therefore, it can be ensured that light ray crosstalk is not easy to occur in the light-emitting chip, thereby causing a display base plate integrated with the light-emitting chip to have a relatively good display effect.

In the present disclosure, the filling part 50 may be a part in the common electrode layer 16. Herein, the common electrode layer 16 is made of a material having reflectivity. Therefore, in the case that the filling part 50 in the first groove U belongs to a part in the common electrode layer 16, the filling part 50 also has reflectivity, such that the filling part 50 can block the portion of light rays emitted by the light-emitting part 11 that are transversely transmitted in the second semiconductor layer 15.

In some embodiments of the present disclosure, as illustrated in FIG. 80, the first groove U may be disposed within the orthographic projection of the common electrode layer 16 on the extension surface of the second semiconductor layer 15. That is, the orthographic projection of the common electrode layer 16 on the extension surface of the second semiconductor layer 15 may cover the orthographic projection of the first groove U on the extension surface of the second semiconductor layer 15. In this case, the filling part 50 in the common electrode layer 16 and filled into the first groove U can completely cover the first groove U.

In some embodiments, the side of the common electrode layer 16 facing away from the color converting unit 20 is a flat surface.

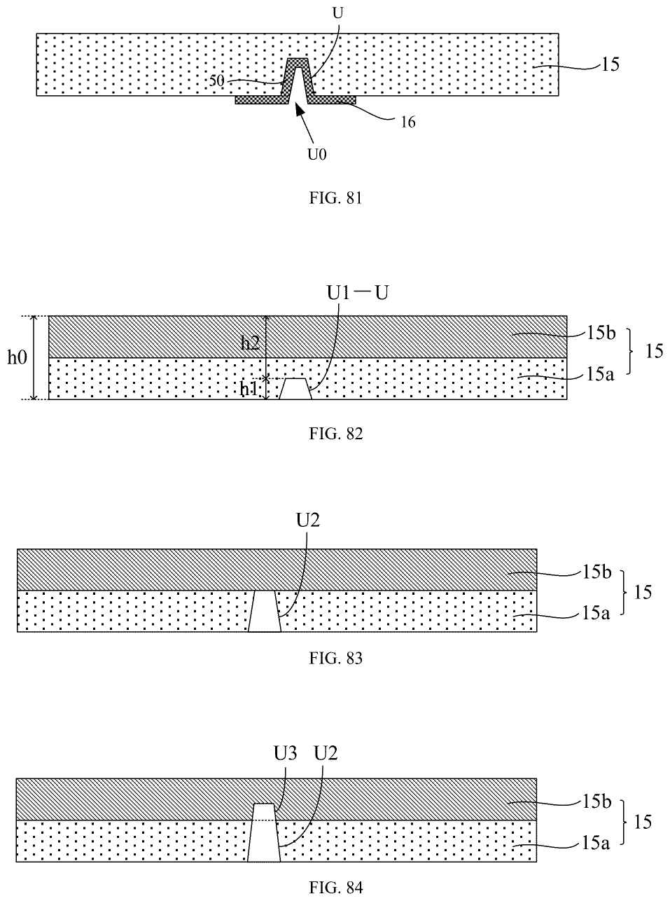

In some embodiments, refer to FIG. 81 which is a partially enlarged view of distribution of a second semiconductor layer and a common electrode layer according to some embodiments of the present disclosure. In some embodiments, the side of the common electrode layer 16 facing away from the color converting unit 20 is provided with a recessed groove U0. An orthographic projection of the recessed groove U0 on the extension surface of the second semiconductor layer 15 overlaps with the first groove U.

For example, the orthographic projection of the recessed groove U0 on the extension surface of the second semiconductor layer 15 is within the first groove U.

For example, the recessed groove U0 is at least partially disposed in the first groove U.

For example, the recessed groove U0 and the first groove U are in an embedded state; and the recessed groove U0 is embedded in the first groove U.

For example, the common electrode layer 16 is formed by a uniform film forming process. In this case, the thicknesses at all positions of the common electrode layer 16 formed on the second semiconductor layer 15 are the same or essentially the same; or the thickness of the portion of the common electrode layer 16 inside the first groove U is larger than the thickness of the portion of the common electrode layer 16 outside the first groove U.

For example, the thicknesses at all the positions of the common electrode layer 16 are larger than 500 nm.

For example, the thickness of the filling part 50 in the common electrode layer 16 and disposed in the first groove U is consistent with the thickness of the portion of the common electrode layer 16 outside the first groove U. The recessed groove U0 may be formed on the side facing away from the color converting unit 20 of the filling part 50 in the common electrode layer 16 and disposed in the first groove U. The recessed groove U0 may be enclosed by the filling part 50 disposed on a slot wall of the first groove U and having a consistent thickness. In view of this, the recessed groove U0 may be distributed in the first groove U.

In the present disclosure, the portion of the common electrode layer 16 inside the first groove U and the portion of the common electrode layer 16 outside the first groove U may be an integral structure that extends continuously. In some embodiments, the common electrode layer 16 is a single conductive layer, wherein materials at all positions of the single conductive layer are the same. In some other embodiments, the common electrode layer 16 is formed by laminating a plurality of conductive sub-layers, wherein each of the plurality of conductive sub-layers extends from the interior of the first groove U to the outside continuously.

In some embodiments, a depth of the first groove U in the second semiconductor layer 15 is less than or equal to the thickness of the second semiconductor layer 15.

In some embodiments, as illustrated in FIG. 82 which is a schematic diagram of a structure of a second semiconductor layer according to some embodiments of the present disclosure, a ratio of the depth h1 of the first groove U in the second semiconductor layer 15 to the thickness h0 of the second semiconductor layer is within a range of 10% to 65%. It should be noted that a larger depth of the first groove U in the second semiconductor layer 15 can ensure that the filling part 50 filled into the first groove U has a better effect of blocking the portion of light rays emitted by the light-emitting part 11 that are transversely transmitted in the second semiconductor layer 15.

Accordingly, a ratio of a distance h2 between the bottom of the first groove U and the first surface A1 in the second semiconductor layer 15 to the thickness h0 of the second semiconductor layer 15 in the first direction X may be within a range of 35% to 90%. In this case, it is also ensured that the entire strength of the second semiconductor layer 15 is relatively high even when the second semiconductor layer 15 is provided with the first groove U therein, thereby ensuring that the first groove U does not affect the entire strength of the light-emitting chip 100, and causing the light-emitting chip 100 to have a low possibility of breaking. Therefore, it is ensured that the stability of the light-emitting chip 100 is relatively high.

For example, the ratio of the depth h1 of the first groove U in the second semiconductor layer 15 to the thickness h0 of the second semiconductor layer is within a range of 12% to 60%. Accordingly, the ratio of the distance h2 between the bottom of the first groove U and the first surface A1 in the second semiconductor layer 15 to the thickness h0 of the second semiconductor layer 15 in the first direction X may be within a range of 40% to 88%.

For example, the ratio of the depth h1 of the first groove U in the second semiconductor layer 15 to the thickness h0 of the second semiconductor layer is within the range of 15% to 55%. Accordingly, the ratio of the distance h2 between the bottom of the first groove U and the first surface

A1 in the second semiconductor layer 15 to the thickness h0 of the second semiconductor layer 15 in the first direction X may be within a range of 45% to 85%.

For example, the ratio of the depth h1 of the first groove U in the second semiconductor layer 15 to the thickness h0 of the second semiconductor layer is within a range of 20% to 50%. Accordingly, the ratio of the distance h2 between the bottom of the first groove U and the first surface A1 in the second semiconductor layer 15 to the thickness h0 of the second semiconductor layer 15 in the first direction X may be within a range of 50% to 80%. In this case, it is ensured that the entire strength of the second semiconductor layer 15 is relatively high; and it is also ensured that the filling part 50 filled into the first groove has a better effect of blocking the portion of light rays emitted by the light-emitting part 11 that are transversely transmitted in the second semiconductor layer 15.

In some embodiments, the depth h1 of the first groove U in the second semiconductor layer 15 is within a range of 0.1 μm to 3 μm. For example, the depth h1 of the first groove U in the second semiconductor layer 15 is within a range of 0.5 μm to 1.5 μm. In this case, the thickness h0 of the second semiconductor layer is 4.6(±0.5) μm. Accordingly, the distance h2 between the bottom of the first groove U and the first surface A1 in the second semiconductor layer 15 in the first direction X is within a range of 1.1 μm to 5 μm. For example, the distance h2 between the bottom of the first groove U and the first surface A1 in the second semiconductor layer 15 in the first direction X is within a range of 2.6 μm to 4.6 μm.

In some embodiments of the present disclosure, as illustrated in FIG. 82, the second semiconductor layer 15 includes a first sub-layer 15a and a second sub-layer 15b that are laminated. Relative to the second sub-layer 15b, the first sub-layer 15a is more proximal to the light-emitting part 11. The first sub-layer 15a is the N-type gallium nitride layer 156 in the foregoing embodiments. The second sub-layer is the gallium nitride buffer layer 155 in the foregoing embodiments.

Herein, because the second semiconductor layer 15 may include the first sub-layer 15a and the second sub-layer 15b that are laminated, the first groove U in the second semiconductor layer 15 is distributed in a different mode. In view of this, embodiments of the present disclosure are illustratively described by using the following four embodiments as examples.

In the first embodiment, as illustrated in FIG. 82, the first groove U includes: a first blind groove U1 formed on the side of the first sub-layer 15a facing away from the second sub-layer 15b. The filling part 50 may be filled into the first blind groove U1.

In the second embodiment, with reference to FIG. 83 which is a schematic diagram of a structure of another second semiconductor layer according to some embodiments of the present disclosure, the first groove U includes a first penetrating groove U2 penetrating the first sub-layer 15a The filling part 50 may be filled into the first penetrating groove U2.

In the third embodiment, with reference to FIG. 84 which is a schematic diagram of a structure of still another second semiconductor layer according to some embodiments of the present disclosure, the first groove U includes a first penetrating groove U2 penetrating the first sub-layer 15a, and a second blind groove U3 formed on the side of the second sub-layer 15b facing the first sub-layer. The first penetrating groove U2 may be connected with the second blind groove U3. A part of the filling part 50 may be filled into the first penetrating groove U2; and the other part of the filling part 50 may be filled into the second blind groove U3.

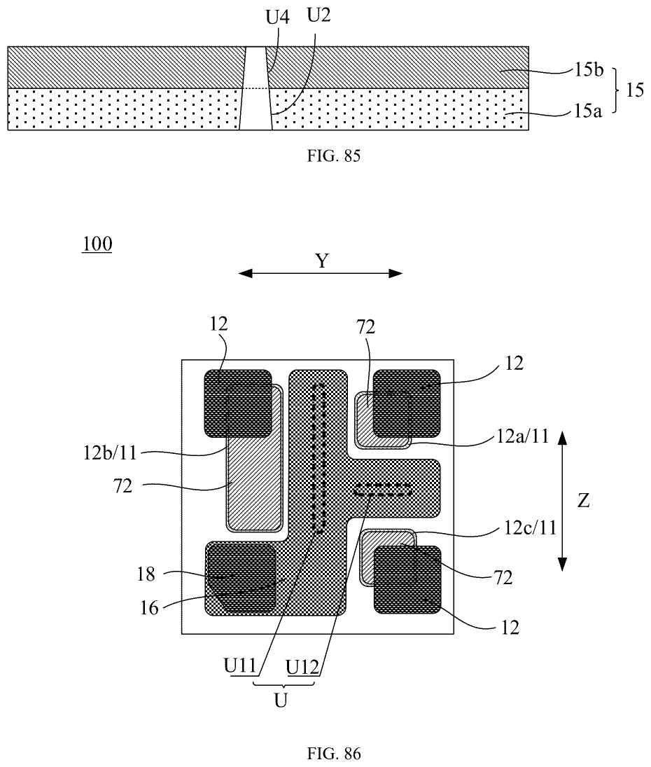

In the fourth embodiment, with reference to FIG. 85 which is a schematic diagram of a structure of yet another second semiconductor layer according to some embodiments of the present disclosure, the first groove U includes a first penetrating groove U2 penetrating the first sub-layer 15a, and a second penetrating groove U4 penetrating the second sub-layer 15b. The first penetrating groove U2 may be connected with the second penetrating groove U4. A part of the filling part 50 may be filled into the first penetrating groove U2; and the other part of the filling part 50 may be filled into the second penetrating groove U4.

It should be noted that in the first embodiment, the second embodiment, and the third embodiment that are described above, the first groove U is a blind groove that does not penetrate the entire second semiconductor layer 15 completely; but in the fourth embodiment described above, the first groove U is a penetrating groove that penetrates the entire second semiconductor layer 15 completely.

In some embodiments of the present disclosure, with reference to FIG. 78, the first groove U in the second semiconductor layer 15 includes: a first groove portion U11 and a second groove portion U12. The first groove portion U11 of the first groove U may be disposed between the orthographic projections of the first light-emitting part 12a and the second light-emitting part 12b on the extension surface of the second semiconductor layer 15; and the second groove portion U12 of the first groove U may be disposed between the orthographic projections of the first light-emitting part 12a and the third light-emitting part 12c on the second semiconductor layer 15.

In this case, the filling part 50 in the first groove portion U11 may block the portion of light rays emitted by the first light-emitting part 12a and the second light-emitting part 12b that are transversely transmitted in the second semiconductor layer 15 in the second direction Y. In this case, light ray crosstalk between the first light-emitting part 12a and the second light-emitting part 12b can be reduced or avoided, thereby reducing a risk that the light-emitting chip 100 generates color cast. Similarly, the filling part 50 in the second groove portion U12 may block the portion of light rays emitted by the first light-emitting part 12a and the third light-emitting part 12c that are transversely transmitted in the second semiconductor layer 15 in the third direction Z. In this case, light ray crosstalk between the first light-emitting part 12a and the third light-emitting part 12c can be reduced or avoided, thereby reducing a risk that the light-emitting chip 100 generates color cast.

In some embodiments of the present disclosure, as illustrated in FIG. 79, the first groove portion U11 and the second groove portion U12 of the first groove U may both be strip-shaped; the first groove portion U11 may extend in the third direction Z; and the second groove portion U12 may extend in the second direction Y.

In the present disclosure, the length of the first groove portion U11 of the first groove U in the third direction Z is larger than or equal to the width of the first light-emitting part 12a in the third direction Z, and is larger than or equal to the width of the second light-emitting part 12b in the third direction Z; and/or the length of the second groove portion U12 of the first groove U in the second direction Y is larger than or equal to the width of the first light-emitting part 12a in the second direction

Y, and is larger than or equal to the width of the third light-emitting part 12c in the second direction Y.

Herein, in the case that the length of the first groove portion U11 of the first groove U in the third direction Z is larger than or equal to the width of the first light-emitting part 12a in the third direction Z, and is larger than or equal to the width of the second light-emitting part 12b in the third direction Z, it can be ensured that the length of the filling part 50 in the first groove portion U11 is relatively long. In this case, it can be ensured that the filling part 50 in the first groove portion U11 blocks as far as possible the portion of light rays emitted by the first light-emitting part 12a and the second light-emitting part 12b that are transversely transmitted in the second semiconductor layer 15 in the second direction Y. In this case, the risk that the light-emitting chip 100 generates color cast can be further reduced.

In the case that the length of the second groove portion U12 of the first groove U in the second direction Y is larger than or equal to the width of the first light-emitting part 12a in the second direction Y, and is larger than or equal to the width of the third light-emitting part 12c in the second direction Y, it can be ensured that the length of the filling part 50 in the second groove portion U12 is relatively long. In this case, it can be ensured that the filling part 50 in the second groove portion U12 blocks as far as possible the portion of light rays emitted by the first light-emitting part 12a and the third light-emitting part 12c that are transversely transmitted in the second semiconductor layer 15 in the third direction Z. In this case, a risk of light ray crosstalk between the first light-emitting part 12a and the third light-emitting part 12c can be further reduced, such that the risk that the light-emitting chip 100 generates color cast can be further reduced.

In some embodiments of the present disclosure, the width of the first groove portion U11 of the first groove U in the second direction Y and the width of the second groove portion U12 in the third direction Z are both within a range of 2 μm to 10 μm. In this case, it can be ensured that the width of the filling part 50 distributed in the first groove portion U11 is relatively wide, such that it can be ensured that the filling part 50 in the first groove portion U11 has a relatively good effect of blocking the portion of light rays emitted by the first light-emitting part 12a and the second light-emitting part 12b that are transversely transmitted in the second semiconductor layer 15 in the second direction Y. Similarly, it can be ensured that the width of the filling part 50 distributed in the second groove portion U12 is relatively wide, such that it can be ensured that the effect of blocking the portion of light rays emitted by the first light-emitting part 12a and the third light-emitting part 12c that are transversely transmitted in the second semiconductor layer 15 in the third direction Z is relatively good.

In some embodiments, the minimum distance between the outer boundary of the first groove U disposed in the second semiconductor layer 15 and the outer boundary of the orthographic projection of a light-emitting layer 14 in an adjacent light-emitting part 11 on the extension surface of the second semiconductor layer 15 is larger than or equal to 5 μm

In some embodiments, with reference to FIG. 78, in the second direction Y, the minimum distance d01 between the first groove portion U11 of the first groove U and a light-emitting layer in an adjacent light-emitting part 11 (that is, the first light-emitting part 12a or the second light-emitting part 12b) needs to be larger than or equal to 5 μm. In this way, it can be ensured that the distance between the first groove portion U11 and a light-emitting layer in an adjacent first light-emitting part 12a or a light-emitting layer in an adjacent second light-emitting part 12b is relatively large, such that the first groove portion U11 does not interfere with light generation of an adjacent first light-emitting part 12a or second light-emitting part 12b. Similarly, in the third direction Z, the minimum distance d02 between the second groove portion U12 of the first groove U and a light-emitting layer in an adjacent light-emitting part 11 (that is, the first light-emitting part 12a or the third light-emitting part 12c) needs to be larger than or equal to 5 μm. In this way, it can be ensured that the distance between the second groove portion U12 and a light-emitting layer in an adjacent first light-emitting part 12a or a light-emitting layer in an adjacent third light-emitting part 12c is relatively large, such that the second groove portion U12 does not interfere with light generation of an adjacent first light-emitting part 12a or third light-emitting part 12c.

In the present disclosure, as illustrated in FIG. 78, the first groove portion U11 and the second groove portion U12 of the first groove U may be connected with each other.

It should be noted that the foregoing embodiments are illustrated by using an example in which the first groove portion U11 and the second groove portion U12 are connected with each other. In some other embodiments, as illustrated in FIG. 86 which is a bottom view of another light-emitting chip according to some other embodiments of the present disclosure, the first groove portion U11 and the second groove portion U12 disposed on the second semiconductor layer 15 are not connected with each other. In this case, for the lengths of and a distribution positional relationship between the first groove portion U11 and the second groove portion U12, reference may be made to the foregoing related content. Details are not described herein any further.

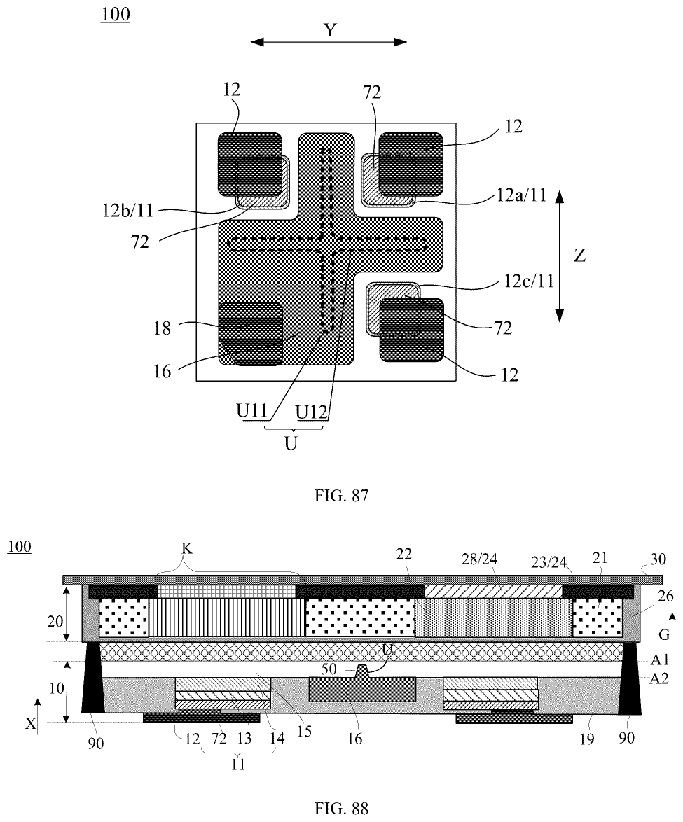

In the case that the first groove portion U11 and the second groove portion U12 of the first groove U are connected with each other, the shapes of the orthographic projections of the connected first groove portion U11 and second groove portion U12 on the extension surface of the second semiconductor layer 15 may include a T shape. In this case, the first groove U prevents light ray crosstalk among the first light-emitting part 12a, the second light-emitting part 12b, and the third light-emitting part 12c, such that color cast can be reduced or avoided effectively. In some other embodiments, as illustrated in FIG. 87 which is a bottom view of still another light-emitting chip according to some other embodiments of the present disclosure, the shapes of the orthographic projections of the connected first groove portion U11 and second groove portion U12 on the extension surface of the second semiconductor layer 15 may include a cross shape. It should be noted that the T shape in the foregoing embodiment may be understood as a portion of the cross shape.

In some embodiments, after the filling part 50 is disposed in the first groove U, the filling part 50 can not only block a light ray that causes crosstalk between the first light-emitting part 12a and the second light-emitting part 12b distributed in the second direction Y, but also block a light ray that causes crosstalk between the first light-emitting part 12a and the third light-emitting part 12c distributed in the third direction Z, and can also block a light ray that causes crosstalk between the second light-emitting part 12b and the third light-emitting part 12c in a diagonal direction.

It should also be noted that FIG. 87 is illustrated by using an example in which all light-emitting areas of the first light-emitting part 12a, the second light-emitting part 12b, and the third light-emitting part 12c are the same. In this case, the second groove portion U12 extending in the second direction Y may extend to the side of the second light-emitting part 12b facing away from the first light-emitting part 12a, such that a risk of light ray crosstalk between light-emitting parts can be further reduced.

In some embodiments of the present disclosure, as illustrated in FIG. 78 and FIG. 86, the light-emitting unit 10 further includes a second electrode 18. Herein, the second electrode 18 may be disposed on the side of the common electrode layer 16 distal from the color converting unit 20, and be electrically connected to the common electrode layer 16.

As illustrated in FIG. 78 and FIG. 86, the second electrode 18 and the first electrode 12 in the third light-emitting part 12c may be disposed in a row in the second direction Y; and the second electrode 18 and the first electrode 12 in the second light-emitting part 12b are disposed in a row in the third direction Z

In some embodiments of the present disclosure, with reference to FIG. 88 which is a sectional view of a light-emitting chip according to some embodiments of the present disclosure, the light-emitting chip 100 further includes an encircling dam 90. The encircling dam 90 may be disposed on the side of the color converting unit 20 facing the light-emitting unit 10, and be distributed surrounding the periphery of the light-emitting unit 10. Specifically, the encircling dam 90 has at least a function of absorbing and/or reflecting blue light. For example, the encircling dam 90 has a function of absorbing and/or reflecting visible light.

For example, the encircling dam 90 is of an integrated structure. The encircling dam 90 may be a continuous structure that is distributed at the periphery of the light-emitting unit 10 in an end-to-end manner. In this case, the encircling dam 90 can shield a side-surface light leak from any direction of the light-emitting chip 100.

For example, the encircling dam 90 in the light-emitting chip 100 is configured to absorb the portion of light rays emitted by the light-emitting part 11 that are transversely transmitted in the second semiconductor layer 15 and emitted to an edge. That is, after the light rays emitted by the light-emitting part 11 enter the second semiconductor layer 15, and an optical waveguide is generated in the second semiconductor layer 15, the light rays transversely transmitted in the second semiconductor layer 15 and emitted to the edge can be absorbed by the encircling dam 90.

The encircling dam 90 may be made of an opaque material. In some embodiments, a material of the encircling dam 90 in the light-emitting chip 100 includes: at least one of an organic material having reflectivity or an organic material having light absorptivity. Herein, in the case that the material of the encircling dam 90 includes the organic material having light absorptivity, the material of the encircling dam 90 is a black organic material that can absorb a light ray transversely transmitted in the second semiconductor layer 15 of the light-emitting unit 10.

For example, the encircling dam 90 is made of a high-molecular polymer in which a light-absorbing material is mixed. The high-molecular polymer may be used as a base material; and the light-absorbing material is mixed in the high-molecular polymer.

For example, the encircling dam 90 is made of a high-molecular polymer in which a light-absorbing material and scattering particles are mixed.

For example, the light-absorbing material is carbon black; and the scattering particles is silicon dioxide particles, titanium dioxide particles, a high-molecular polymer whose refractive index is different from the base material of the encircling dam 90, or any combination thereof.

In some embodiments of the present disclosure, as illustrated in FIG. 78 or FIG. 86, the light-emitting area of the second light-emitting part 12b is larger than the light-emitting area of the first light-emitting part 12a, and is larger than the light-emitting area of the third light-emitting part 12c. That is, the light-emitting area of the second light-emitting part 12b is relatively large; and both the light-emitting areas of the first light-emitting part 12a and the third light-emitting part 12c are relatively small. In this way, it can be ensured that the second light-emitting part 12b can emit more light rays.

In the present disclosure, as illustrated in FIG. 79, the projection area of the optical functional part 22 corresponding to the second light-emitting part 12b (that is, the second optical functional part 22b in the foregoing embodiment) on the extension surface of the second semiconductor layer 15 is larger than the projection area of the optical functional part 22 corresponding to the first light-emitting part 12a (that is, the first optical functional part 22a in the foregoing embodiment) on the extension surface of the second semiconductor layer 15, and is larger than the projection area of the optical functional part 22 corresponding to the third light-emitting part 12c (that is, the third optical functional part 22c in the foregoing embodiment) on the extension surface of the second semiconductor layer 15

In the present disclosure, the first light ray is blue light; and the optical functional part 22 corresponding to the second light-emitting part 12b (that is, the second optical functional part 22b in the foregoing embodiment) may be configured to convert the blue light into green light. The optical functional part 22 corresponding to one of the first light-emitting part 12a or the second light-emitting part 12b may be configured to convert the blue light into red light; and the optical functional part 22 corresponding to the other one of the first light-emitting part 12a or the second light-emitting part 12b may be configured to transmit the first light ray. In some embodiments, the optical functional part 22 corresponding to the first light-emitting part 12a (that is, the first optical functional part 22a in the foregoing embodiment) is configured to convert the blue light into red light, and the optical functional part 22 corresponding to the third light-emitting part 12c (that is, the third optical functional part 22c in the foregoing embodiment) is configured to transmit the first light ray.

In this case, it can be ensured that the projection area of the second optical functional part 22b on the extension surface of the second semiconductor layer 15 is relatively large; both the projection areas of the first optical functional part 22a and the third optical functional part 22c on the extension surface of the second semiconductor layer 15 are relatively small. In this case, it can be ensured that the second optical functional part 22b can convert more light rays emitted by the second light-emitting part 12b into green light.

It should be noted that under the action of a red sub-pixel R, a blue sub-pixel B, and a green sub-pixel G, the light-emitting chip 100 may be configured to emit white light rays. The proportion of light rays emitted by the green sub-pixel G to the white light rays is the highest. Therefore, the light-emitting efficiency of the light-emitting chip 100 can be improved by enlarging the area of the green sub-pixel G, such that it can be ensured that the light-emitting efficiency of the light-emitting chip 100 is relatively high

In some embodiments of the present disclosure, as illustrated in FIG. 78 or FIG. 86, the length of the light-emitting layer 14 of the second light-emitting part 12b in the third direction Z is larger than the length of the light-emitting layer 14 of the first light-emitting part 12a in the third direction Z. In this case, it can be ensured that the light-emitting area of the second light-emitting part 12b is relatively large.

The length of the optical functional part 22 corresponding to the second light-emitting part 12b (that is, the second optical functional part 22b in the foregoing embodiment) in the third direction may be larger than the length of the optical functional part 22 corresponding to the third light-emitting part (that is, the third optical functional part 22c in the foregoing embodiment) in the third direction Z. In this case, it can be ensured that all light rays emitted by the second light-emitting part 12b having a relatively large light-emitting area can be converted by the second optical functional part 22b.

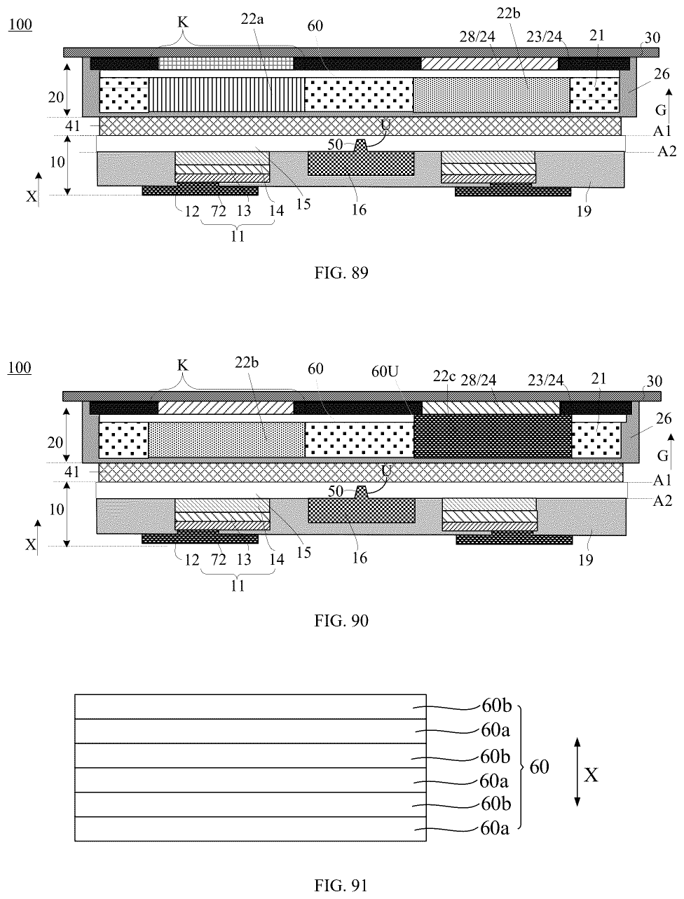

In some embodiments of the present disclosure, with reference to FIG. 89 which is a sectional view of another light-emitting chip according to some embodiments of the present disclosure, the color converting unit 20 further includes a first light selective transmission layer 60. Herein, the first light selective transmission layer 60 may be distributed on the side of the color converting unit 20 facing away from the light-emitting unit 10, and be configured to reflect the first light ray and transmit a light ray different from the first light ray in color. For example, the first light selective transmission layer 60 is configured to reflect blue light rays, and transmit red light rays and green light rays.

After passing through the optical functional part 22, the first light ray emitted by the light-emitting part 11 in the light-emitting unit 10 may be converted by the optical functional part 22 into a light ray different from the first light ray in color. In this case, the light ray different from the first light ray in color may be transmitted out through the first light selective transmission layer 60, and then emitted out through the first substrate 30. However, the first light ray emitted by the light-emitting part 11 may be reflected by the first light selective transmission layer 60 back into the optical functional part 22, such that the optical functional part 22 can continue converting the first light ray that has not been converted. In this case, the converting efficiency of the optical functional part 22 for the first light ray can be improved effectively, such that the light-emitting efficiency of the light-emitting chip 100 can be improved effectively.

The plurality of optical functional parts 22 may include: at least one first target optical functional part configured to convert the color of the first light ray into another color. In some embodiments, the first light ray is blue light; and the first target optical functional part includes at least one of the first optical functional part 22a or the second optical functional part 22b in the foregoing embodiments. In some other embodiments, the first light ray is ultraviolet light; and the first target optical functional part includes at least one of the first optical functional part 22a, the second optical functional part 22b, or the third optical functional part 22c in the foregoing embodiments.

For example, in the case that the first light ray is blue light, and the first target optical functional part includes the first optical functional part 22a and the second optical functional part 22b in the foregoing embodiments, it can be ensured that a blue light ray having not been converted by the first optical functional part 22a and the second optical part 22b is reflected back to the first optical part 22a and the second optical part 22b by setting the first light selective transmission layer 60, such that the first optical part 22a and the second optical part 22b can continue converting the first light ray that has not been converted, thereby effectively improving the converting efficiency of the first optical part 22a and the second optical part 22b for the first light ray. Therefore, the light-emitting efficiency of the light-emitting chip 100 can be improved effectively.

In the present disclosure, the orthogonal projection of the first light selective transmission layer 60 on the extension surface of the second semiconductor layer 15 may overlap with the orthogonal projection of the first target optical functional part on the extension surface of the second semiconductor layer 15. For example, the orthographic projection of the first light selective transmission layer 60 on the extension surface of the second semiconductor layer 15 covers the orthographic projection of the first target optical functional part on the extension surface of the second semiconductor layer 15. In this case, it can be ensured that first light rays having not been converted by the first target optical functional part can be reflected back to the first target optical functional part as more as possible, thereby ensuring that the first target optical functional part has relatively high efficiency of converting the first light ray into a light ray of another color. In addition, it can be ensured that the light ray of the another color acquired by conversion of the first target optical functional part can be transmitted out normally through the first light selective transmission layer 60 and the first substrate 30.

In some embodiments of the present disclosure, with reference to FIG. 90 which is a sectional view of still another light-emitting chip according to some embodiments of the present disclosure, the first light selective transmission layer 60 is a continuously distributed film layer. The plurality of optical functional parts 22 may include at least one second target optical functional part configured to transmit the first light ray. For example, in the case that the first light ray is a blue light ray, the at least one second target optical functional part includes a third optical functional part 22c configured to transmit the first light ray.

The first light selective transmission layer 60 may include a hollowed-out region 60U. An orthogonal projection of the hollowed-out region 60U on the extension surface of the second semiconductor layer 15 may overlap with the orthogonal projection of the second target optical functional part on the extension surface of the second semiconductor layer 15.

In some embodiments, the orthographic projection of the hollowed-out region 60U of the first light selective transmission layer 60 on the extension surface of the second semiconductor layer 15 covers the orthographic projection of the second target optical functional part on the extension surface of the second semiconductor layer 15. That is, the orthogonal projection of the first light selective transmission layer 60 on the extension surface of the second semiconductor layer 15 does not overlap with the orthogonal projection of the second target optical functional part on the extension surface of the second semiconductor layer 15.

In this case, due to the hollowed-out region 60U provided in the first light selective transmission layer 60, it can be ensured that blue light emitted from the second target optical functional part can be emitted out after passing through the hollowed-out region 60U, such that the first light selective transmission layer 60 does not block the blue light emitted from the second target optical functional part.

In some embodiments of the present disclosure, with reference to FIG. 91 which is a schematic diagram of a structure of a first light selective transmission layer according to some embodiments of the present disclosure, the first light selective transmission layer 60 includes a plurality of first dielectric layers 60a and a plurality of second dielectric layers 60b which are sequentially laminated in the first direction X, wherein refractive indexes of the first dielectric layer 60a and the second dielectric layer 60b may be different. That is, in each film layer of the first light selective transmission layer 60, the refractive indexes in different regions may be different. In view of this, the thicknesses and the refractive indexes of the plurality of first dielectric layers 60a and the plurality of second dielectric layers 60b may be different.

In some embodiments, a material of the first dielectric layer 60a includes an oxide of silicon; and a material of the second dielectric layer 60b includes an oxide of niobium. Both each first dielectric layer 60a and each second dielectric layer 60b are made of inorganic materials That is, the first light selective transmission layer 60 is a film layer structure made of an inorganic material. In this case, the first light selective transmission layer 60 is a distributed Bragg reflection (DBR) layer.

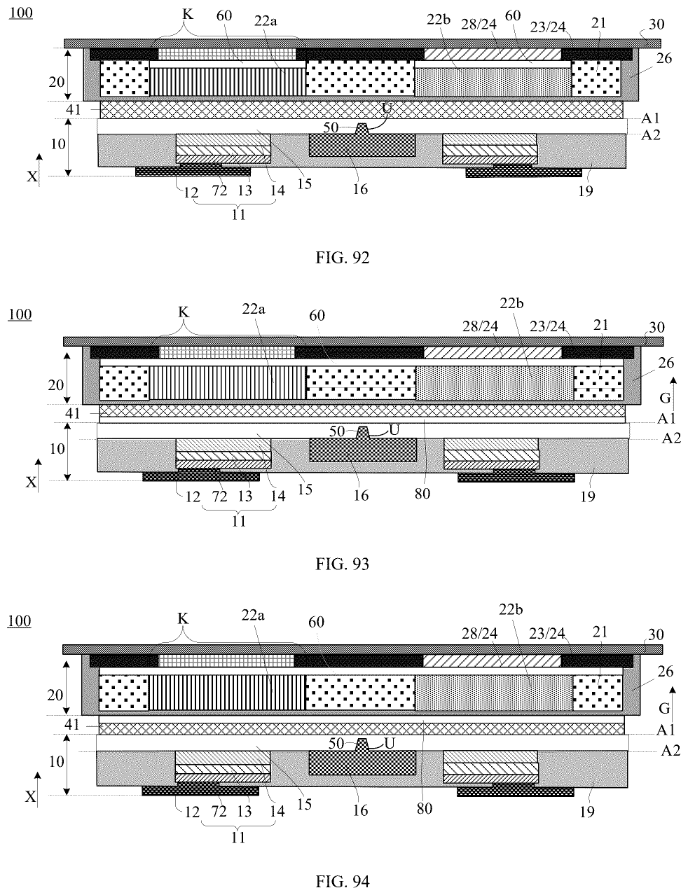

In some other embodiments, as illustrated in FIG. 92 which is a sectional view of yet another light-emitting chip according to some embodiments of the present disclosure, a material of the first light selective transmission layer 60 is cholesteric liquid crystal. In this case, because both the cholesteric liquid crystal and the optical functional part 22 can be formed by an ink-jet printing process, the first light selective transmission layer 60 can be disposed in the opening region K for defining the first target optical functional part. The cholesteric liquid crystal may be configured to enable the first light selective transmission layer 60 to reflect the first light ray and transmit a light ray different from the first light ray in color. In some embodiments, the cholesteric liquid crystal includes left-handed liquid crystal molecules and right-handed liquid crystal molecules. By controlling refractive indexes of the left-handed liquid crystal molecules and refractive indexes of the right-handed liquid crystal molecules in the cholesteric liquid crystal, and controlling thread pitches of adjacent left-handed liquid crystal molecules and adjacent right-handed liquid crystal molecules in the cholesteric liquid crystal, the first light selective transmission layer 60 is enabled to reflect the first light ray and transmit a light ray different from the first light ray in color.

In some embodiments of the present disclosure, with reference to FIG. 93 which is a sectional view of a light-emitting chip according to some other embodiments of the present disclosure, the light-emitting chip 100 further includes a second light selective transmission layer 80 distributed in the color converting unit 20 or the light-emitting unit 10. The second light selective transmission layer 80 may be configured to transmit the first light ray and reflect a light ray different from the first light ray in color. For example, the second light selective transmission layer 80 is configured to reflect red light rays and green light rays, and transmit blue light rays.

Herein, the first light ray emitted by the light-emitting part 11 of the light-emitting unit 10 may be transmitted out through the second light selective transmission layer 80. After the first light ray is converted by the optical functional part 22 into the light ray different from the first light ray in color, the acquired light ray may be emitted out from the optical functional part 22. However, if the light ray different from the first light ray in color is not emitted out from the optical functional part 22, it can be reflected back by the second light selective transmission layer 80 to the optical functional part 22, and then emitted out through the first substrate 30. In this way, the light-emitting efficiency of the light-emitting chip 100 can be improved effectively.

For example, the first light ray is blue light; and blue light rays emitted by the first light-emitting part 12a and the second light-emitting part 12b are transmitted out through the second light selective transmission layer 80. After the blue light ray is converted by the first optical functional part 22a into a red light ray, the red light ray may be emitted out from the first optical functional part 22a. If the red light ray is not emitted out from the first optical functional part 22a, the red light ray can be reflected back by the second light selective transmission layer 80 to the optical functional part 22, and then emitted out through the first substrate 30. In this way, the light-emitting efficiency of the light-emitting chip 100 can be improved effectively.

It should be noted that the light-emitting chip 100 in embodiments of the present disclosure may include at least one of the first light selective transmission layer 60 or the second light selective transmission layer 80. Herein, in the case that the light-emitting chip 100 includes both the first light selective transmission layer 60 and the second light selective transmission layer 80, the second light selective transmission layer 80 allows an unconverted first light ray to be emitted to the optical functional part 22, and reflects a light ray converted by the optical functional part 22 In addition, the first light selective transmission layer 60 allows a light ray converted by the optical functional part 22 to be transmitted out, and reflects a first light ray not converted by the optical functional part 22 In this way, the light-emitting efficiency of the light-emitting chip 100 can be further improved.

It should also be noted that the second light selective transmission layer 80 may be a DBR layer. In the case that both the first light selective transmission layer 60 and the second light selective transmission layer 80 are DBR layers, distribution of the plurality of first dielectric layers 60a and the plurality of second dielectric layers 60b in the first light selective transmission layer 60 may be different, and the refractive indexes thereof may be different from one another; and the distribution and the refractive indexes of the plurality of first dielectric layers 60a and the plurality of second dielectric layers 60b in the first light selective transmission layer 60 may be different from those of the plurality of first dielectric layers 60a and the plurality of second dielectric layers 60b in the second light selective transmission layer 80. Therefore, it can be ensured that the wavelength of a light ray reflected by the first light selective transmission layer 60 is different from the wavelength of a light ray reflected by the second light selective transmission layer 80; and it can be ensured that the wavelength of a light ray transmitted by the first light selective transmission layer 60 is different from the wavelength of a light ray transmitted by the second light selective transmission layer 80.

In the present disclosure, the second light selective transmission layer 80 may be distributed in the color converting unit 20; or the second light selective transmission layer 80 may be distributed in the light-emitting unit 10. In view of this, embodiments of the present disclosure are illustratively described by using the following two embodiments as examples.

In the first embodiment, as illustrated in FIG. 93, in the case that the second light selective transmission layer 80 is distributed in the light-emitting unit 10, the second light selective transmission layer 80 may be disposed on the side of the second semiconductor layer 15 facing the color converting unit 20 In this case, the second light selective transmission layer 80 may be formed in a preparation process of the light-emitting unit 10. For example, the second light selective transmission layer 80 is adhered with the second semiconductor layer 15. For example, in the preparation process of the light-emitting unit 10, the second light selective transmission layer 80 is prepared in advance; and then each film layer of the light-emitting unit 10 is prepared on the second light selective transmission layer 80.

In the second embodiment, with reference to FIG. 94 which is a sectional view of a light-emitting chip according to some other embodiments of the present disclosure, in the case that the second light selective transmission layer 80 is distributed in the color converting unit 20, the second light selective transmission layer 80 may be disposed on the side, facing the light-emitting unit 10, of the defining dam layer 21 and the plurality of optical functional parts 22. In this case, the second light selective transmission layer 80 is formed in a preparation process of the color converting unit 20. For example, in the preparation process of the color converting unit 10, each film layer of the color converting unit 20 is prepared in advance; and then the second light selective transmission layer 80 is formed on the outermost film layer. For example, the second light selective transmission layer 80 is disposed between the color converting unit 20 and the encapsulating layer 26; and in the preparation process of the color converting unit 20, the second light selective transmission layer 80 is prepared before the encapsulating layer 26.

It should be noted that in the case that the second light selective transmission layer 80 is the DBR layer, the interior of the second light selective transmission layer 80 is composed of a plurality of first dielectric layers and second dielectric layers that are laminated; and because both the first dielectric layer and the second dielectric layer are inorganic layers, the second light selective transmission layer has a relatively high water and oxygen isolation capability. Therefore, in the case that the second light selective transmission layer 80 is disposed on the side, facing the light-emitting unit 10, of the defining dam layer 21 and the plurality of optical functional parts 22, the second light selective transmission layer 80 can encapsulate the defining dam layer 21 and the plurality of optical functional parts 22. That is, the second light selective transmission layer 80 can further have the function of the encapsulating layer 26. In this case, the second light selective transmission layer 80 and the encapsulating layer 26 may be integrated into one film layer.

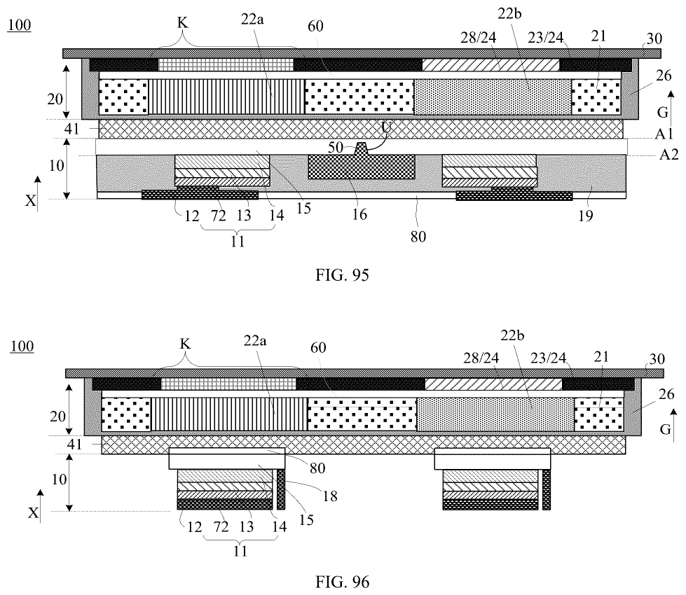

In some other embodiments, with reference to FIG. 95 which is a sectional view of another light-emitting chip according to some other embodiments of the present disclosure, in the case that the second light selective transmission layer 80 is distributed in the light-emitting unit 10, the second light selective transmission layer 80 is disposed on the side facing away from the second semiconductor layer 15 of the plurality of light-emitting parts 11. For example, the second light selective transmission layer 80 is configured to coat the plurality of light-emitting parts 11 of the light-emitting unit 10.

It should be noted that the sectional views provided by the embodiments of the present disclosure may be accompanying drawings acquired by cutting a top view using a section line as a datum. For example, at least one of FIG. 47 or FIG. 48 in the foregoing embodiments is a sectional view acquired based on FIG. 45 along a section line HH; at least one of FIG. 50, FIG. 51, FIG. 52, FIG. 53, FIG. 59, FIG. 61, FIG. 62, FIG. 63, FIG. 64, FIG. 65, FIG. 66, FIG. 67, FIG. 69, FIG. 70, FIG. 72, FIG. 73, FIG. 75, FIG. 76, or FIG. 77 in the foregoing embodiments is a sectional view acquired based on FIG. 49 along a section line VV; FIG. 88 is a sectional view acquired based on FIG. 78 along a section line LL or QQ; and at least one of FIG. 89, FIG. 90, FIG. 92, FIG. 93, FIG. 94, or FIG. 95 is a sectional view acquired based on FIG. 78 along the section line QQ.

It should also be noted that all light-emitting chips 100 in the foregoing embodiments are three-in-one chips. That is, the light-emitting chip 100 includes three light-emitting parts 11 inside at the same time; and the three light-emitting parts 11 are illustrated by using the same second semiconductor layer 15 as an example. In some other embodiments, the light-emitting chip 100 includes only one light-emitting part 11 inside.

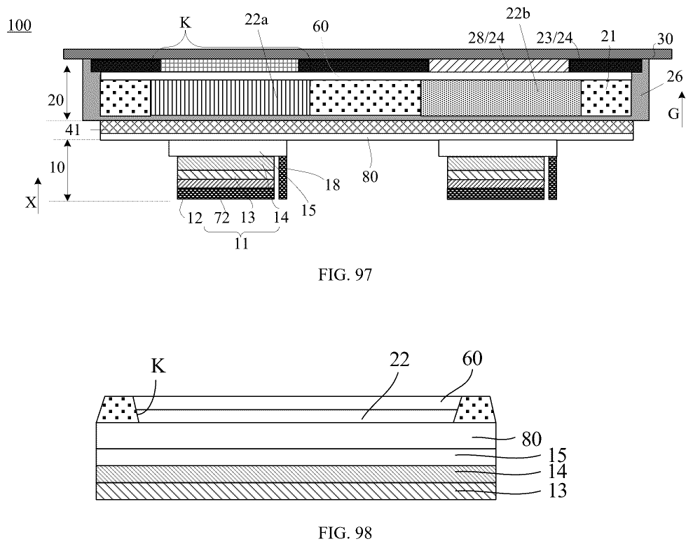

In some embodiments, as illustrated in FIG. 96 which is a sectional view of still yet another light-emitting chip according to some other embodiments of the present disclosure, in the case that the light-emitting chip 100 includes only one light-emitting part 11 inside, the second semiconductor layer 15 in each light-emitting chip 100 is disposed in a separated manner; and the second semiconductor layer 15 of each light-emitting chip 100 may be independently connected to one second electrode 18. In the case that the light-emitting chip 100 includes the second light selective transmission layer 80 inside, and the second light selective transmission layer 80 is disposed on the side of the second semiconductor layer 15 facing the color converting unit 20, the second light selective transmission layers 80 in all the light-emitting chips 100 may be disposed in a separated manner. In some other embodiments, as illustrated in FIG. 97 which is a sectional view of still yet another light-emitting chip according to some other embodiments of the present disclosure, the second light selective transmission layer 80 in each light-emitting chip 100 is connected into a whole.

After a plurality of light-emitting chips 100 are connected to the color converting unit 20 for combination, each optical functional part 22 in the color converting unit 20 may independently correspond to one light-emitting part 11 of one light-emitting chip 100. For example, in FIGS. 96 and 97, the first optical functional part 22a corresponds to one light-emitting part 11 of one light-emitting chip 100; and the second optical functional part 22b corresponds to one light-emitting part 11 of another light-emitting chip 100.

It should be noted that in the case that the light-emitting chip 100 includes only one light-emitting part 11 inside, both the internal structure and principle of the light-emitting chip 100 are consistent with those of the three-in-one light-emitting chip 100 in the foregoing embodiments. In view of this, another structure in the light-emitting chip 100 is not described in detail herein any further.

It should also be noted that all the foregoing embodiments are illustrated by using an example in which the color converting unit 20 and the light-emitting unit 10 are formed separately and then cell aligned. In some other embodiments, the color converting unit 20 is directly formed after formation of the light-emitting unit 10.

As illustrated in FIG. 98, FIG. 98 which is a schematic diagram of a structure of a light-emitting chip according to some other embodiments of the present disclosure. It should be noted that

FIG. 98 merely illustrates the case that only one light-emitting part exists; and actually, in the light-emitting chip 100, there may be a plurality of light-emitting parts, for example, light-emitting parts that respectively emit light rays whose colors are RGB after passing through the optical functional parts. The light-emitting chip 100 includes a first semiconductor layer 13, a light-emitting layer 14, a second semiconductor layer 15, and a defining dam layer 21 disposed on the side of the second semiconductor layer facing away from the light-emitting layer 14 that are laminated sequentially. The defining dam layer includes an opening region K. The optical functional part 22 is formed in the opening region K For example, the light-emitting chip 100 further includes a first light selective transmission layer 60. For example, a material of the first light selective transmission layer 60 being cholesteric liquid crystal may also be another embodiment of the present disclosure. For example, the cholesteric liquid crystal may be disposed in the opening region K. For example, the second light selective transmission layer 80 is disposed between the optical functional part 22 and the second semiconductor layer 15.

The first light selective transmission layer 60 and/or the second light selective transmission layer 80 can modulate a light ray emitted by the light-emitting layer, thereby increasing the light-emitting efficiency of the light-emitting chip 100. Herein, light ray modulation principles of the first light selective transmission layer 60 and the second light selective transmission layer 80 are consistent with those of the first light selective transmission layer 60 and the second light selective transmission layer 80 of the three-in-one light-emitting chip 100 in the foregoing embodiments. The type of a light-emitting part on which the first light selective transmission layer 60 and the second light selective transmission layer 80 are disposed to emit light rays whose colors are RGB is consistent with that of the light-emitting part on which the first light selective transmission layer 60 and the second light selective transmission layer 80 of the three-in-one light-emitting chip 100 in the foregoing embodiments are disposed. Therefore, another structure in the light-emitting chip 100 is not described in detail herein.

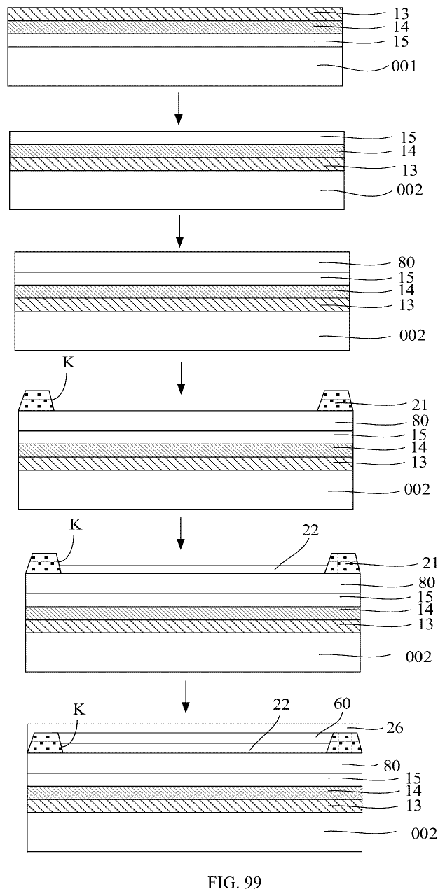

In some embodiments, FIG. 99 is a schematic diagram of a preparation process of the light-emitting chip provided in the embodiment of FIG. 98. First, the second semiconductor layer 15, the light-emitting layer 14, and the first semiconductor layer 13 are sequentially formed on a side of a substrate 001 (for example, a sapphire substrate).

Then, a temporary substrate 002 is formed on the side of the first semiconductor layer 13 facing away from light-emitting layer 14, and the temporary substrate 002 is stripped.

Subsequently, the second light selective transmission layer 80 is formed on the side of the second semiconductor layer 15 facing away from the temporary substrate 002.

Subsequently, the defining dam layer 21 is formed on the side of the second light selective transmission layer 80 facing away from the temporary substrate 002.

Subsequently, the optical functional part 22 is formed in the opening region K of the defining dam layer 21 in an ink-jet printing manner.

Subsequently, the first light selective transmission layer 60 made of the cholesteric liquid crystal is formed in the opening region K of the defining dam layer 21 in an ink-jet printing manner.

Finally, in some embodiments, the encapsulating layer 26 configured to encapsulate the defining dam layer 21, the first light selective transmission layer 60, and the optical functional part 22 is formed.

It should be noted that the preparation process illustrated in FIG. 99 may be used to prepare a light-emitting chip 100 including only one light-emitting part 11, or prepare a three-in-one light-emitting chip 100, which is not limited in embodiments of the present disclosure.

In summary, the light-emitting chip provided in embodiments of the present disclosure includes a light-emitting unit and a color converting unit disposed on a light-emitting side of the light-emitting unit. Because the second semiconductor layer in the light-emitting unit may be provided with the first groove whose opening is on the second surface, and the filling part may be disposed in the first groove, after a portion of light rays emitted by the light-emitting part are transversely transmitted in the second semiconductor layer, a light ray transmitted to a region where an adjacent light-emitting part is disposed may be blocked by the filling part in the first groove. In this case, a probability that the portion of light rays emitted by the light-emitting part that are transversely transmitted in the second semiconductor layer to the region where the adjacent light-emitting part is disposed can be reduced effectively. Therefore, it can be ensured that light ray crosstalk is not easy to occur in the light-emitting chip, thereby causing a display base plate integrated with the light-emitting chip to have a relatively good display effect.

The foregoing descriptions are merely specific embodiments of the present disclosure, but the protection scope of the present disclosure is not limited thereto. Any variation or replacement figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A light-emitting chip, comprising: a light-emitting unit, and a color converting unit disposed on a light-emitting side of the light-emitting unit, wherein
the light-emitting unit comprises a plurality of light-emitting parts, wherein each light-emitting part in the plurality of light-emitting parts comprises a first electrode, a first semiconductor layer and a light-emitting layer which are laminated in a first direction;
the light-emitting unit further comprises a second semiconductor layer and a common electrode layer, wherein the second semiconductor layer is disposed on light-emitting sides of the plurality of light-emitting parts, and comprises a connecting part and an assisting part, wherein the connecting part is connected to the light-emitting parts, and at least part of the assisting part is disposed between an adjacent connecting part; the connecting part and the assisting part are of an integrated structure, and the common electrode layer and the assisting part are connected;
wherein a surface of the second semiconductor layer facing the color converting unit is a first surface, and a surface of the second semiconductor layer facing away from the color converting unit is a second surface, and the second semiconductor layer comprises a first groove that opens in the second surface, and the first groove is at least disposed between orthographic projections of two adjacent light-emitting parts in the plurality of light-emitting parts on an extension surface of the second semiconductor layer; and
the light-emitting chip further comprises a filling part disposed in the first groove, wherein the filling part is made of an opaque material.

2. The light-emitting chip according to claim 1, wherein the filling part is a part of the common electrode layer.

3. The light-emitting chip according to claim 2, wherein the first groove is disposed in an orthographic projection of the common electrode layer on the extension surface of the second semiconductor layer.

4. (canceled)

5. The light-emitting chip according to claim 2, wherein a portion of the common electrode layer disposed in the first groove and a portion of the common electrode layer disposed outside the first groove are of a continuously-extended integrated structure.

6. The light-emitting chip according to claim 1, wherein a ratio of a depth of the first groove to a thickness of the second semiconductor layer is in a range of 10% to 65%.

7. The light-emitting chip according to claim 1, wherein a ratio of a distance between a bottom of the first groove and the first surface in the first direction to a thickness of the second semiconductor layer is in a range of 35% to 90%.

8. The light-emitting chip according to claim 1, wherein the second semiconductor layer comprises a first sub-layer and a second sub-layer which are laminated, wherein the first sub-layer is more proximal to the light-emitting part than the second sub-layer, the first sub-layer is a first carrier transport layer, and the second sub-layer is a buffer layer;
wherein the first groove comprises a first blind groove disposed on a side of the first sub-layer facing away from the second sub-layer; or
the first groove comprises a first penetrating groove penetrating through the first sub-layer; or
the first groove comprises: a first penetrating groove penetrating through the first sub-layer and a second blind groove disposed on a side of the second sub-layer facing the first sub-layer, the first penetrating groove being connected with the second blind groove; or
the first groove comprises: a first penetrating groove penetrating through the first sub-layer and a second penetrating groove penetrating through the second sub-layer, the first penetrating groove being connected with the second penetrating groove.

9. The light-emitting chip according to claim 8, wherein a minimum distance between an outer boundary of the first groove and an outer boundary of an orthographic projection, on the extension surface of the second semiconductor layer, of the light-emitting layer in the light-emitting part adjacent to the first groove is greater than or equal to 5 microns.

10. The light-emitting chip according to claim 1, wherein the plurality of light-emitting parts comprises a first light-emitting part, a second light-emitting part and a third light-emitting part; wherein the first light-emitting part and the second light-emitting part are disposed in a row in a second direction, and the first light-emitting part and the third light-emitting part are disposed in a row in a third direction; the second direction intersects with the third direction, and both the second direction and the third direction intersect with the first direction; and
the first groove comprises a first groove portion and a second groove portion, wherein the first groove portion is disposed between orthographic projections of the first light-emitting part and the second light-emitting part on the extension surface of the second semiconductor layer, and the second groove portion is disposed between orthographic projections of the first light-emitting part and the third light-emitting part on the extension surface of the second semiconductor layer.

11. The light-emitting chip according to claim 10, wherein the first groove portion and the second groove portion are both strip-shaped, the first groove portion extends along the third direction, and the second groove portion extends along the second direction; or
a length of the first groove in the third direction is greater than or equal to a width of the first light-emitting part in the third direction and greater than or equal to a width of the second light-emitting part in the third direction; and/or, a length of the second groove portion in the second direction is greater than or equal to a width of the first light-emitting part in the second direction and greater than or equal to a width of the third light-emitting part in the second direction.

12. (canceled)

13. The light-emitting chip according to claim 10, wherein a width of the first groove portion in the second direction and a width of the second groove portion in the third direction are both in a range of 2 microns to 10 microns.

14. The light-emitting chip according to claim 10, wherein the first groove portion and the second groove portion are connected with each other;
wherein a shape of an orthographic projection, on the extension surface of the second semiconductor layer, of the first groove portion and the second groove portion that are connected with each other comprises a T-shape.

15. (canceled)

16. The light-emitting chip according to claim 11 to 15, wherein the light-emitting unit further comprises a second electrode, the second electrode being disposed on a side of the common electrode layer distal from the color converting unit and being electrically connected to the common electrode layer;
wherein the first electrode in the third light-emitting part and the second electrode are disposed in a row in the second direction, and the first electrode in the second light-emitting part and the second electrode are disposed in a row in the third direction.

17. (canceled)

18. The light-emitting chip according to claim 1, wherein the color converting unit comprises a defining dam layer, wherein the defining dam layer defines a plurality of opening regions, one light-emitting part corresponding to one opening region in the first direction; and
the color converting unit further comprises: optical functional parts disposed in the opening regions of the defining dam layer, and an encapsulating layer configured to encapsulate the optical functional parts and the defining dam layer;
wherein each light-emitting part is configured to emit a first light ray, and at least part of the optical functional parts are configured to convert a color of an incident first light rays.

19. The light-emitting chip according to claim 18, wherein the plurality of light-emitting parts comprises: a first light-emitting part, a second light-emitting part and a third light-emitting part; wherein the first light-emitting part and the second light-emitting part are disposed in a row in a second direction, and the first light-emitting part and the third light-emitting part are disposed in a row in a third direction; the second direction intersects with the third direction, and both the second direction and the third direction intersect with the first direction;
a light-emitting area of the second light-emitting part is larger than a light-emitting area of the first light-emitting part, and is larger than a light-emitting area of the third light-emitting part; and
a projection area of an optical functional part corresponding to the second light-emitting part on the extension surface of the second semiconductor layer is larger than a projection area of an optical functional part corresponding to the first light-emitting part on the extension surface of the second semiconductor layer, and is larger than a projection area of an optical functional part corresponding to the third light-emitting part on the extension surface of the second semiconductor layer.

20. The light-emitting chip according to claim 19, wherein a length of a light-emitting layer of the second light-emitting part in the third direction is greater than a length of a light-emitting layer of the first light-emitting part in the third direction; and
a length of the optical functional part corresponding to the second light-emitting part in the third direction is greater than a length of the optical functional part corresponding to the third light-emitting part in the third direction.

21. The light-emitting chip according to claim 19, wherein the first light ray is blue light, and the optical functional part corresponding to the second light-emitting part is configured to convert the blue light into green light; and
the optical functional part corresponding to one of the first light-emitting part or the second light-emitting part is configured to convert the blue light into red light, and the optical functional part corresponding to the other light-emitting part of the first light-emitting part or the second light-emitting part is configured to transmit the first light ray.

22. The light-emitting chip according to claim 18, wherein the color converting unit further comprises: a first light selective transmission layer, wherein the first light selective transmission layer is distributed on a side of the color converting unit facing away from the light-emitting unit, and is configured to reflect the first light ray and transmit a light ray different from the first light ray in color;
wherein the plurality of optical functional parts comprises at least one first target optical functional part configured to convert the color of the first light ray into another color, wherein an orthographic projection of the first light selective transmission layer on the extension surface of the second semiconductor layer overlaps with an orthographic projection of the first target optical functional part on the extension surface of the second semiconductor layer.

23. The light-emitting chip according to claim 22, wherein the first light selective transmission layer is a continuously distributed film layer;
wherein the plurality of optical functional parts comprises at least one second target optical functional part configured to transmit the first light ray, the first light selective transmission layer comprises a hollowed-out region, wherein an orthographic projection of the hollowed-out region on the extension surface of the second semiconductor layer overlaps with an orthographic projection of the second target optical functional part on the extension surface of the second semiconductor layer.

24-30. (canceled)

31. A display base plate, comprising: a
light-emitting chip and
a driving circuit layer, wherein the driving circuit layer is configured to drive the light-emitting chip to emit light, and the light-emitting chip comprises: a light-emitting unit, and a color converting unit disposed on a light-emitting side of the light-emitting unit, wherein
the light-emitting unit comprises a plurality of light-emitting parts, wherein each light-emitting part in the plurality of light-emitting parts comprises a first electrode, a first semiconductor layer and a light-emitting layer which are laminated in a first direction;
the light-emitting unit further comprises a second semiconductor layer and a common electrode layer, wherein the second semiconductor layer is disposed on light-emitting sides of the plurality of light-emitting parts, and comprises a connecting part and an assisting part, wherein the connecting part is connected to the light-emitting parts, and at least part of the assisting part is disposed between an adjacent connecting part; the connecting part and the assisting part are of an integrated structure, and the common electrode layer and the assisting part are connected;
wherein a surface of the second semiconductor layer facing the color converting unit is a first surface, and a surface of the second semiconductor layer facing away from the color converting unit is a second surface, and the second semiconductor layer comprises a first groove that opens in the second surface, and the first groove is at least disposed between orthographic projections of two adjacent light-emitting parts in the plurality of light-emitting parts on an extension surface of the second semiconductor layer; and
the light-emitting chip further comprises a filling part disposed in the first groove, wherein the filling part is made of an opaque material.

32. (canceled)
